(19) United States
(12) Patent Application Publication
(10) Pub. No.: US 2026/0184994 A1
(43) Pub. Date: Jul. 2, 2026

(54) LIQUID CRYSTAL COMPOSITION, LIGHT ABSORPTION ANISOTROPIC FILM, LAMINATE, IMAGE DISPLAY DEVICE, AND POLYMER

(71) Applicant: FUJIFILM Corporation, Tokyo (JP)

(72) Inventors: Hiroshi MATSUYAMA, Minamiashigara-shi (JP); Wataru HOSHINO, Minamiashigara-shi (JP); Hiroyuki OKUSA, Minamiashigara-shi (JP); Toshikazu SUMI, Minamiashigara-shi (JP)

(73) Assignee: FUJIFILM Corporation, Tokyo (JP)

(21) Appl. No.: 19/378,360

(22) Filed: Nov. 4, 2025

Related U.S. Application Data
(63) Continuation of application No. PCT/JP2024/020692, filed on Jun. 6, 2024.

(30) Foreign Application Priority Data
Jun. 28, 2023 (JP) 2023-106087
Sep. 27, 2023 (JP) 2023-165673

(51) Int. Cl. C09K 19/54; C08G 77/26; C08G 77/38; C09K 19/20; C09K 19/60; G02B 5/30; G02F 1/1335; H10K 59/80

(52) U.S. Cl. CPC C09K 19/544; C08G 77/26; C08G 77/38; C09K 19/2028; C09K 19/601; G02B 5/3016; G02F 1/133531; H10K 59/8792; C09K 2019/2042; C09K 2019/2078; C09K 2019/546; C09K 2219/03

(57) ABSTRACT

A liquid crystal composition is provided that can form a light absorption anisotropic film with suppressed cissing and alignment defects. The invention also relates to the resulting film, a laminate, an image display device, and a polymer. The liquid crystal composition includes a liquid crystal compound, a dichroic substance, and a polymer having a specific repeating unit that contributes to stable film formation. The polymer includes substituent groups that improve compatibility with the liquid crystal and enhance alignment control. As a result, the composition enables formation of a uniform, defect-free light absorption anisotropic film suitable for use in high-quality display devices and optical laminates.

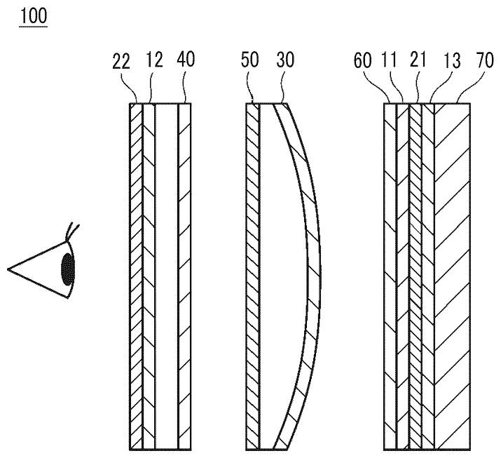

### CROSS-REFERENCE TO RELATED APPLICATIONS

This application is a Continuation of PCT International Application No. PCT/JP2024/020692 filed on Jun. 6, 2024, which claims priority under 35 U.S.C. § 119(a) to Japanese Patent Application No. 2023-106087 filed on Jun. 28, 2023 and Japanese Patent Application No. 2023-165673 filed on Sep. 27, 2023. The above applications are hereby expressly incorporated by reference, in their entirety, into the present application.

### BACKGROUND OF THE INVENTION

### 1. Field of the Invention

The present invention relates to a liquid crystal composition, a light absorption anisotropic film, a laminate, an image display device, and a polymer.

### 2. Description of the Related Art

Optical films such as optical compensation sheets and retardation films are used in various display devices from the viewpoints of eliminating image coloration and controlling a viewing angle.

For example, JP2016-095421A describes “a composition for forming a retardation layer contained in a retardation film, which contains a liquid crystal compound, a surfactant, and a solvent, in which the surfactant is a polyether-modified silicone having a repeating unit represented by General Formula (I)” (claim 1 of JP2016-095421A).

### SUMMARY OF THE INVENTION

As an optical film used in a display device, a light absorption anisotropic film containing a liquid crystal compound and a dichroic substance is known.

As a result of studying a liquid crystal composition containing the polyether-modified silicone described in JP2016-095421A, a liquid crystal compound, and a dichroic substance, the present inventors have found that, in a case of forming a light absorption anisotropic film, cissing occurs, and alignment defects occur in the formed light absorption anisotropic film.

Therefore, an object of the present invention is to provide a liquid crystal composition capable of forming a light absorption anisotropic film in which cissing is suppressed during formation of the light absorption anisotropic film and alignment defects are suppressed, the light absorption anisotropic film, a laminate, an image display device, and a polymer.

As a result of intensive studies in order to achieve the above-described object, the present inventors have found that, by blending a predetermined polymer in a liquid crystal composition used for forming the light absorption anisotropic film, the light absorption anisotropic film in which the cissing is suppressed in the formation of the light absorption anisotropic film and the alignment defects are suppressed can be formed, and thus have completed the present invention.

That is, the present inventors have found that the object can be achieved by the following configurations.

[1]

A liquid crystal composition comprising: a liquid crystal compound; a dichroic substance; and a polymer having a repeating unit A including a structure represented by Formula (A).

In Formula (A),
R^{A1} and R^{A2} each independently represent a hydrogen atom or an alkyl group.
R^{A3} represents a hydrogen atom, a halogen atom, or a substituent.
X represents a substituent including one or more structures represented by Formula (a).

In Formula (a),
* represents a bonding position.
R^{a1}, R^{a2}, and R^{a3} each independently represent an alkyl group, an alkenyl group, an aryl group, or an alkylene-aryl group, each of which may have a substituent.
   [2]

The liquid crystal composition according to [1], in which the polymer further has a repeating unit B represented by Formula (B).

In Formula (B),
R^{B1}, R^{B2}, and R^{B3} each independently represent a hydrogen atom, a halogen atom, a cyano group, an alkyl group, an alkenyl group, or an aryl group.
R^{B4} and R^{B5} each independently represent a hydrogen atom or a substituent. In a case where R^{B4} and R^{B5} are a substituent, R^{B4} and R^{B5} may be linked to each other to form a ring.
   [3]

The liquid crystal composition according to [2], in which in Formula (B), a total of molecular weights of R^{B4} and R^{B5} is 100 or less.

[4]

The liquid crystal composition according to [2] or [3], in which in Formula (B), R^{B4} and R^{B5} each independently represent a hydrogen atom or an organic group having 1 to 15 carbon atoms.

[5]

The liquid crystal composition according to any one of [1] to [4], in which the polymer further has a repeating unit D represented by Formula (D).

In Formula (D),
R^{D1}, R^{D2}, and R^{D3} each independently represent a hydrogen atom, a halogen atom, a cyano group, an alkyl group, an alkenyl group, or an aryl group.
L^{D1} represents a single bond, —COO—, or —CO—.
Sp^{D1} represents a divalent hydrocarbon group having 1 to 20 carbon atoms. Provide that one —CH₂— or two or more —CH₂—'s which are not adjacent to each other among —CH₂—'s constituting a part of the hydrocarbon group may be each independently substituted with —O—, —S—, —NH—, or —N(Q)-, and Q represents a substituent.
L^{D2} and L^{D3} each independently represent a single bond or a divalent linking group.
Cy^{D} represents a divalent linking group including a mesogen group.
D represents a hydrogen bonding group formed of a hydrogen atom and a non-metal atom of Groups 14 to 16. Provide that the non-metal atom may have a substituent.
n represents an integer of 1 to 3. In a case where n is 2 or 3, a plurality of L^{D2}'s may be the same or different from each other and a plurality of Cy^{D}'s may be the same or different from each other.
   [6]

The liquid crystal composition according to [5], in which in Formula (D), L^{D3} represents a single bond, and D represents —COOH, —NHCOR², or —CONHR³.

Here, R² and R³ each independently represent an alkyl group or an alkenyl group, each of which has 1 to 10 carbon atoms. Provide that one —CH₂— or two or more —CH₂—'s which are not adjacent to each other among —CH₂—'s constituting a part of the alkyl group and the alkenyl group may be substituted with —O—.

[7]

The liquid crystal composition according to [5] or [6], in which in Formula (D), L^{D3} represents a single bond, and D represents —NHCOR⁴.

Here, R⁴ represents an alkyl group or an alkenyl group, each of which has 1 to 3 carbon atoms. Provide that one —CH₂— or two or more —CH₂—'s which are not adjacent to each other among —CH₂—'s constituting a part of the alkyl group and the alkenyl group may be substituted with —O—.

[8]

The liquid crystal composition according to any one of [5] to [7], in which in Formula (D), n is 1 or 2.

[9]

The liquid crystal composition according to any one of [1] to [8], in which the repeating unit A is a repeating unit A-1 represented by Formula (A-1).

In Formula (A-1),
R^{A1} and R^{A2} each independently represent a hydrogen atom or an alkyl group.
R^{A3} represents a hydrogen atom, a halogen atom, or a substituent.
L^{A1} represents a single bond, —O—, or —NR^{Z}—. Provide that R^{Z} represents a hydrogen atom or a substituent.
L^{A2} represents a single bond or an (m+1)-valent linking group.
m represents an integer of 1 or more.
R^{a1}, R^{a2}, and R^{a3} each independently represent an alkyl group, an alkenyl group, an aryl group, or an alkylene-aryl group, each of which may have a substituent.

In a case where m is an integer of 2 or more, a plurality of R^{a1}'s may be the same or different from each other, a plurality of R^{a2}'s may be the same or different from each other, and a plurality of R^{a3}'s may be the same or different from each other.

[10]

The liquid crystal composition according to [9], in which in Formula (A-1), m is an integer of 2 or more.

[11]

The liquid crystal composition according to any one of [1] to [10], in which the polymer has a repeating unit A-1 represented by Formula (A-1), a repeating unit B represented by Formula (B), and a repeating unit D represented by Formula (D).

In Formula (A-1),
R^{A1} and R^{A2} each independently represent a hydrogen atom or an alkyl group.
R^{A3} represents a hydrogen atom, a halogen atom, or a substituent.
L^{A1} represents a single bond, —O—, or —NR^{Z}—. Provide that R^{Z} represents a hydrogen atom or a substituent.
L^{A2} represents a single bond or an (m+1)-valent linking group.
m represents an integer of 1 or more.
R^{a1}, R^{a2}, and R^{a3} each independently represent an alkyl group, an alkenyl group, an aryl group, or an alkylene-aryl group, each of which may have a substituent.

In a case where m is an integer of 2 or more, a plurality of R^{a1}'s may be the same or different from each other, a plurality of R^{a2}'s may be the same or different from each other, and a plurality of R^{a3}'s may be the same or different from each other.

In Formula (B),
R^{B1}, R^{B2}, and R^{B3} each independently represent a hydrogen atom, a halogen atom, a cyano group, an alkyl group, an alkenyl group, or an aryl group.
R^{B4} and R^{B5} each independently represent a hydrogen atom or a substituent. In a case where R^{B4} and R^{B5} are a substituent, R^{B4} and R^{B5} may be linked to each other to form a ring.

In Formula (D),
R^{D1}, R^{D2}, and R^{D3} each independently represent a hydrogen atom, a halogen atom, a cyano group, an alkyl group, an alkenyl group, or an aryl group.
L^{D1} represents a single bond, —COO—, or —CO—.
Sp^{D1} represents a divalent hydrocarbon group having 1 to 20 carbon atoms. Provide that one —CH₂— or two or more —CH₂—'s which are not adjacent to each other among —CH₂—'s constituting a part of the hydrocarbon group may be each independently substituted with —O—, —S—, —NH—, or —N(Q)-, and Q represents a substituent.
L^{D2} and L^{D3} each independently represent a single bond or a divalent linking group.
Cy^{D} represents a divalent linking group including a mesogen group.
D represents a hydrogen bonding group formed of a hydrogen atom and a non-metal atom of Groups 14 to 16. Provide that the non-metal atom may have a substituent.
n represents an integer of 1 to 3. In a case where n is 2 or 3, a plurality of L^{D2}'s may be the same or different from each other and a plurality of Cy^{D}'s may be the same or different from each other.
   [12]

The liquid crystal composition according to any one of [1] to [11], in which a mass ratio of a content of the polymer to a content of the dichroic substance is 0.0007 to 0.6.

[13]

The liquid crystal composition according to any one of [1] to [12], in which the liquid crystal compound includes a high-molecular-weight liquid crystal compound.

[14]

The liquid crystal composition according to [13], in which the liquid crystal compound further includes a low-molecular-weight liquid crystal compound.

[15]

A light absorption anisotropic film which is obtained by using the liquid crystal composition according to any one of [1] to [14].

[16]

The light absorption anisotropic film according to [15],
in which an alignment state of a liquid crystal compound and a dichroic substance which are contained in the light absorption anisotropic film is fixed, and
an angle θ between a transmittance central axis of the light absorption anisotropic film and a normal direction of a surface of the light absorption anisotropic film is more than 45° and 90° or less.
   [17]

A laminate comprising: the light absorption anisotropic film according to [15] or [16]; and a λ/4 plate.

[18]

An image display device comprising: the light absorption anisotropic film according to [15] or [16]; and a display element.

[19]

A polymer comprising:
a repeating unit A-1 represented by Formula (A-1); and
at least one of a repeating unit B represented by Formula (B) or a repeating unit D represented by Formula (D).

In Formula (A-1),
R^{A1} and R^{A2} each independently represent a hydrogen atom or an alkyl group.
R^{A3} represents a hydrogen atom, a halogen atom, or a substituent.
L^{A1} represents a single bond, —O—, or —NR^{Z}—. Provide that R^{Z} represents a hydrogen atom or a substituent.
L^{A2} represents a single bond or an (m+1)-valent linking group.
m represents an integer of 1 or more.
R^{a1}, R^{a2}, and R^{a3} each independently represent an alkyl group, an alkenyl group, an aryl group, or an alkylene-aryl group, each of which may have a substituent.

In a case where m is an integer of 2 or more, a plurality of R^{a1}'s may be the same or different from each other, a plurality of R^{a2}'s may be the same or different from each other, and a plurality of R³'s may be the same or different from each other.

In Formula (B),
R^{B1}, R^{B2}, and R^{B3} each independently represent a hydrogen atom, a halogen atom, a cyano group, an alkyl group, an alkenyl group, or an aryl group.
R^{B4} and R^{B5} each independently represent a hydrogen atom or a substituent. In a case where R^{B4} and R^{B5} are a substituent, R^{B4} and R^{B5} may be linked to each other to form a ring.

In Formula (D),
R^{D1}, R^{D2}, and R^{D3} each independently represent a hydrogen atom, a halogen atom, a cyano group, an alkyl group, an alkenyl group, or an aryl group.
L^{D1} represents a single bond, —COO—, or —CO—.
Sp^{D1} represents a divalent hydrocarbon group having 1 to 20 carbon atoms. Provide that one —CH₂— or two or more —CH₂—'s which are not adjacent to each other among —CH₂—'s constituting a part of the hydrocarbon group may be each independently substituted with —O—, —S—, —NH—, or —N(Q)-, and Q represents a substituent.
L^{D2} and L^{D3} each independently represent a single bond or a divalent linking group.
Cy^{D} represents a divalent linking group including a mesogen group.
D represents a hydrogen bonding group formed of a hydrogen atom and a non-metal atom of Groups 14 to 16. Provide that the non-metal atom may have a substituent.
n represents an integer of 1 to 3. In a case where n is 2 or 3, a plurality of L^{D2}'s may be the same or different from each other and a plurality of Cy^{D}'s may be the same or different from each other.

According to the present invention, it is possible to provide a liquid crystal composition capable of forming a light absorption anisotropic film in which cissing is suppressed during formation of the light absorption anisotropic film and alignment defects are suppressed, the light absorption anisotropic film, a laminate, an image display device, and a polymer.

### BRIEF DESCRIPTION OF THE DRAWINGS

The FIGURE is a side view schematically showing an embodiment of a virtual reality display apparatus which is an example of a display device according to the embodiment of the present invention.

### DESCRIPTION OF THE PREFERRED EMBODIMENTS

Hereinafter, the present invention will be described in detail.

The description of configuration requirements described below may be made based on typical embodiments of the present invention, but the present invention is not limited to such embodiments.

In the present specification, numerical ranges represented by “to” include numerical values before and after “to” as lower limit values and upper limit values. In a numerical range described in a stepwise manner in the present specification, an upper limit value or a lower limit value described in a certain numerical range may be replaced with an upper limit value or a lower limit value in another numerical range described in a stepwise manner. In addition, regarding a numerical range described in the present specification, the upper limit value or the lower limit value described in a certain numerical range may be replaced with a value described in Examples.

In addition, in the present specification, substances corresponding to respective components may be used alone or in combination of two or more kinds thereof. Here, in a case where two or more types of substances are used in combination for each component, the content of the component refers to a total content of the substances used in combination unless otherwise specified.

In addition, in the present specification, “(meth)acrylate” denotes “acrylate” or “methacrylate”, “(meth)acryl” denotes “acryl” or “methacryl”, “(meth)acryloyl” denotes “acryloyl” or “methacryloyl”, and “(meth)acrylic acid” denotes “acrylic acid” or “methacrylic acid”.

In addition, a bonding direction of divalent groups cited in the present specification is not limited unless otherwise specified. For example, in a case where Y in a compound represented by Formula “X—Y—Z” is —C(O)—O—, Y may be —C(O)—O— or —O—C(O)—. In addition, the above-described compound may be “X—C(O)—O—Z” or “X—O—C(O)—Z”.

In addition, in the present specification, “orthogonal” and “parallel” with respect to angles mean a range of a strict angle ±10°, and “same” and “different” with respect to the angles can be determined based on whether the difference is less than 5° or not.

In addition, in the present specification, “visible light” refers to light in a wavelength range of 380 to 780 nm.

In addition, in the present specification, a measurement wavelength is 550 nm unless otherwise specified.

In the present specification, “slow axis” means a direction in which the in-plane refractive index is maximum. Moreover, the slow axis of the optically anisotropic layer is intended to mean a slow axis of the entire optically anisotropic layer.

In the present specification, “Re(λ)” and “Rth(λ)” respectively represent an in-plane retardation at a wavelength λ, and a thickness-direction retardation at a wavelength λ.

Here, the values of the in-plane retardation and the thickness-direction retardation refer to values measured using AxoScan OPMF-1 (manufactured by Opto Science, Inc.) with a light having a measurement wavelength.

Specifically, by inputting an average refractive index ((nx+ny+nz)/3) and a film thickness (d (μm)) to AxoScan OPMF-1, it is possible to calculate:
a slow axis direction (°),

$$Re ( λ ) = R 0 ( λ ) , and$$

$$Rth ( λ ) = ( ( nx + ny ) / 2 - nz ) \times d .$$

In addition, R0(λ) is expressed in a numerical value calculated with AxoScan OPMF-1, and means Re(λ).

### [Substituent W]

A substituent W used in the present specification represents any of the following groups.

Examples of the substituent W include a halogen atom, an alkyl group having 1 to 20 carbon atoms, a halogenated alkyl group having 1 to 20 carbon atoms, a cycloalkyl group having 1 to 20 carbon atoms, an alkylcarbonyl group having 1 to 10 carbon atoms, an alkyloxycarbonyl group having 1 to 10 carbon atoms, an alkylcarbonyloxy group having 1 to 10 carbon atoms, an alkylamino group having 1 to 10 carbon atoms, an alkylaminocarbonyl group, an alkoxy group having 1 to 20 carbon atoms, an alkenyl group having 1 to 20 carbon atoms, an alkynyl group having 1 to 20 carbon atoms, an aryl group having 1 to 20 carbon atoms, a heterocyclic group (may be referred to as a hetero ring group), a cyano group, a hydroxy group, a nitro group, a carboxy group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an acylamino group, an aminocarbonylamino group, an alkoxycarbonylamino group, an aryloxycarbonylamino group, a sulfamoylamino group, an alkyl or arylsulfonylamino group, a mercapto group, an alkylthio group, an arylthio group, a heterocyclic thio group, a sulfamoyl group, a sulfo group, an alkyl or arylsulfinyl group, an alkyl or arylsulfonyl group, an acyl group, an aryloxycarbonyl group, an alkoxycarbonyl group, a carbamoyl group, an aryl or heterocyclic azo group, an imide group, a phosphino group, a phosphinyl group, a phosphinyloxy group, a phosphinylamino group, a phosphono group, a silyl group, a hydrazino group, a ureido group, a boronic acid group (—B(OH)₂), a phosphate group (—OPO(OH)₂), a sulfate group (—OSO₃H), and other known substituents.

Details of the substituent are described in paragraph [0023] of JP2007-234651A.

In addition, the substituent W may be a group represented by Formula (W1).

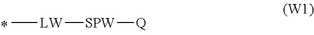

In Formula (W1), LW represents a single bond or a divalent linking group, SPW represents a divalent spacer group, Q represents a terminal group, and * represents a bonding position.

Examples of the divalent linking group represented by LW include —O—, —Si(CH₃)₂—, —(Si(CH₃)₂O)_{g}— (g represents an integer of 1 to 10), —N(Z)—, —C(Z)═C(Z¹)—, —C(Z)═N—, —C(O)—, —C(O)O—, —O—C(O)O—, —C(O)N(Z)—, —C(Z)═C(Z¹)—C(O)O—, —C(Z)═N—, —C(Z)═C(Z¹)—C(O)N(Z²)—, —C(Z)═C(Z¹)—C(O)—S—, —C(Z)═N—N═C(Z¹)— (Z, Z¹, and Z² each independently represent a hydrogen atom, an alkyl group having 1 to 4 carbon atoms, a cycloalkyl group, an aryl group, a cyano group, or a halogen atom), —C≡C—, —N═N—, —S—, —S(O)—, —S(O)(O)—, —(O)S(O)O—, —O(O)S(O)O—, and —SC(O)—. LW may be a group in which two or more of these groups are combined (hereinafter, also abbreviated as “L-C”).

Examples of the divalent spacer group represented by SPW include a linear, branched, or cyclic alkylene group having 1 to 50 carbon atoms, and a heterocyclic group having 1 to 20 carbon atoms.

The carbon atoms of the alkylene group and the heterocyclic group may be substituted with —O—, —Si(CH₃)₂—, —(Si(CH₃)₂O)_{g}— (g represents an integer of 1 to 10), —N(Z)—, —C(Z)═C(Z¹)—, —C(Z)═N—, —C(Z)₂—C(Z¹)₂—, —C(O)—, —C(O)O—, —O—C(O)O—, —C(O)N(Z)—, —C(Z)═C(Z¹)—C(O)O—, —C(Z)═N—, —C(Z)═C(Z¹)—C(O)N(Z²)—, —C(Z)═C(Z¹)—C(O)—S—, —C(Z)═N—N═C(Z¹)— (Z, Z¹, and Z² independently represent hydrogen, an alkyl group having 1 to 4 carbon atoms, a cycloalkyl group, an aryl group, a cyano group, or a halogen atom), —C≡C—, —N═N—, —S—, —C(S)—, —S(O)—, —SO₂—, —(O)S(O)O—, —O(O)S(O)O—, —SC(O)—, and a group obtained by combining two or more of these groups.

Further, the hydrogen atoms of the alkylene group and the hydrogen atoms of the heterocyclic group may be substituted with a halogen atom, a cyano group, —Z^{H1}, —OH, —OZ^{H1}, —COOH, —C(O)Z^{H1}, —C(O)OZ^{H1}, —OC(O)Z^{H1}, —OC(O)OZ^{H1}, —NZ^{H1}Z^{H2}, —NZ^{H1}C(O)Z^{H2}, —NZ^{H1}C(O)OZ^{H2}, —C(O)NZ^{H1}Z^{H2}, —OC(O)NZ^{H1}Z^{H2}, —NZ^{H1}C(O)NZ^{H2}OZ^{H3}, —SH, —SZ^{H1}, —C(S)Z^{H1}, —C(O)SZ^{H1}, or —SC(O)Z^{H1}. Here, Z^{H1}, Z^{H2}, and Z^{H3} represent an alkyl group having 1 to 10 carbon atoms, a halogenated alkyl group, or -L-CL.

In -L-CL, L represents a single bond or a divalent linking group. Specific examples of the divalent linking group are the same as those for LW and SPW described above.

In -L-CL, CL represents a crosslinkable group. Specific examples of the crosslinkable group include crosslinkable groups represented by Formulae (P-1) to (P-30).

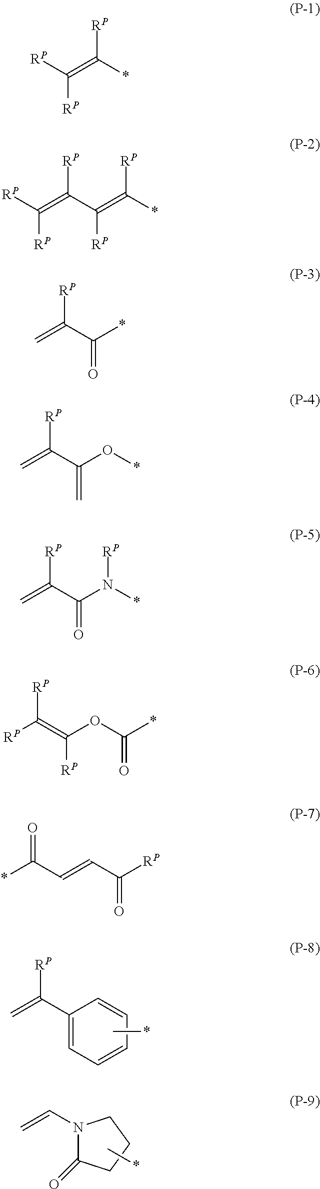

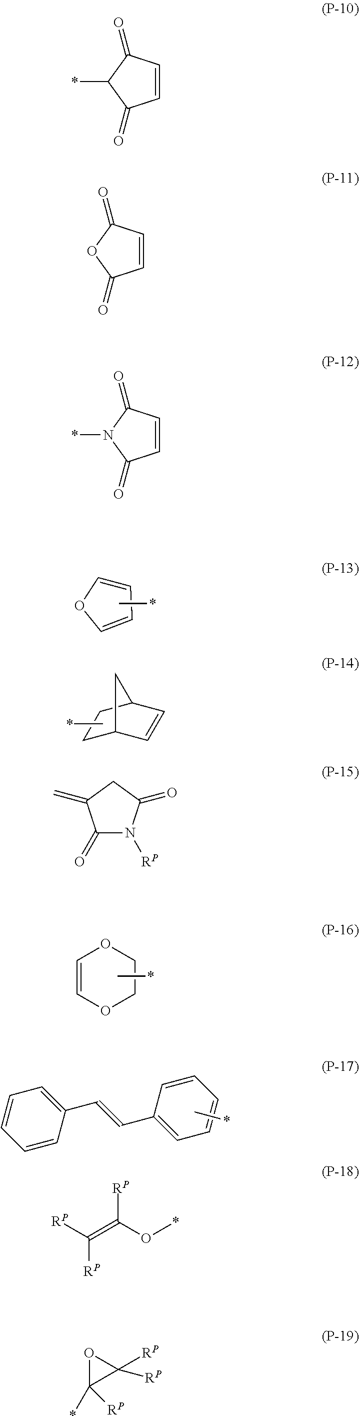

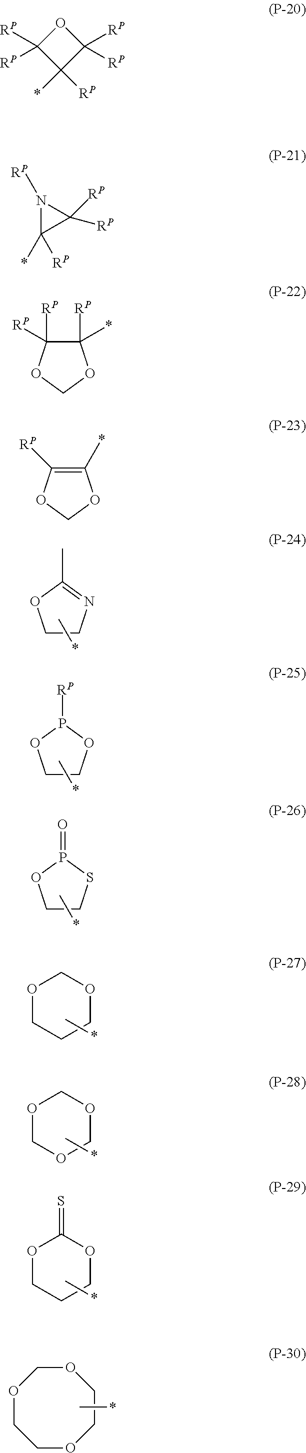

In Formulae (P-1) to (P-30), R^{P} represents a hydrogen atom, a halogen atom, a linear, branched, or cyclic alkylene group having 1 to 10 carbon atoms, a halogenated alkyl group having 1 to 20 carbon atoms, an alkoxy group having 1 to 20 carbon atoms, an alkenyl group having 1 to 20 carbon atoms, an alkynyl group having 1 to 20 carbon atoms, an aryl group having 1 to 20 carbon atoms, a heterocyclic group (may be referred to as a hetero ring group), a cyano group, a hydroxy group, a nitro group, a carboxy group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an acylamino group, an aminocarbonylamino group, an alkoxycarbonylamino group, an aryloxycarbonylamino group, a sulfamoylamino group, an alkyl or arylsulfonylamino group, a mercapto group, an alkylthio group, an arylthio group, a heterocyclic thio group, a sulfamoyl group, a sulfo group, an alkyl or arylsulfinyl group, an alkyl or arylsulfonyl group, an acyl group, an aryloxycarbonyl group, an alkoxycarbonyl group, a carbamoyl group, an aryl or heterocyclic azo group, an imide group, a phosphino group, a phosphinyl group, a phosphinyloxy group, a phosphinylamino group, a phosphono group, a silyl group, a hydrazino group, a ureido group, a boronic acid group (—B(OH)₂), a phosphate group (—OPO(OH)₂), or a sulfate group (—OSO₃H), and a plurality of R^{P}'s may be the same or different from each other.

Examples of a preferred aspect of the crosslinkable group include a radically polymerizable group and a cationically polymerizable group. As the radically polymerizable group, a vinyl group represented by Formula (P-1), a butadiene group represented by Formula (P-2), a (meth)acryloyl group represented by Formula (P-4), a (meth)acrylamide group represented by Formula (P-5), a vinyl acetate group represented by Formula (P-6), a fumaric acid ester group represented by Formula (P-7), a styryl group represented by Formula (P-8), a vinylpyrrolidone group represented by Formula (P-9), a maleic acid anhydride represented by Formula (P-11), or a maleimide group represented by Formula (P-12) is preferable. As the cationically polymerizable group, a vinyl ether group represented by Formula (P-18), an epoxy group represented by Formula (P-19), or an oxetanyl group represented by Formula (P-20) is preferable.

The terminal group represented by Q represents a hydrogen atom, a halogen atom, a linear, branched, or cyclic alkyl group having 1 to 20 carbon atoms, an alkoxy group having 1 to 20 carbon atoms, an alkenyl group having 1 to 20 carbon atoms, an alkynyl group having 1 to 20 carbon atoms, an aryl group having 1 to 20 carbon atoms, a heterocyclic group (may be referred to as a hetero ring group), a cyano group, a hydroxy group, a nitro group, a carboxy group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an acylamino group, an aminocarbonylamino group, an alkoxycarbonylamino group, an aryloxycarbonylamino group, a sulfamoylamino group, an alkyl or arylsulfonylamino group, a mercapto group, an alkylthio group, an arylthio group, a heterocyclic thio group, a sulfamoyl group, a sulfo group, an alkyl or arylsulfinyl group, an alkyl or arylsulfonyl group, an acyl group, an aryloxycarbonyl group, an alkoxycarbonyl group, a carbamoyl group, an aryl or heterocyclic azo group, an imide group, a phosphino group, a phosphinyl group, a phosphinyloxy group, a phosphinylamino group, a phosphono group, a silyl group, a hydrazino group, a ureido group, a boronic acid group (—B(OH)₂), a phosphate group (—OPO(OH)₂), a sulfate group (—OSO₃H), or crosslinkable groups represented by Formulae (P-1) to (P-30).

### [Liquid Crystal Composition]

A liquid crystal composition according to the embodiment of the present invention contains a liquid crystal compound, a dichroic substance, and a polymer having a repeating unit A including a structure represented by Formula (A) (hereinafter, also referred to as a “specific polymer”).

According to the liquid crystal composition according to the embodiment of the present invention, it is possible to form a light absorption anisotropic film in which cissing is suppressed during formation of the light absorption anisotropic film and alignment defects are suppressed. The details of the reason for this are not clear, but it is presumed as follows.

That is, the specific polymer having the repeating unit A having a branched Si structure in the side chain can reduce the surface tension of the liquid crystal composition, and also has good compatibility with the liquid crystal compound and the dichroic substance. As a result, it is considered that the cissing in a case of forming the light absorption anisotropic film was suppressed. In addition, it is presumed that the alignment defects are caused by a component having the dichroic substance precipitated during film formation as a nucleus, but since the compatibility with the specific polymer and the dichroic substance is good, it is considered that a light absorption anisotropic film in which the occurrence of the alignment defects is suppressed can be formed.

In addition, according to the liquid crystal composition according to the embodiment of the present invention, it is possible to form a light absorption anisotropic film that has an excellent alignment degree. The details of the reason are not clear, but it is presumed that the alignment degree of the light absorption anisotropic film was improved by the reduction in the surface tension of the liquid crystal composition due to the use of the specific polymer and the good compatibility between the specific polymer and the liquid crystal compound and the dichroic substance.

Hereinafter, each component of the liquid crystal composition according to the embodiment of the present invention will be described in detail.

### [Liquid Crystal Compound]

The liquid crystal composition according to the embodiment of the present invention contains a liquid crystal compound. In this manner, the dichroic substance can be aligned with a high alignment degree while precipitation of the dichroic substance is restrained.

As the liquid crystal compound, both a high-molecular-weight liquid crystal compound and a low-molecular-weight liquid crystal compound can be used, and from the viewpoint of increasing the alignment degree, a high-molecular-weight liquid crystal compound is preferable. In addition, the high-molecular-weight liquid crystal compound and the low-molecular-weight liquid crystal compound may be used in combination as the liquid crystal compound.

Here, the “high-molecular-weight liquid crystal compound” refers to a liquid crystal compound having a repeating unit in the chemical structure.

In addition, the “low-molecular-weight liquid crystal compound” refers to a liquid crystal compound having no repeating unit in the chemical structure.

Examples of the high-molecular-weight liquid crystal compound include thermotropic liquid crystalline polymers described in JP2011-237513A and high-molecular-weight liquid crystal compounds described in paragraphs [0012] to [0042] of WO2018/199096A.

Examples of the low-molecular-weight liquid crystal compound include liquid crystal compounds described in paragraphs [0072] to [0088] of JP2013-228706A, and among these, a liquid crystal compound exhibiting smectic properties is preferable.

Examples of such a liquid crystal compound include compounds described in paragraphs [0019] to [0140] of WO2022/014340A, the description of which is incorporated herein by reference.

The weight-average molecular weight (Mw) of the high-molecular-weight liquid crystal compound is preferably 2,000 to 300,000 and more preferably 2,000 to 100,000. In a case where the Mw of the high-molecular-weight liquid crystal compound is within the above-described range, the high-molecular-weight liquid crystal compound is easily handled.

Here, the weight-average molecular weight (Mw) and the number-average molecular weight (Mn) of the high-molecular-weight liquid crystal compound are values measured by a gel permeation chromatography (GPC) method.

Solvent (eluent): N-methylpyrrolidone
Device Name: TOSOH HLC-8220GPC
Column: Three items of TOSOH TSKgel Super HZM-H (4.6 mm×15 cm) are connected and used
Column Temperature: 25° C.
Sample Concentration: 0.1% by mass
Flow rate: 0.35 mL/min
Calibration curve: TSK standard polystyrene (manufactured by TOSOH Corporation), calibration curves of 7 samples with Mw of 2,800,000 to 1,050 (Mw/Mn=1.03 to 1.06) are used

A content of the liquid crystal compound is preferably 25 to 2,000 parts by mass, more preferably 100 to 1,300 parts by mass, and still more preferably 200 to 900 parts by mass with respect to 100 parts by mass of the content of the dichroic substance described later. In a case where the content of the liquid crystal compound is within the above-described range, the alignment degree of the dichroic substance is further improved.

The liquid crystal compound may be contained only one kind or two or more kinds. In a case of containing two or more kinds of liquid crystal compounds, the above-described content of the liquid crystal compound means the total content of the liquid crystal compounds.

### [Dichroic Substance]

The liquid crystal composition according to the embodiment of the present invention contains a dichroic substance.

Here, the dichroic substance means a coloring agent having different absorbances depending on the direction.

In addition, the dichroic substance may or may not exhibit liquid crystallinity.

The dichroic substance is not particularly limited, and examples thereof include a visible light absorbing material (dichroic coloring agent), a light emitting material (such as a fluorescent material or a phosphorescent material), an ultraviolet absorbing material, an infrared absorbing material, a non-linear optical material, a carbon nanotube, and an inorganic material (for example, a quantum rod). In addition, known dichroic substances (dichroic coloring agents) of the related art can be used.

Specific examples thereof include those described in paragraphs [0067] to [0071] of JP2013-228706A, paragraphs [0008] to [0026] of JP2013-227532A, paragraphs [0008] to [0015] of JP2013-209367A, paragraphs [0045] to [0058] of JP2013-14883A, paragraphs [0012] to [0029] of JP2013-109090A, paragraphs [0009] to [0017] of JP2013-101328A, paragraphs [0051] to [0065] of JP2013-37353A, paragraphs [0049] to [0073] of JP2012-63387A, paragraphs [0016] to [0018] of JP1999-305036A (JP-H11-305036A), paragraphs [0009] to [0011] of JP2001-133630A, paragraphs [0030] to [0169] of JP2011-215337A, paragraphs [0021] to [0075] of JP2010-106242A, paragraphs [0011] to [0025] of JP2010-215846A, paragraphs [0017] to [0069] of JP2011-048311A, paragraphs [0013] to [0133] of JP2011-213610A, paragraphs [0074] to [0246] of JP2011-237513A, paragraphs [0005] to [0051] of JP2016-006502A, paragraphs [0014] to [0032] of JP2018-053167A, paragraphs [0014] to [0033] of JP2020-11716A, paragraphs [0005] to [0041] of WO2016/060173A, paragraphs [0008] to [0062] of WO2016/136561A, paragraphs [0014] to [0033] of WO2017/154835A, paragraphs [0014] to [0033] of WO2017/154695A, paragraphs [0013] to [0037] of WO2017/195833A, paragraphs [0014] to [0034] of WO2018/164252A, paragraphs [0021] to [0030] of WO2018/186503A, paragraphs [0043] to [0063] of WO2019/189345A, paragraphs [0043] to [0085] of WO2019/225468A, paragraphs [0050] to [0074] of WO2020/004106A, and paragraphs [0015] to [0038] of WO2021/044843A.

As the dichroic substance, a dichroic azo coloring agent compound is preferable.

The dichroic azo coloring agent compound denotes an azo coloring agent compound having different absorbances depending on the direction. The dichroic azo coloring agent compound may or may not exhibit liquid crystallinity. In a case where the dichroic azo coloring agent compound exhibits liquid crystallinity, any of nematic properties or smectic properties may be exhibited. A temperature range at which the liquid crystallinity is exhibited is preferably room temperature (approximately 20° C. to 28° C.) to 300° C., and from the viewpoint of handleability and manufacturing suitability, more preferably 50° C. to 200° C.

In the present invention, from the viewpoint of tint adjustment, it is preferable to use at least at least one coloring agent compound (first dichroic azo coloring agent compound) having a maximal absorption wavelength in a wavelength range of 560 to 700 nm and at least one coloring agent compound (second dichroic azo coloring agent compound) having a maximal absorption wavelength in a wavelength range of 455 nm or more and less than 560 nm.

In the present invention, three or more kinds of dichroic azo coloring agent compounds may be used in combination. For example, from the viewpoint of making color of the light absorption anisotropic film close to black, it is preferable to use the first dichroic azo coloring agent compound, the second dichroic azo coloring agent compound, and at least one coloring agent compound (third dichroic azo coloring agent compound) having a maximal absorption wavelength in a wavelength range of 380 nm or more and less than 455 nm in combination.

In the present invention, from the viewpoint of excellent light resistance of the light absorption anisotropic film, it is preferable to contain two or more kinds of first dichroic azo coloring agent compounds.

In the present invention, it is preferable that the dichroic azo coloring agent compound has a crosslinkable group.

Examples of the crosslinkable group include a (meth)acryloyl group, an epoxy group, an oxetanyl group, and a styryl group, and among these, a (meth)acryloyl group is preferable.

From the viewpoint of further increasing the alignment degree of the light absorption anisotropic layer to be formed, a content of the dichroic substance is preferably 3% to 90% by mass, more preferably 5% to 70% by mass, and still more preferably 10% to 60% by mass with respect to the total solid content mass of the liquid crystal composition. In a case where a plurality of dichroic substances are used in combination, the total amount of the plurality of dichroic substances is preferably within the above range.

Here, in the present specification, the “total solid content in the liquid crystal composition” denotes components excluding a solvent, and specific examples of the solid content include the liquid crystal compound, the dichroic substance, and the specific polymer.

### [Specific Polymer]

The specific polymer is a polymer having the repeating unit A, and particularly in a case of horizontal alignment (the angle θ between the transmittance central axis of the light absorption anisotropic film and the normal direction of the surface of the light absorption anisotropic film is more than 450 and 900 or less), from the viewpoint that the effect of the present invention is more excellent and the alignment degree of the light absorption anisotropic film is more excellent, the specific polymer is preferably a polymer (copolymer) including the repeating unit A (preferably, the repeating unit A-1) and at least one of the repeating unit B or the repeating unit D, and more preferably a polymer (copolymer) including the repeating unit A (preferably, the repeating unit A-1), the repeating unit B, and the repeating unit D.

### <Repeating Unit A>

The repeating unit A is a repeating unit including a structure represented by Formula (A).

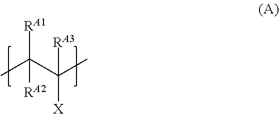

In Formula (A), R^{A1} and R^{A2} each independently represent a hydrogen atom or an alkyl group.

Examples of the alkyl group in R^{A1} and R^{A2} include a linear alkyl group having 1 to 18 carbon atoms (preferably 1 to 6 carbon atoms and more preferably 1 to 4 carbon atoms), and a branched or cyclic alkyl group having 3 to 18 carbon atoms (preferably 3 to 9 carbon atoms and more preferably 3 to 6 carbon atoms). Specific examples thereof include a methyl group, an ethyl group, a propyl group, a butyl group, an isopropyl group, a tert-butyl group, and a cyclohexyl group.

Both R^{A1} and R^{A2} are preferably a hydrogen atom.

In Formula (A), R^{A}S represents a hydrogen atom, a halogen atom, or a substituent, Examples of the substituent in R^{A3} include a substituent having an alkyl group, an alkenyl group, an aryl group, or a linking group, and having the structure of Formula (a) described later at a terminal.

Specific examples of the substituent having a linking group and having a structure of Formula (a) described later at a terminal include —CH₂—CO-L^{A1}-L^{A2}-(Si(R^{a1})(R^{a2})(R^{a3}))ₘ. The definition of -L^{A1}-L^{A2}-(Si(R^{a1})(R^{a2})(R^{a3}))ₘ is the same as the definition of -L^{A1}-L^{A2}-(Si(R^{a1})(R^{a2})(R^{a3}))ₘ in Formula (A-1) described later, and the suitable aspect thereof is also the same.

The substituent represented in R^{A3} is preferably an alkyl group, more preferably a linear alkyl group having 1 to 4 carbon atoms, and still more preferably a methyl group or an ethyl group.

R^{A3} is preferably a hydrogen atom or a methyl group.

In Formula (A), X represents a substituent (hereinafter, also referred to as a “substituent X”) including one or more structures represented by Formula (a) (hereinafter, also referred to as a “group a”).

As the substituent X, a monovalent hydrocarbon group having one or more groups a is preferable. The monovalent hydrocarbon group in the substituent X may be linear, branched, or cyclic; however, it is preferably linear or branched.

Examples of the monovalent hydrocarbon group in the substituent X include a monovalent aliphatic hydrocarbon group and a monovalent aromatic hydrocarbon group. The monovalent hydrocarbon group is preferably a monovalent aliphatic hydrocarbon group, and more preferably an alkyl group. The alkyl group may be linear, branched, or cyclic, and is preferably linear or branched. The number of carbon atoms in the alkyl group is preferably 1 to 30, more preferably 2 to 25, and still more preferably 2 to 20.

Here, one or more —CH₂—'s among —CH₂—'s constituting a part of the monovalent hydrocarbon group in the substituent X may be each independently substituted with a divalent group such as —O—, —CO—, —C(O)—O—, —C(O)—N(R^{X10})—, —[O—Si(R^{X11})₂]ₙₓ—, or —Si(R^{X12})₂—, and they are preferably substituted with these divalent groups.

R^{X10} represents a hydrogen atom or an alkyl group having 1 to 6 carbon atoms, and is preferably a hydrogen atom. The alkyl group may be linear, branched, or cyclic, and is preferably linear or branched.

R^{X11} and R^{X12} each independently represent a hydrogen atom, a hydroxy group, a group a (that is, a group represented by Formula (a) shown below), or an alkyl group having 1 to 6 carbon atoms, and an alkyl group having 1 to 6 carbon atoms or the above-described group a is preferable. The alkyl group may be linear, branched, or cyclic, and is preferably linear or branched. Two R^{X11}'s may be the same as or different from each another. Two R^{X12}'s may be the same as or different from each another.

nx is a number of 1 or more, and is preferably a number from 1 to 100 and more preferably a number from 1 to 11. In a case where nx is a number of 2 or more, a plurality of [O—Si(R^{X11})₂]'s may be the same or different from each other.

Examples of one suitable aspect of the substituent X include a group represented by Formula (X1) shown below.

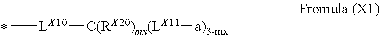

In Formula (X1), * represents a bonding position.

In Formula (X1), L^{X10} and L^{X11} each independently represent a divalent hydrocarbon group. Provide that one or more —CH₂—'s among —CH₂—'s constituting a part of the divalent hydrocarbon group may be each independently substituted with a divalent group such as —O—, —CO—, —C(O)—O—, —C(O)—N(R^{X10})—, —[O—Si(R^{X11})₂]ₙₓ—, or —Si(R^{X12})₂—. The definitions of R^{X10}, R^{X11}, R^{X12}, and nx are as described above. Two R¹¹'s may be the same as or different from each another. Two R^{X12}'s may be the same as or different from each another. In a case where nx is a number of 2 or more, a plurality of [O—Si(R^{X11})₂]'s may be the same or different from each other.

Examples of the divalent hydrocarbon group in L^{X10} and L^{X11} include a divalent aliphatic hydrocarbon group and a divalent aromatic hydrocarbon group. The divalent hydrocarbon group is preferably a divalent aliphatic hydrocarbon group, and more preferably an alkylene group. The alkylene group may be linear, branched, or cyclic, and is preferably linear or branched and more preferably linear. The number of carbon atoms in the alkylene group is preferably 1 to 30, more preferably 2 to 25, and still more preferably 2 to 20.

In Formula (X1), R^{X20} represents a hydrogen atom or a monovalent hydrocarbon group. The definition of the monovalent hydrocarbon group in R^{X20} is the same as the monovalent hydrocarbon group described in the substituent X above.

In Formula (X1), a represents a structure (group) represented by Formula (a) described later.

In Formula (X1), mx represents an integer of 0 to 2. In a case where mx is an integer of 0 or 1, a plurality of [L^{X11}-a]'s may be the same or different from each other. In a case where mx is 2, two R^{X20}'s may be the same as or different from each another.

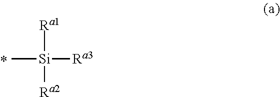

In Formula (a), * represents a bonding position.

In addition, R^{a1}, R^{a2}, and R^{a3} each independently represent an alkyl group, an alkenyl group, an aryl group, or an alkylene-aryl group, each of which may have a substituent. Specific examples of the substituent include the substituent W described above; and among these, a halogen atom, an alkyl group, an alkylcarbonyl group, an alkyloxycarbonyl group, an alkylcarbonyloxy group, or an alkoxy group is preferable.

Examples of the alkyl group include a linear alkyl group having 1 to 18 carbon atoms and a branched or cyclic alkyl group having 3 to 18 carbon atoms. Specific examples thereof include a methyl group, an ethyl group, a propyl group, a butyl group, an isopropyl group, a tert-butyl group, and a cyclohexyl group.

Examples of the alkenyl group include an alkenyl group having 2 to 12 carbon atoms. Specific examples thereof include a vinyl group, a 1-propenyl group, a 1-butenyl group, a 1-methyl-1-propenyl group, a 1-cyclopentenyl group, and a 1-cyclohexenyl group.

Examples of the aryl group include an aryl group having 6 to 12 carbon atoms. Specific examples thereof include a phenyl group, an a-methylphenyl group, and a naphthyl group.

Examples of the alkylene-aryl group include an alkylene-aryl group having 7 to 30 carbon atoms.

The number of groups a included in the substituent X is 1 or more, and is preferably 2 or more and more preferably 3 or more from the viewpoint that the alignment degree of the light absorption anisotropic film is more excellent, and is preferably 18 or less, more preferably 12 or less, still more preferably 9 or less, and particularly preferably 6 or less from the viewpoint that the alignment defects can be further suppressed.

From the viewpoint that the effect of the present invention is more excellent and the alignment degree of the light absorption anisotropic film is more excellent, the repeating unit A is preferably a repeating unit A-1 represented by Formula (A-1).

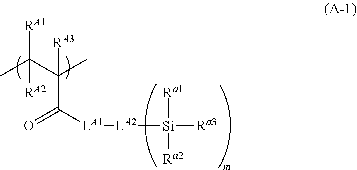

In Formula (A-1), R^{A1}, R^{A2}, and R^{A3} are the same as those described in Formula (A), and R^{a1}, R^{a2}, and R^{a3} are the same as those described in Formula (a).

In a case where m in Formula (A-1) is an integer of 2 or more, a plurality of R^{a1}'s may be the same or different from each other, a plurality of R^{a2}'s may be the same or different from each other, and a plurality of R^{a3}'s may be the same or different from each other.

In Formula (A-1), L^{A1} represents a single bond, —O—, or —NR^{Z}—. Provide that R^{Z} represents a hydrogen atom or a substituent.

Regarding —NR^{Z}— in L^{A1}, as the substituent in R^{Z}, an alkyl group is preferable, a linear alkyl group having 1 to 4 carbon atoms is more preferable, and a methyl group or an ethyl group is still more preferable.

L^{A1} is preferably —O— or —NH— and more preferably —O—.

In Formula (A-1), L^{A2} represents a single bond or an (m+1)-valent linking group.

Suitable examples of the (m+1)-valent linking group in L^{A2} include an (m+1)-valent hydrocarbon group having 1 to 10 carbon atoms, which may have a substituent, in which a part of carbon atoms constituting the hydrocarbon group may be substituted with a heteroatom.

Here, as the substituent which may be included in the hydrocarbon group, an alkyl group is preferable, a linear alkyl group having 1 to 4 carbon atoms is more preferable, and a methyl group or an ethyl group is still more preferable.

In addition, examples of the heteroatom include a silicon atom, an oxygen atom, and a nitrogen atom.

In Formula (A-1), m represents an integer of 1 or more, and is preferably an integer of 2 or more and more preferably an integer of 3 or more from the viewpoint that the alignment degree of the light absorption anisotropic film is more excellent, and is preferably an integer of 18 or less, more preferably an integer of 12 or less, still more preferably an integer of 9 or less, and particularly preferably an integer of 6 or less from the viewpoint that the alignment defects can be further suppressed.

Specific examples of the repeating unit A include repeating units corresponding to monomers represented by Formulae K-1 to K-33. In Examples described later, the monomer represented by Formula K-1 is referred to as “monomer K-1”. The same applies to other monomers.

The monomer represented by Formula K-29 is a mixture of monomers having different numbers of —(O—Si(CH₃)₂)—, and thus the average value thereof is represented as n≈11. The same applies to the monomer represented by K-30.

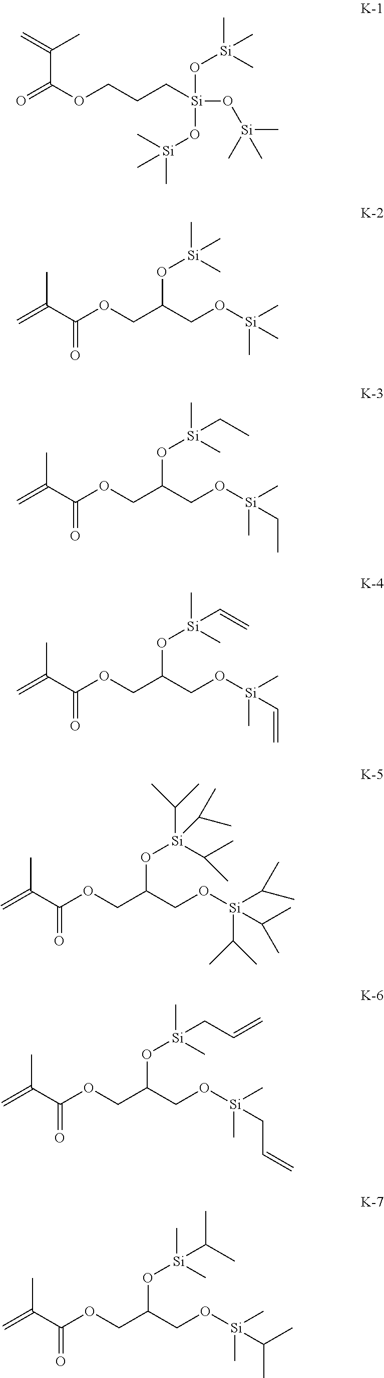

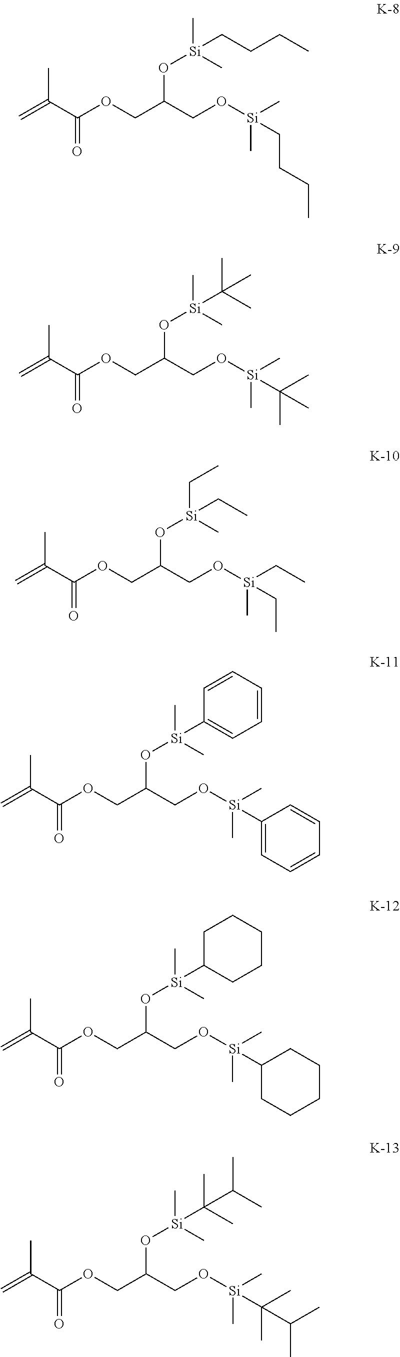

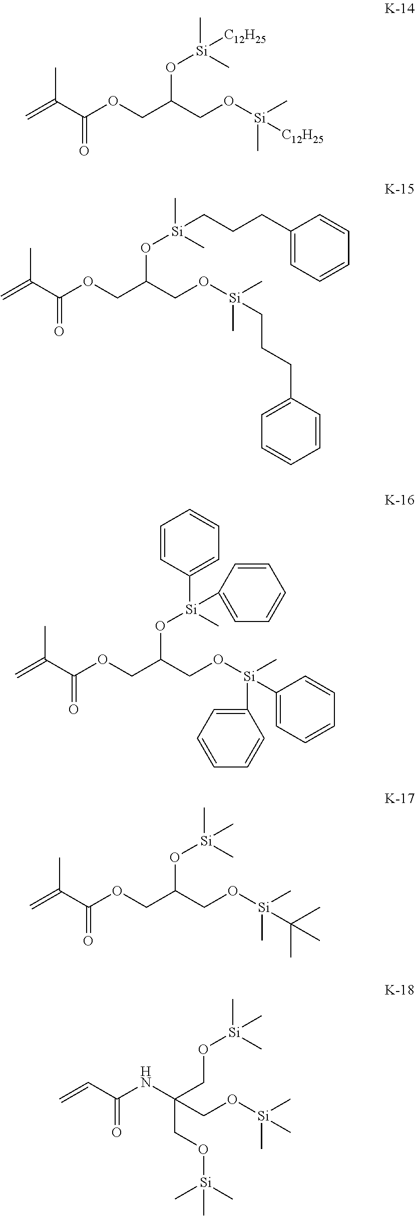

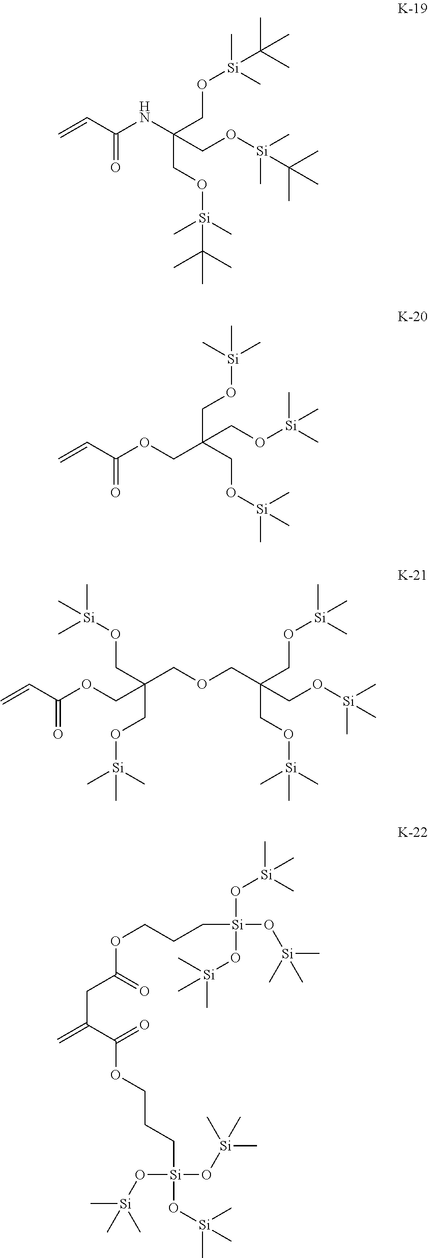

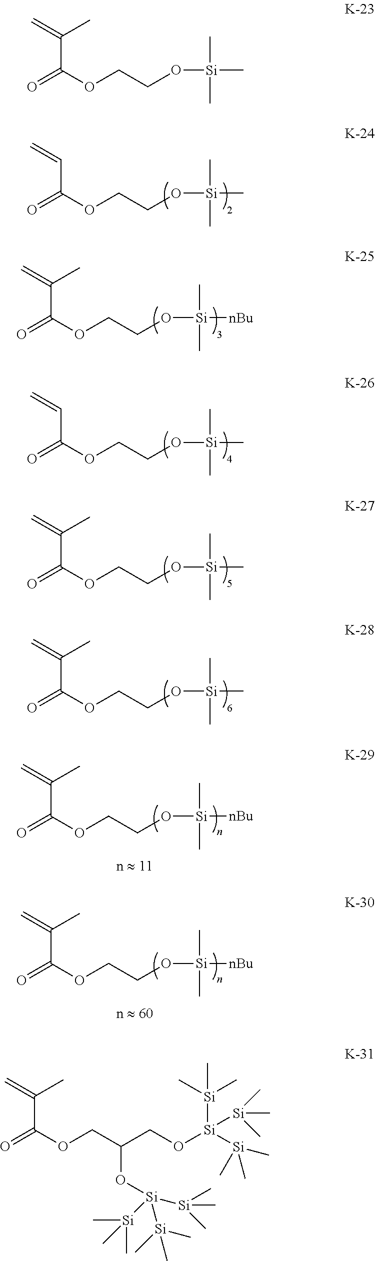

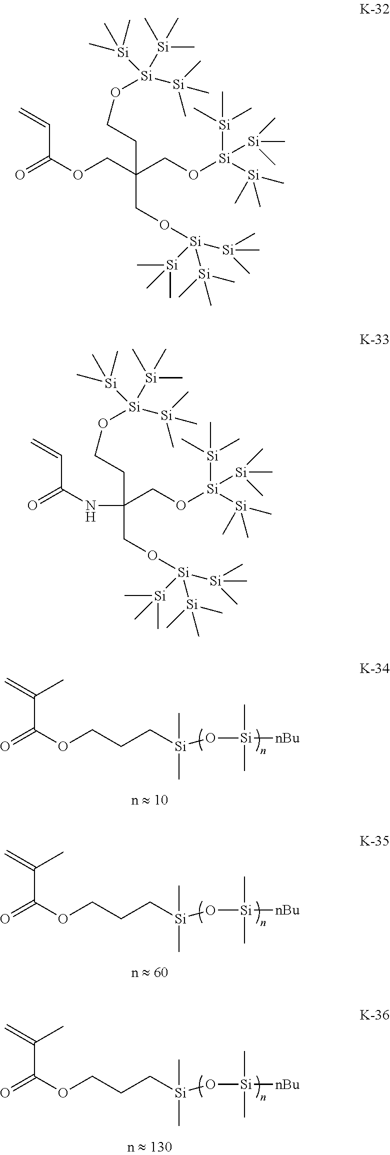

The content of the repeating unit A is preferably in a range of 10% to 90% by mass, more preferably in a range of 15% to 80% by mass, and still more preferably in a range of 20% to 70% by mass with respect to all repeating units (100% by mass) of the specific polymer. In a case where the content of the repeating unit A is within the above range, the effect of the present invention is more excellent, and the alignment degree of the light absorption anisotropic film is more excellent.

The repeating unit A may be contained alone or in combination of two or more kinds thereof in the specific polymer. In a case where the specific polymer has two or more kinds of repeating units A, the content of the repeating unit A denotes the total content of the repeating units A.

### <Repeating Unit B>

The repeating unit B is a repeating unit represented by Formula (B).

It is considered that the repeating unit B having an amide structure can improve the compatibility between the copolymer and the liquid crystal compound. As a result, it is assumed that a light absorption anisotropic film with further less alignment defects is obtained.

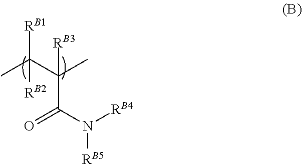

In Formula (B), R^{B1}, R^{B2}, and R^{B3} each independently represent a hydrogen atom, a halogen atom, a cyano group, an alkyl group, an alkenyl group, or an aryl group.

Examples of the alkyl group in R^{B1}, R^{B2}, and R^{B3} include a linear alkyl group having 1 to 18 carbon atoms (preferably 1 to 6 carbon atoms and more preferably 1 to 4 carbon atoms), and a branched or cyclic alkyl group having 3 to 18 carbon atoms (preferably 3 to 9 carbon atoms and more preferably 3 to 6 carbon atoms). Specific examples thereof include a methyl group, an ethyl group, a propyl group, a butyl group, an isopropyl group, a tert-butyl group, and a cyclohexyl group.

Examples of the alkenyl group in R^{B1}, R^{B2}, and R^{B3} include a linear alkenyl group having 2 to 18 carbon atoms, and a branched alkenyl group having 3 to 18 carbon atoms. Specific examples thereof include a vinyl group, an aryl group, a 2-butenyl group, and a 3-pentenyl group.

Examples of the aryl group in R^{B1}, R^{B2}, and R^{B3} include an aryl group having preferably 6 to 30 carbon atoms (preferably 6 to 20 carbon atoms and more preferably 6 to 12 carbon atoms). Specific examples thereof include a phenyl group, a 2,6-diethylphenyl group, a 3,5-ditrifluoromethylphenyl group, a styryl group, a naphthyl group, and a biphenyl group.

R^{B1}, R^{B2}, and R^{B3} are preferably a hydrogen atom or an alkyl group, more preferably a hydrogen atom or a methyl group, and still more preferably a hydrogen atom.

In Formula (B), R^{B4} and R^{B5} each independently represent a hydrogen atom or a substituent. In a case where R^{B4} and R^{B5} are a substituent. R^{B4} and R^{B5} may be linked to each other to form a ring.

The total of molecular weights of R^{B4} and R^{B5} is preferably 200 or less, more preferably 100 or less, and still more preferably 70 or less. The details of the reason for this are not clear, but it is presumed as follows. That is, in a case where the total of molecular weights is 100 or less, it is considered that the steric hindrance of the substituent disappears, the specific copolymer does not hinder the alignment of the liquid crystal compound and the dichroic substance, and as a result, the degree of order of the liquid crystal increases and the alignment degree of the light absorption anisotropic film is more excellent.

The lower limit of the total of molecular weights of R^{B4} and R^{B5} is preferably 2 or more.

As the substituent represented by R^{B4} and R^{B5}, from the viewpoint that the effect of the present invention is more excellent, an organic group is preferable, an organic group having 1 to 15 carbon atoms is more preferable, an organic group having 1 to 12 carbon atoms is still more preferable, and an organic group having 1 to 8 carbon atoms is particularly preferable.

Examples of the above-described organic group include a linear, branched, or cyclic alkyl group, an aromatic hydrocarbon group, and a heterocyclic group.

The number of carbon atoms in the alkyl group is preferably 1 to 15, more preferably 1 to 12, and still more preferably 1 to 8.

The carbon atom in the alkyl group may be substituted with —O—, —Si(CH₃)₂—, —(Si(CH₃)₂O)_{g}—, —(OSi(CH₃)₂)_{g}— (g represents an integer of 1 to 10), —N(Z)—, —C(Z)═C(Z¹)—, —C(Z)═N—, —N═C(Z)—, —C(O)—, —OC(O)—, —C(O)O—, —O—C(O)O—, —N(Z)C(O)—, —C(O)N(Z)—, —C(Z)═C(Z¹)—C(O)O—, —O—C(O)—C(Z)═C(Z¹)—, —C(Z)═N—, —N═C(Z)—, —C(Z)═C(Z¹)—C(O)N(Z²)—, —N(Z²)—C(O)—C(Z)═C(Z¹)—, —C(Z)═C(Z¹)—C(O)—S—, —S—C(O)—C(Z)═C(Z¹)—, —C(Z)═N—N═C(Z¹)— (Z, Z¹, and Z² each independently represent hydrogen, an alkyl group having 1 to 4 carbon atoms, a cycloalkyl group, an aryl group, a cyano group, or a halogen atom), —C≡C—, —N═N—, —S—, —C(S)—, —S(O)—, —SO₂—, —(O)S(O)O—, —O(O)S(O)O—, —SC(O)—, —C(O)S—, and a group obtained by combining two or more of these groups. Among the groups with which the carbon atom in the alkyl group may be substituted, from the viewpoint that the effect of the present invention is more excellent, —O—, —C(O)—, —N(Z)—, —OC(O)—, or —C(O)O— is preferable.

The hydrogen atom in the alkyl group may be substituted with a halogen atom, a cyano group, an aryl group, a nitro group, —OZ^{H1}, —C(O)Z^{H1}, —C(O)OZ^{H1}, —OC(O)Z^{H1}, —OC(O)OZ^{H1}, —NZ^{H1}Z^{H2}, —NZ^{H1}C(O)Z^{H2}, —NZ^{H1}C(O)OZ^{H2}, —C(O)NZ^{H1}Z^{H2}, —OC(O)NZ^{H1}Z^{H2}, —NZ^{H1}C(O)NZ^{H2}OZ^{H3}, —SZ^{H1}, —C(S)Z^{H1}, —C(O)SZ^{H1}, or —SC(O)Z^{H1}, Z^{H1}, Z^{H2}, and Z^{H3} each independently represent a hydrogen atom, a halogen atom, an alkyl group having 1 to 10 carbon atoms, a cyano group, or a nitro group. Among the groups with which the hydrogen atom in the alkyl group may be substituted, from the viewpoint that the effect of the present invention is more excellent, —OH, —COOH, or an aryl group (preferably, a phenyl group) is preferable.

The hydrogen atom in the aromatic hydrocarbon group and the hydrogen atom in the heterocyclic group may be substituted with a halogen atom, a cyano group, an alkyl group having 1 to 10 carbon atoms, a cyano group, a nitro group, —OZ^{H1}, —C(O)Z^{H1}, —C(O)OZ^{H1}, —OC(O)Z^{H1}, —OC(O)OZ^{H1}, —NZ^{H1}Z^{H2}, —NZ^{H1}C(O)Z^{H2}, —NZ^{H1}C(O)OZ^{H2}, —C(O)NZHtZ^{H2}, —OC(O)NZ^{H1}Z^{H2}, —NZ^{H1}C(O)NZ^{H2}OZ^{H3}, —SZ^{H1}, —C(S)Z^{H1}, —C(O)SZ^{H1}, —SC(O)Z^{H1}, or —B(OH)₂. Z^{H1}, Z^{H2}, and Z^{H3} each independently represent a hydrogen atom, a halogen atom, an alkyl group having 1 to 10 carbon atoms, a cyano group, or a nitro group. Among the groups with which the hydrogen atom in the aromatic hydrocarbon group and the hydrogen atom in the heterocyclic group may be substituted, —OH or —B(OH)₂ is preferable from the viewpoint that the effect of the present invention is more excellent.

From the viewpoint that the effect of the present invention is more excellent, it is preferable that R^{B4} and R^{B5} each independently represent a hydrogen atom or an organic group having 1 to 15 carbon atoms. Suitable aspects of the organic group are as described above.

From the viewpoint that the effect of the present invention is more excellent, at least one of R^{B4} or R^{B5} is preferably a substituent and more preferably an organic group having 1 to 15 carbon atoms.

The ring formed by linking R^{B4} and R^{B5} to each other is a heterocyclic ring having a nitrogen atom in Formula (B), and may further have a heteroatom such as an oxygen atom, a sulfur atom, and a nitrogen atom in the ring.

From the viewpoint that the effect of the present invention is more excellent, the ring formed by linking R^{B4} and R^{B5} to each other is preferably a 4- to 8-membered ring, more preferably a 5- to 7-membered ring, and still more preferably a 5- or 6-membered ring.

From the viewpoint that the effect of the present invention is more excellent, the number of carbon atoms constituting the ring formed by linking R^{B4} and R^{B5} to each other is preferably 3 to 7 and more preferably 3 to 6.

The ring formed by linking R^{B4} and R^{B5} to each other may or may not have aromaticity, but it is preferable that the ring does not have aromaticity from the viewpoint that the effect of the present invention is more excellent.

Specific examples of the ring formed by linking R^{B4} and R^{B5} to each other include the following groups.

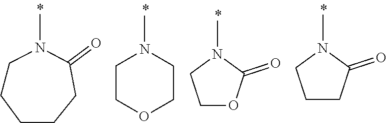

Specific examples of the repeating unit B will be shown below, but the repeating unit B is not limited to the following structures.

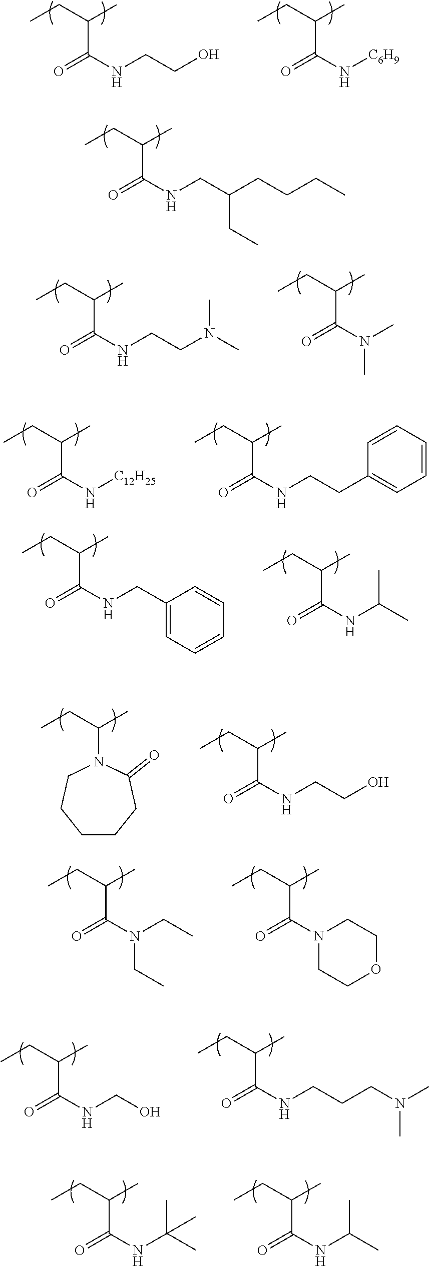

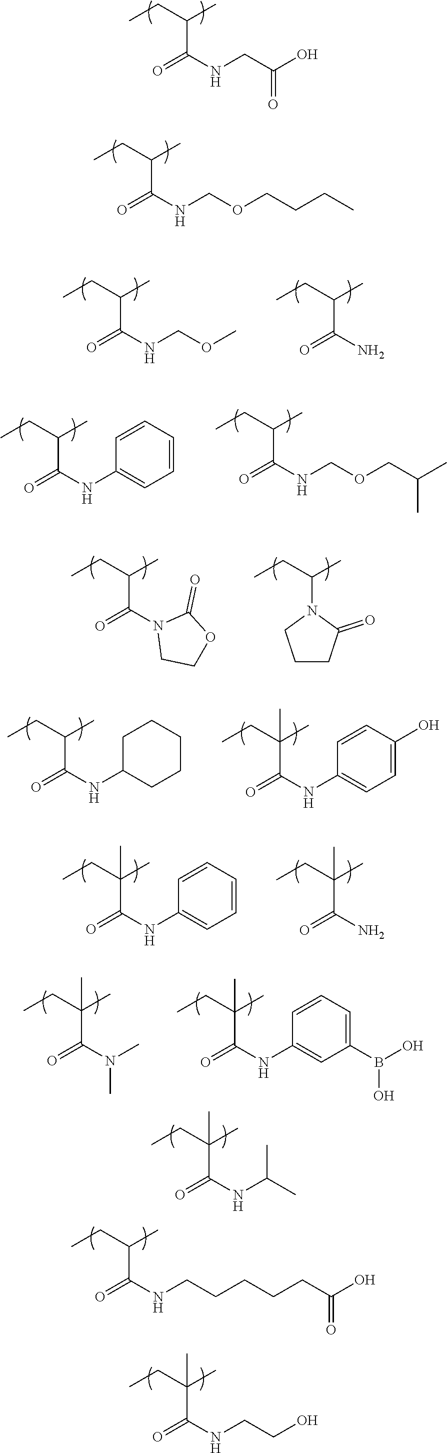

In a case where the specific polymer has the repeating unit B, the content of the repeating unit B is preferably in a range of 2% to 75% by mass, more preferably in a range of 3% to 70% by mass, and still more preferably in a range of 5% to 65% by mass with respect to all the repeating units (100% by mass) of the specific polymer. In a case where the content of the repeating unit B is within the above range, the effect of the present invention is more excellent, and the alignment degree of the light absorption anisotropic film is more excellent.

The repeating unit B may be contained alone or in combination of two or more kinds thereof in the specific polymer. In a case where the specific polymer has two or more kinds of repeating units B, the content of the repeating unit B denotes the total content of the repeating units B.

### <Repeating Unit D>

The repeating unit D is a repeating unit represented by Formula (D).

The repeating unit D has a predetermined spacer group (Sp^{D1} in Formula (D) described later) and a linking group consisting of a predetermined ring structure (Cy^{D} in Formula (D) described later). As a result, it is considered that the viscosity of the liquid crystal composition is improved and the cissing is further suppressed.

Further, in a case where the repeating unit D has a predetermined hydrogen bonding group (D in Formula (D)), a multimer is formed via a hydrogen bond, an air interface layer having high planarity suitable for aligning the liquid crystal compound and the dichroic substance is obtained, and thus the alignment degree of a light absorption anisotropic film to be formed is considered to be further improved.

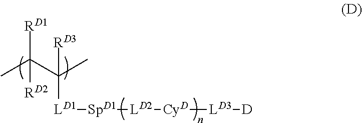

In Formula (D), R^{D1}, R^{D2}, and R^{D3} each independently represent a hydrogen atom, a halogen atom, a cyano group, an alkyl group, an alkenyl group, or an aryl group.

Specific examples and suitable aspects of the alkyl group, the alkenyl group, and the aryl group in R^{D1}, R^{D2}, and R^{D3} are the same as those of the alkyl group, the alkenyl group, and the aryl group in R^{B1}, R^{B2}, and R^{B3} in Formula (B).

R^{D1}, R^{D2}, and R^{D3} are preferably a hydrogen atom or an alkyl group, more preferably a hydrogen atom or a methyl group, and still more preferably a hydrogen atom.

In Formula (D), L^{D1} represents a single bond, —COO—, or —CO— and is preferably —CO—.

In Formula (D), Sp^{D1} represents a divalent hydrocarbon group having 1 to 20 carbon atoms. The divalent hydrocarbon group may be linear or branched.

Examples of the divalent hydrocarbon group having 1 to 20 carbon atoms in Sp^{D1} include a divalent aliphatic hydrocarbon group having 1 to 20 carbon atoms, a divalent alicyclic hydrocarbon group having 3 to 20 carbon atoms, a divalent aromatic hydrocarbon group having 6 to 20 carbon atoms, and a divalent aromatic heterocyclic group having 6 to 20 carbon atoms. Among these, a divalent aliphatic hydrocarbon group having 1 to 20 carbon atoms is preferable.

Here, as the divalent aliphatic hydrocarbon group having 1 to 20 carbon atoms, an alkylene group having 1 to 15 carbon atoms is preferable and an alkylene group having 1 to 8 carbon atoms is more preferable, and specific suitable examples thereof include a methylene group, an ethylene group, a propylene group, a butylene group, a pentylene group, a hexylene group, a methylhexylene group, and a heptylene group.

In addition, one —CH₂— or two or more —CH₂—'s which are not adjacent to each other among —CH₂—'s constituting a part of the hydrocarbon group in Sp^{D1}, may be each independently substituted with —O—, —S—, —NH—, or —N(Q)-. Q represents a substituent, examples thereof include the above-described substituent W, and an alkyl group, an alkoxy group, or a halogen atom is preferable.

In Formula (D), L^{D2} and L^{D3} each independently represent a single bond or a divalent linking group.

Examples of the divalent linking group as L^{D2} and L^{D3} include —C(O)O—, —O—, —S—, —C(O)NR^{L1}—, —SO₂—, and —NR^{L1}R^{L2}—. In the formula, R^{L1} and R^{L2} each independently represent a hydrogen atom or an alkyl group having 1 to 6 carbon atoms, which may have a substituent. Examples of the substituent which may be included in the alkyl group having 1 to 6 carbon atoms include the above-described substituent W, and an alkyl group, an alkoxy group, or a halogen atom is preferable.

In Formula (D), Cy^{D} represents a divalent linking group including a mesogen group.

The mesogen group is a group indicating the main skeleton of liquid crystal molecules contributing to the formation of the liquid crystal. A liquid crystal molecule exhibits liquid crystallinity which is in an intermediate state (mnesophase) between a crystal state and an isotropic liquid state. The mesogen group is not particularly limited, and for example, particularly description on pages 7 to 16 of “Flussige Kristalle in Tabellen II” (VEB Deutsche Verlag fur Grundstoff Industrie, Leipzig, 1984) and particularly description in Chapter 3 of “Liquid Crystal Handbook” (Maruzen, 2000) edited by Liquid Crystal Handbook Editing Committee can be referred to.

The mesogen group preferably has 1 to 10 cyclic structures and more preferably has 1 to 7 cyclic structures. Specific examples of the cyclic structure include an aromatic hydrocarbon group, a heterocyclic group, and an alicyclic group.

The divalent linking group including a mesogen group in Cy^{D} is preferably a divalent mesogen group. Examples of the divalent mesogen group include a divalent aromatic hydrocarbon group, a divalent heterocyclic group, and a divalent alicyclic group.

Specific examples of the divalent aromatic hydrocarbon group include a phenylene group, a naphthylene group, a fluorene-diyl group, an anthracene-diyl group, and a tetracene-diyl group.

The divalent heterocyclic group may be any of aromatic or non-aromatic, but a divalent aromatic heterocyclic group is preferable as the divalent heterocyclic group from the viewpoint of further improving the alignment degree.

Examples of atoms other than carbon, constituting the divalent aromatic heterocyclic group, include a nitrogen atom, a sulfur atom, and an oxygen atom. In a case where the aromatic heterocyclic group has a plurality of atoms other than carbon, constituting a ring, these atoms may be the same or different from each other.

Specific examples of the divalent aromatic heterocyclic group include a pyridylene group (pyridine-diyl group), a pyridazine-diyl group, an imidazole-diyl group, a thienylene group (thiophene-diyl group), a quinolylene group (quinoline-diyl group), an isoquinolylene group (isoquinoline-diyl group), an oxazole-diyl group, a thiazole-diyl group, an oxadiazole-diyl group, a benzothiazole-diyl group, a benzothiadiazole-diyl group, a phthalimido-diyl group, a thienothiazole-diyl group, a thiazolothiazole-diyl group, a thienothiophene-diyl group, and a thienooxazole-diyl group.

Specific examples of the divalent alicyclic group include a cyclopentylene group and a cyclohexylene group, and the carbon atoms thereof may be substituted with —O—, —Si(CH₃)₂—, —N(Z^{M})— (Z^{M} represents hydrogen, an alkyl group having 1 to 4 carbon atoms, a cycloalkyl group, an aryl group, a cyano group, or a halogen atom), —C(O)—, —S—, —C(S)—, —S(O)—, —SO₂—, or a group obtained by combining two or more of these groups.

Among these, from the viewpoint that the effect of the present invention is more excellent and the alignment degree of the light absorption anisotropic film is more excellent, Cy^{D} is preferably a divalent linking group represented by any one of Formulae (Cy^{D}-1) to (Cy^{D}-15). In the following formulae, * represents a bonding position to L^{D2} or L^{D3}, and carbon atoms constituting ring structures in the following formulae may be substituted with a heteroatom or may have a substituent. Further, examples of the substituents which may be included in the carbon atoms constituting the ring structures include the above-described substituent W. Among these, an alkyl group, an alkoxy group, or a halogen atom is preferable.

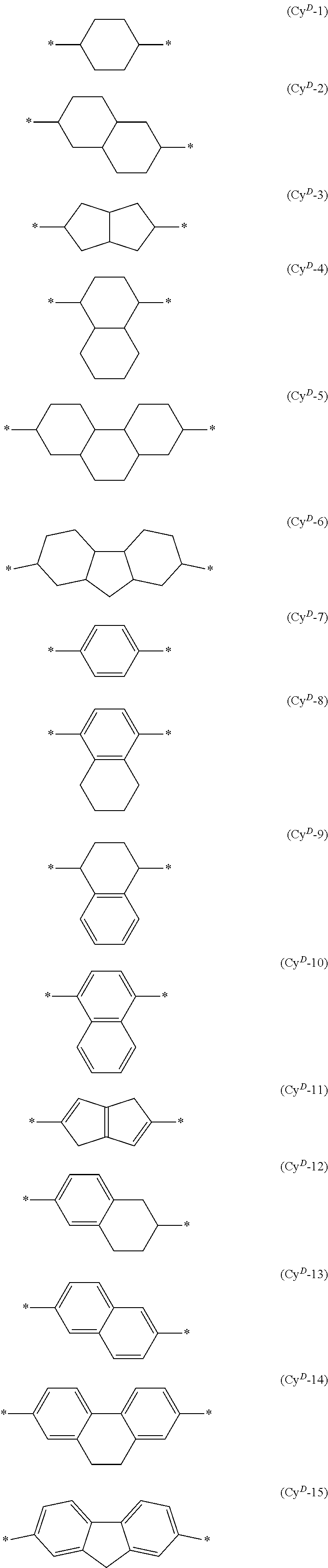

Specific examples of the divalent linking group represented by any of Formulae (Cy^{D}-1) to (Cy^{D}-15) include a 1,4-phenylene group, a 1,4-cyclohexylene group, a 1,4-cyclohexenyl group, a tetrahydropyran-2,5-diyl group, a 1,4-piperazine group, a 1,4-piperidine group, a 1,3-dioxane-2,5-diyl group, a tetrahydrothiopyran-2,5-diyl group, a 1,4-bicyclo(2,2,2)octylene group, a decahydronaphthalene-2,6-diyl group, a pyridine-2,5-diyl group, a pyrimidine-2,5-diyl group, a pyrazine-2,5-diyl group, a 1,2,3,4-tetrahydronaphthalene-2,6-diyl group, a 2,6-naphthylene group, a phenanthrene-2,7-diyl group, a 9,10-dihydrophenanthrene-2,7-diyl group, a 1,2,3,4,4a,9,10a-octahydrophenanthrene-2,7-diyl group, a 9-fluorenone-2,7-diyl group, a fluorene-2,7-diyl group, a thienothiophene-3,6-diyl group, a carbazole-3,6-diyl group, and a carbazole-2,7-diyl group.

From the viewpoint that the alignment degree of the light absorption anisotropic film is more excellent, Cy^{D} in Formula (D) is preferably a divalent linking group represented by any of Formula (Cy^{D}-1), (Cy^{D}-4), (Cy^{D}-7), (Cy^{D}-10), or (Cy^{D}-13) and more preferably a divalent linking group represented by any of Formula (Cy^{D}-7) or Formula (Cy^{D}-13).

In Formula (D), D represents a hydrogen bonding group formed of a hydrogen atom and a non-metal atom of Groups 14 to 16 (periodic table). Provide that the non-metal atom may have a substituent.

Here, examples of the non-metal atom of Groups 14 to 16 include an oxygen atom, a sulfur atom, a nitrogen atom, and a carbon atom.

In addition, examples of the substituent which may be included in the non-metal atom (particularly, a nitrogen atom and a carbon atom) include a halogen atom, an alkyl group, an alkoxy group, an alkyl-substituted alkoxy group, a cyclic alkyl group, an aryl group (such as a phenyl group or a naphthyl group), a cyano group, an amino group, a nitro group, an alkylcarbonyl group, a sulfo group, and a hydroxyl group.

Examples of such a hydrogen bonding group include a hydrogen bond-donating group and a hydrogen bond-accepting group.

Specific examples of the hydrogen bond-donating group include an amino group, an amide group, a urea group, a urethane group, a sulfonylamino group, a sulfo group, a phospho group, a hydroxy group, a mercapto group, a carboxy group, a methylene group substituted with an electron withdrawing group, and a methine group substituted with an electron withdrawing group. Among these, a carboxy group or an amide group is preferable. Specific examples of the hydrogen bond-accepting group include a heteroatom having an unshared electron pair on a heterocycle, a hydroxy group, an aldehyde, a ketone, a carboxy group, carboxylic acid ester, carboxylic acid amide, a lactone, a lactam, sulfonic acid amide, a sulfo group, a phospho group, phosphoric acid amide, urethane, urea, an ether structure (particularly, a polymer structure having an oxygen atom contained in a polyether structure), an aliphatic amine, and an aromatic amine. Among these, a carboxy group or an amide group is preferable.

In Formula (D), n represents an integer of 1 to 3. In a case where n is 2 or 3, a plurality of L^{D2}'s may be the same or different from each other and a plurality of Cy^{D}'s may be the same or different from each other.

In the present invention, n in Formula (D) is preferably 1 or 2 from the viewpoint that the haze of the light absorption anisotropic film is less difficult to observe (the haze is enhanced) and more preferably 2 from the viewpoint of further suppressing cissing during the formation of the light absorption anisotropic film.

In the present invention, from the viewpoint of further increasing the alignment degree of the light absorption anisotropic film to be formed, it is preferable that the repeating unit D is a repeating unit in which L^{D3} in Formula (D) represents a single bond and D represents —COOH, —NHCOR², or —CONHR³.

Here, R² and R³ each independently represent an alkyl group or an alkenyl group, each of which has 1 to 10 carbon atoms. The alkyl group and the alkenyl group may be linear or branched. Provide that one —CH₂— or two or more —CH₂—'s which are not adjacent to each other among —CH₂—'s constituting a part of the alkyl group and the alkenyl group may be substituted with —O—.

In addition, in the present invention, from the viewpoint that the haze of the light absorption anisotropic film is less difficult to observe, it is preferable that the repeating unit D is a repeating unit in which L^{D3} in Formula (D) represents a single bond and D represents —NHCOR⁴.

Here, R⁴ represents an alkyl group or an alkenyl group, each of which has 1 to 3 carbon atoms. The alkyl group and the alkenyl group may be linear or branched. Provide that one —CH₂— or two or more —CH₂—'s which are not adjacent to each other among —CH₂—'s constituting a part of the alkyl group and the alkenyl group may be substituted with —O—.

Examples of the monomer forming the repeating unit D include monomers represented by the following formulae. In the following formulae, Me represents a methyl group, and Ac represents an acetyl group.

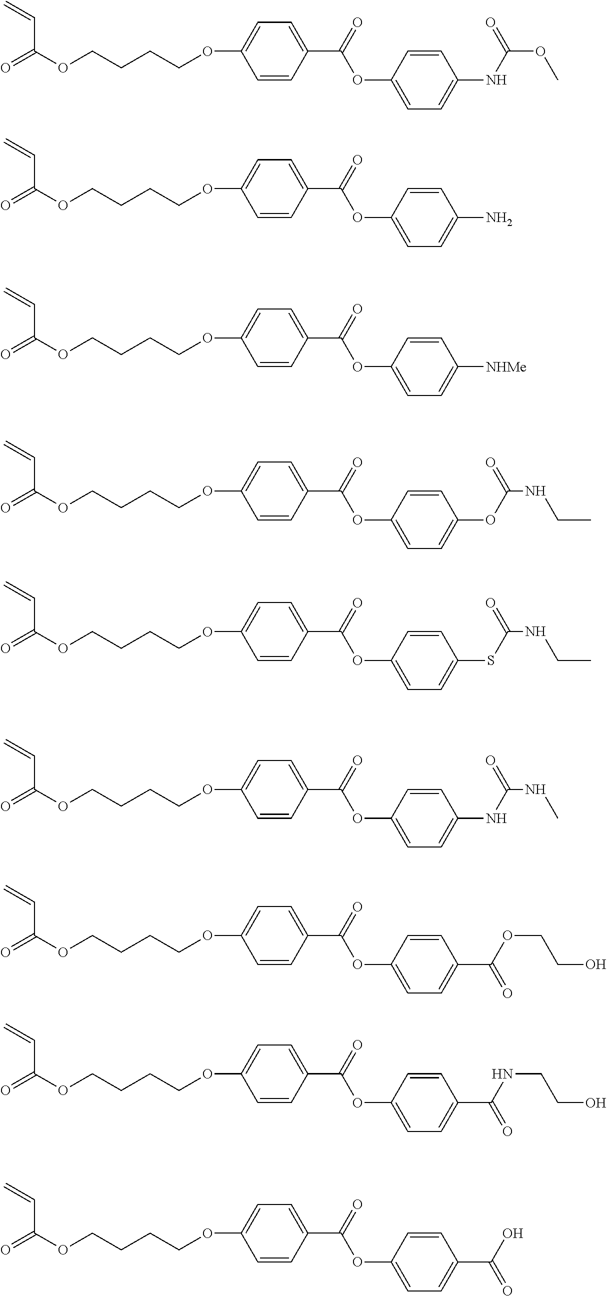

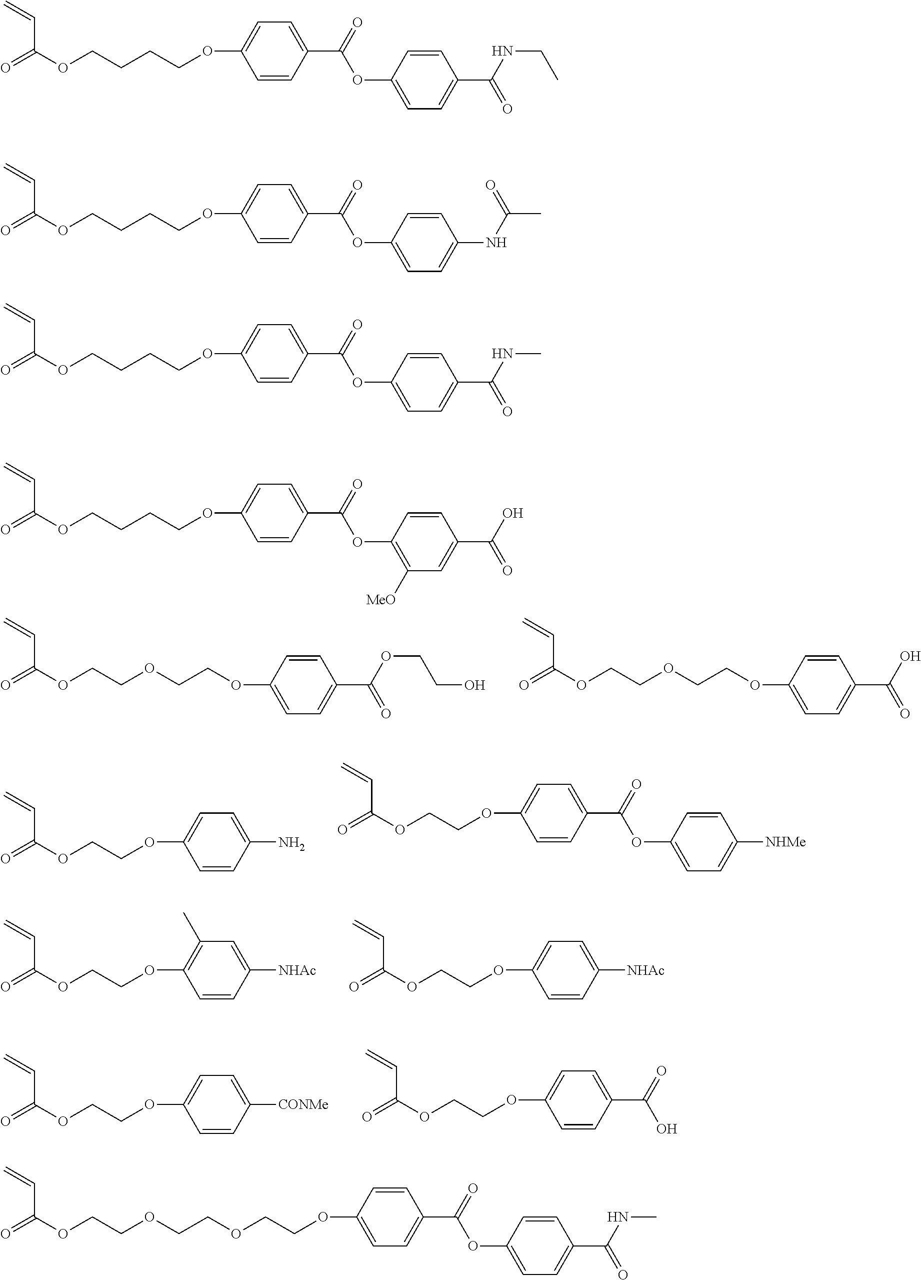

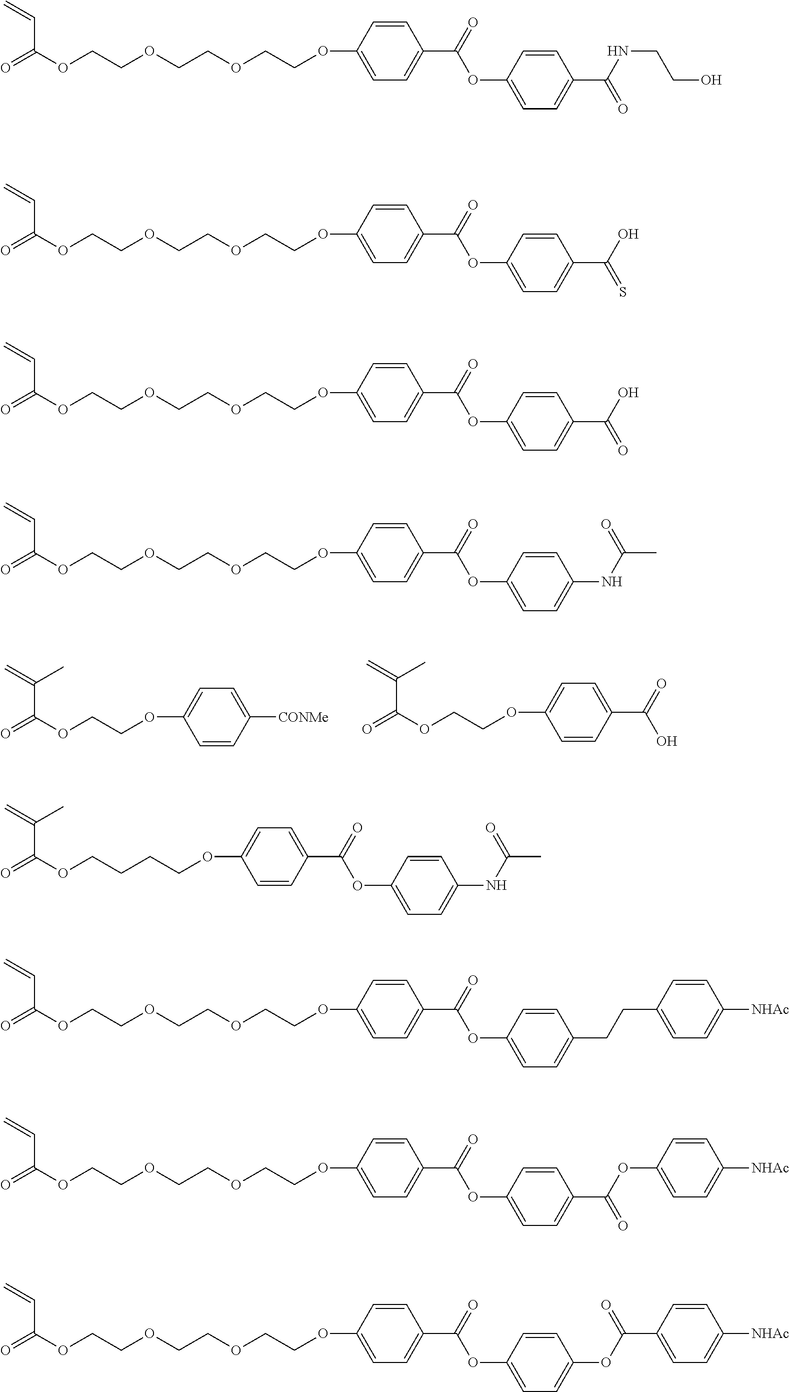

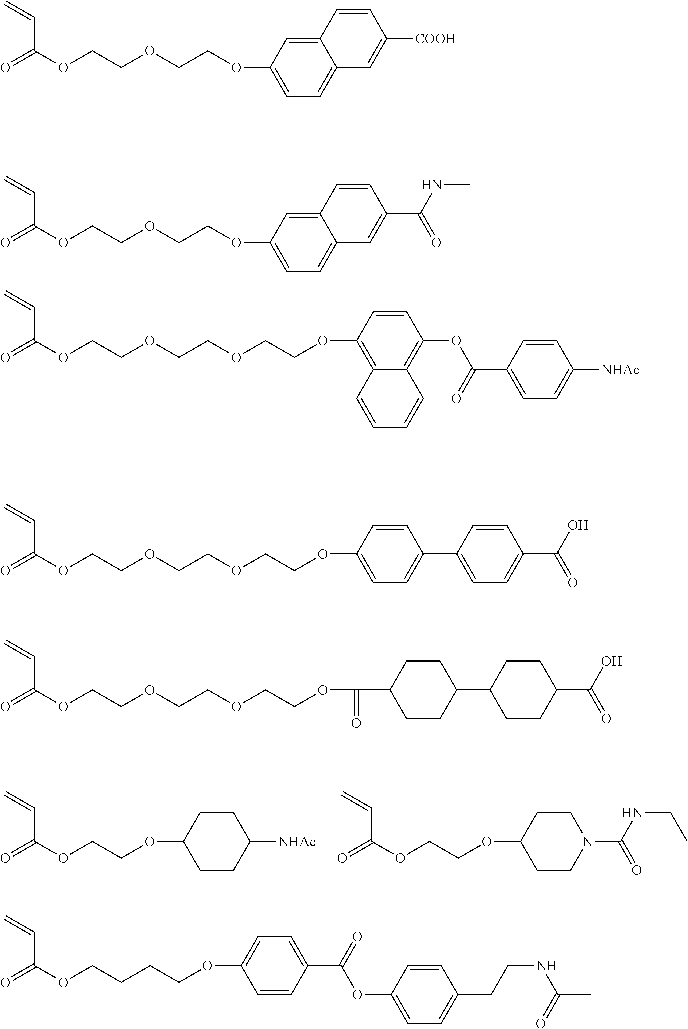

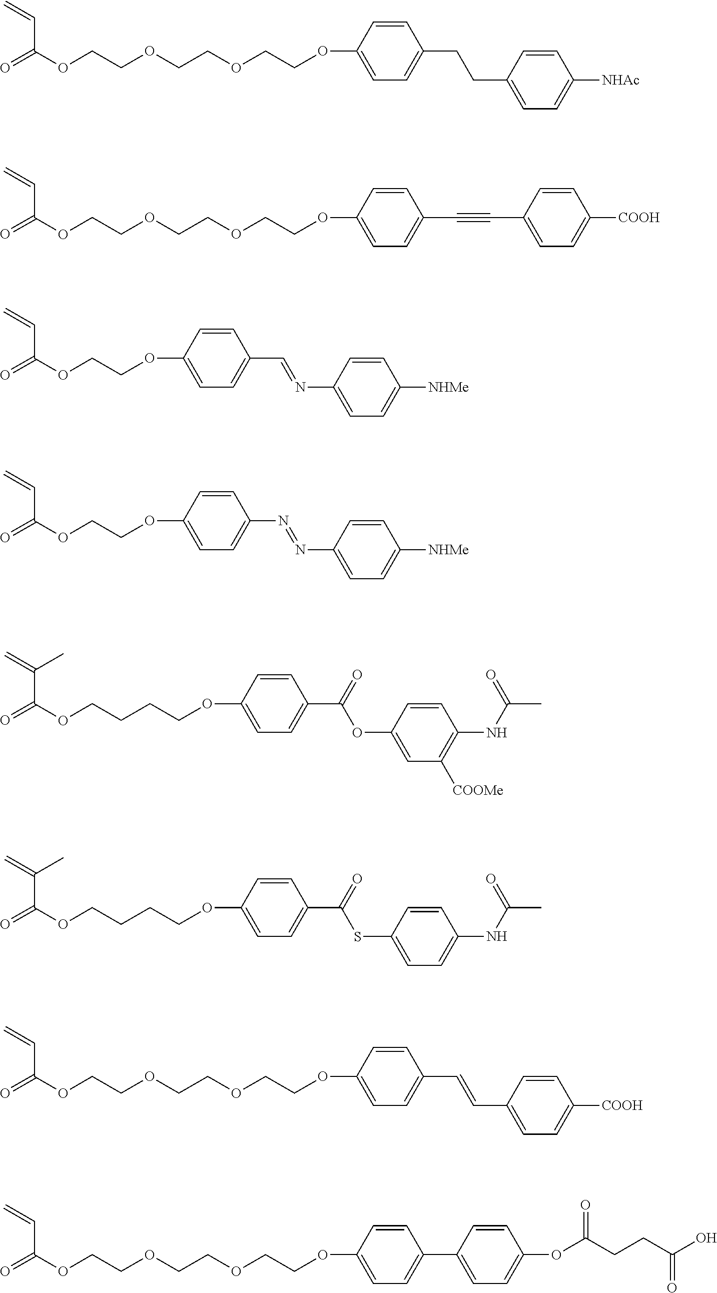

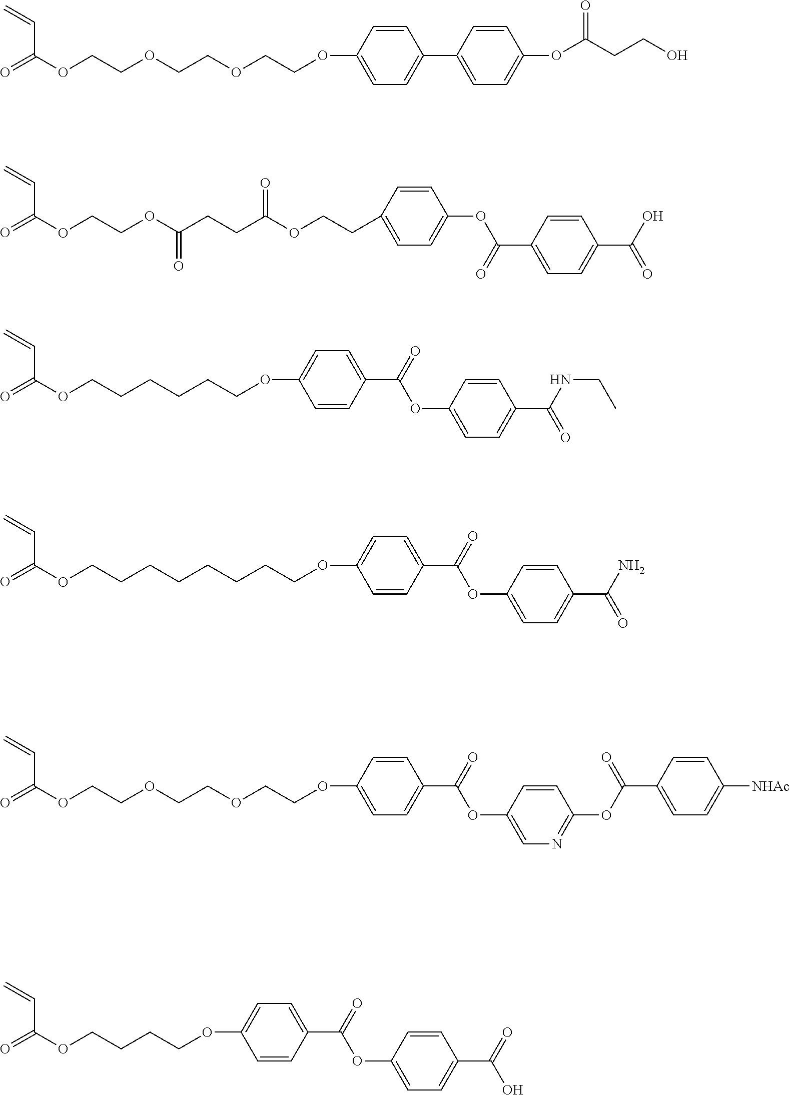

In a case where the specific polymer has the repeating unit D, the content of the repeating unit D is preferably in a range of 5% to 85% by mass, more preferably in a range of 10% to 75% by mass, and still more preferably in a range of 20% to 70% by mass with respect to all the repeating units (100% by mass) of the specific polymer. In a case where the content of the repeating unit D is within the above range, the effect of the present invention is more excellent, and the alignment degree of the light absorption anisotropic film is more excellent.

The repeating unit D may be contained alone or in combination of two or more kinds thereof in the specific polymer. In a case where the specific polymer has two or more kinds of repeating units D, the content of the repeating unit D denotes the total content of the repeating units D.

### <Repeating Unit X>

The specific polymer may have a repeating unit X represented by Formula (X).

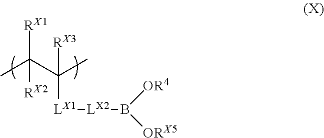

In Formula (X), R^{X1}, R^{X2}, and R^{X3} each independently represent a hydrogen atom, an alkyl group, an alkenyl group, or an aryl group.

Specific examples and suitable aspects of the alkyl group, the alkenyl group, and the aryl group in R^{X1}, R^{X2}, and R^{X3} are the same as those of the alkyl group, the alkenyl group, and the aryl group in R^{B1}, R^{B2}, and R^{B3} in Formula (B).

R^{X1}, R^{X2}, and R^{X3} are preferably a hydrogen atom or an alkyl group, more preferably a hydrogen atom or a methyl group, and still more preferably a hydrogen atom.

L^{X1} represents a single bond or —CO—, and —CO— is preferable.

In Formula (X), L^{X2} represents a divalent aliphatic hydrocarbon group having 1 to 20 carbon atoms. The aliphatic hydrocarbon group may be linear or branched.

As the divalent aliphatic hydrocarbon group having 1 to 20 carbon atoms, an alkylene group having 1 to 15 carbon atoms is preferable and an alkylene group having 1 to 8 carbon atoms is more preferable, and specific suitable examples thereof include a methylene group, an ethylene group, a propylene group, a butylene group, a pentylene group, a hexylene group, a methylhexylene group, and a heptylene group.

One or more —CH₂—'s among —CH₂—'s constituting a part of the hydrocarbon group in L^{X2} may be each independently substituted with —O—, —C(O)O—, or a phenylene group.

In Formula (X), B represents a boron atom.

In Formula (X), R^{X4} and R^{X5} each independently represent a hydrogen atom, an alkyl group which may have a substituent, an aryl group which may have a substituent, or a heteroaryl group which may have a substituent. Among these, from the viewpoint that at least one of the adhesiveness or the alignment degree is more excellent, a hydrogen atom or an alkyl group which may have a substituent is preferable.

The number of carbon atoms in the alkyl group is not particularly limited, but is preferably in a range of 1 to 10 and more preferably in a range of 1 to 5. Examples of the alkyl group include a methyl group, an ethyl group, and a propyl group.

The number of carbon atoms in the aryl group is not particularly limited, but is preferably in a range of 4 to 20 and more preferably in a range of 6 to 12. Examples of the aryl group include a phenyl group.

The number of carbon atoms in the heteroaryl group is not particularly limited, but is preferably in a range of 3 to 10 and more preferably in a range of 3 to 5. Examples of a heteroatom contained in the heteroaryl group include an oxygen atom, a nitrogen atom, and a sulfur atom.

R^{X4} and R^{X5} may be bonded to each other to form a ring.

Specific examples of the repeating unit X will be shown below, but the repeating unit X is not limited to the following structures.

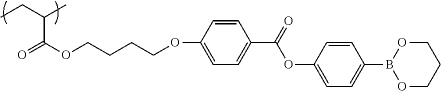

In a case where the specific polymer has the repeating unit X, the content of the repeating unit X is preferably in a range of 3% to 75% by mass, more preferably in a range of 5% to 70% by mass, and still more preferably in a range of 10% to 60% by mass with respect to all the repeating units (100% by mass) of the specific polymer. In a case where the content of the repeating unit X is within the above range, the effect of the present invention is more excellent, and the alignment degree of the light absorption anisotropic film is more excellent.

The repeating unit X may be contained alone or in combination of two or more kinds thereof in the specific polymer. In a case where the specific polymer has two or more kinds of repeating units X, the content of the repeating unit X denotes the total content of the repeating units X.

### <Repeating Unit Y>

The specific polymer may have a repeating unit Y represented by Formula (Y).

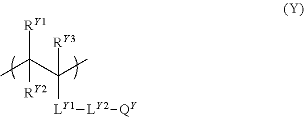

In Formula (Y), R^{Y1}, R^{Y2}, and R^{Y3} each independently represent a hydrogen atom, an alkyl group, an alkenyl group, or an aryl group.

Specific examples and suitable aspects of the alkyl group, the alkenyl group, and the aryl group in R^{Y1}, R^{Y2}, and R^{Y3} are the same as those of the alkyl group, the alkenyl group, and the aryl group in R^{B1}, R^{B2}, and R^{B3} in Formula (B).

R^{Y1}, R^{Y2}, and R^{Y3} are preferably a hydrogen atom or an alkyl group, more preferably a hydrogen atom or a methyl group, and still more preferably a hydrogen atom.

In Formula (Y), L^{Y1} represents a single bond or —CO—, and —CO— is preferable.

In Formula (Y), L^{Y2} represents a divalent aliphatic hydrocarbon group having 1 to 20 carbon atoms. The aliphatic hydrocarbon group may be linear or branched.

As the divalent aliphatic hydrocarbon group having 1 to 20 carbon atoms, an alkylene group having 1 to 15 carbon atoms is preferable and an alkylene group having 1 to 8 carbon atoms is more preferable, and specific suitable examples thereof include a methylene group, an ethylene group, a propylene group, a butylene group, a pentylene group, a hexylene group, a methylhexylene group, and a heptylene group.

One or more —CH₂—'s among —CH₂—'s constituting a part of the hydrocarbon group in L^{Y2} may be each independently substituted with —O—, —C(O)O—, or a phenylene group.

One or more hydrogen atoms among hydrogen atoms constituting a part of the hydrocarbon group in L^{Y2} may be substituted with —OH or the like.

In Formula (Y), Q^{Y} represents the crosslinkable group represented by Formulae (P-1) to (P-30) described above, and the suitable aspect thereof is also the same.

Specific examples of the repeating unit Y will be shown below, but the repeating unit Y is not limited to the following structures.

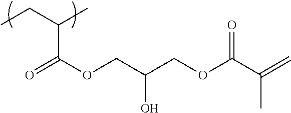

In a case where the specific polymer has the repeating unit Y, the content of the repeating unit Y is preferably in a range of 3% to 75% by mass, more preferably in a range of 5% to 70% by mass, and still more preferably in a range of 10% to 60% by mass with respect to all the repeating units (100% by mass) of the specific polymer. In a case where the content of the repeating unit X is within the above range, the effect of the present invention is more excellent, and the alignment degree of the light absorption anisotropic film is more excellent.

The repeating unit Y may be contained alone or in combination of two or more kinds thereof in the specific polymer. In a case where the specific polymer has two or more kinds of repeating units Y, the content of the repeating unit Y denotes the total content of the repeating units Y.

### <Repeating Unit Z>

The specific polymer may have a repeating unit Z represented by Formula (Z).

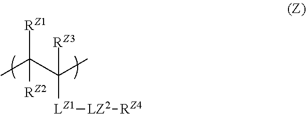

In Formula (Z), R^{Z1}, R^{Z2}, and R^{Z3} each independently represent a hydrogen atom, an alkyl group, an alkenyl group, or an aryl group.

Specific examples and suitable aspects of the alkyl group, the alkenyl group, and the aryl group in R^{Z1}, R^{Z2}, and R^{Z3} are the same as those of the alkyl group, the alkenyl group, and the aryl group in R^{B1}, R^{B2}, and R^{B3} in Formula (B).

R^{Z1}, R^{Z2}, and R^{Z3} are preferably a hydrogen atom or an alkyl group, more preferably a hydrogen atom or a methyl group, and still more preferably a hydrogen atom.

In Formula (Z), L^{Z1} represents a single bond or —CO—, and —CO— is preferable.

In Formula (Z), L^{Z2} represents a single bond or a divalent aliphatic hydrocarbon group having 1 to 20 carbon atoms. The aliphatic hydrocarbon group may be linear or branched. Provide that L^{Z1} and L^{Z2} are not simultaneously a single bond.

As the divalent aliphatic hydrocarbon group having 1 to 20 carbon atoms, an alkylene group having 1 to 15 carbon atoms is preferable and an alkylene group having 1 to 8 carbon atoms is more preferable, and specific suitable examples thereof include a methylene group, an ethylene group, a propylene group, a butylene group, a pentylene group, a hexylene group, a methylhexylene group, and a heptylene group.

One or more —CH₂—'s among —CH₂—'s constituting a part of the hydrocarbon group in L^{Z2} may be each independently substituted with —O—.

In Formula (Z), R^{Z4} represents a hydrogen atom, —OH, or an aryl group.

Examples of the aryl group include an aryl group having preferably 6 to 30 carbon atoms (preferably 6 to 20 carbon atoms and more preferably 6 to 12 carbon atoms). Specific examples thereof include a phenyl group, a 2,6-diethylphenyl group, a 3,5-ditrifluoromethylphenyl group, a styryl group, a naphthyl group, and a biphenyl group.

Specific examples of the repeating unit Z will be shown below, but the repeating unit Z is not limited to the following structures.

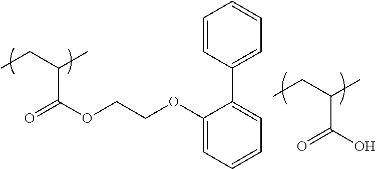

In a case where the specific polymer has a repeating unit Z, the content of the repeating unit Z is preferably in a range of 0.05% to 60% by mass, more preferably in a range of 0.05% to 30% by mass, still more preferably in a range of 0.05% to 10% by mass, and particularly preferably in a range of 0.05% to 5% by mass with respect to all the repeating units (100% by mass) of the specific polymer. In a case where the content of the repeating unit Z is within the above range, the effect of the present invention is more excellent, and the alignment degree of the light absorption anisotropic film is more excellent.

The repeating unit Z may be contained alone or in combination of two or more kinds thereof in the specific polymer. In a case where the specific polymer has two or more kinds of repeating units Z, the content of the repeating unit Z denotes the total content of the repeating units Z.

### <Content>

A content of the specific polymer is preferably 0.01% to 10% by mass, more preferably 0.02% to 5% by mass, and still more preferably 0.2% to 1.5% by mass with respect to the total solid content mass of the liquid crystal composition. In a case where the content of the specific polymer is within the above range, the effect of the present invention is more excellent, and the alignment degree of the light absorption anisotropic film is more excellent.

The content of the specific polymer is preferably in a range of 0.01 to 10 parts by mass, more preferably in a range of 0.02 to 5 parts by mass, and still more preferably in a range of 0.2 to 1.5 parts by mass with respect to 100 parts by mass which is the total amount of the liquid crystal compound and the dichroic substance in the liquid crystal composition. In a case where the content of the specific polymer is within the above range, the effect of the present invention is more excellent, and the alignment degree of the light absorption anisotropic film is more excellent.

### <Mass Ratio of Specific Polymer to Dichroic Substance>

A mass ratio of the content of the specific polymer to the content of dichroic substance (content of the specific polymer/content of the dichroic substance) is preferably 0.0007 to 0.6, more preferably 0.0012 to 0.3, and still more preferably 0.008 to 0.15.

In a case where the above mass ratio is within the above range, the alignment degree of a light absorption anisotropic film is more excellent. The reason for this is presumed to be that the compatibility between the specific polymer and the dichroic substance is further improved.

### <Molecular Weight>

From the viewpoint that the effect of the present invention is more excellent, the weight-average molecular weight (Mw) of the specific polymer is preferably in a range of 2,000 to 1,000,000, more preferably in a range of 3,000 to 200,000, and still more preferably in a range of 5,000 to 80,000.

Here, the weight-average molecular weight of the specific polymer can be measured by the method described in Examples described later.

### [Other Components]

The liquid crystal composition according to the embodiment of the present invention may contain a component other than the above-described liquid crystal compound, the dichroic substance, and the specific polymer (hereinafter, also referred to as “other components”).

Examples of the other components include a surfactant, an alignment agent, a polymerization initiator, and a solvent.

### <Surfactant>

The liquid crystal composition according to the embodiment of the present invention may contain a surfactant. In a case where the liquid crystal composition contains a surfactant, smoothness of a coated surface is improved, the alignment degree is further improved, and cissing and unevenness are suppressed so that in-plane uniformity is expected to be further improved.

Further, fluorine (meth)acrylate-based polymers described in [0018] to [0043] of JP2007-272185A can also be used as the surfactant. A compound other than the compounds described above may be used as the surfactant. The surfactant may be used alone or in combination of two or more kinds thereof.

In a case where the liquid crystal composition according to the embodiment of the present invention contains a surfactant, a content of the surfactant is preferably 0.01% to 10% by mass, and more preferably 0.02% to 5% by mass with respect to the total solid content mass of the liquid crystal composition.

### <Alignment Agent>

The liquid crystal composition according to the embodiment of the present invention may contain an alignment agent. Examples of the alignment agent include a boronic acid compound and an onium salt. The boronic acid compound functions as a horizontal alignment agent or a vertical alignment agent. In addition, the onium salt functions as a vertical alignment agent. The alignment agent may be used alone or in combination of two or more kinds thereof.

As the boronic acid compound, a compound represented by Formula (30) is preferable.

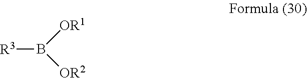

In Formula (30), R¹ and R² each independently represent a hydrogen atom, a substituted or unsubstituted aliphatic hydrocarbon group, a substituted or unsubstituted aryl group, or a substituted or unsubstituted hetero ring group.

R³ represents a substituent containing a (meth)acrylic group.

Specific examples of the boronic acid compound include a boronic acid compound represented by General Formula (I) described in paragraphs [0023] to [0032] of JP2008-225281A.

As the boronic acid compound, compounds shown below are also preferable.

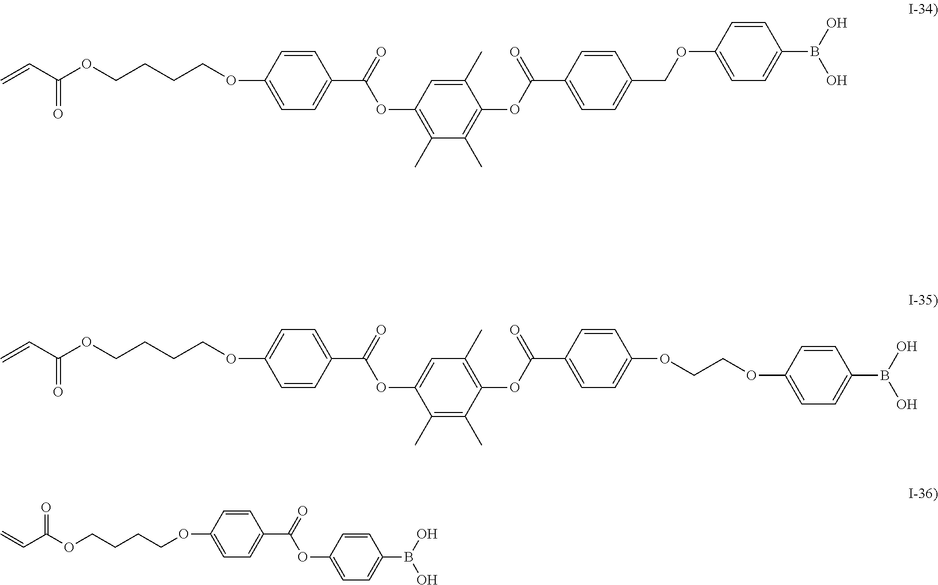 [SMILES: C=CC(=O)OCCCCOc1ccc(C(=O)Oc2cc(C)c(OC(=O)c3ccc(COc4ccc(B(O)O)cc4)cc3)c(C)c2C)cc1 ; C=CC(=O)OCCCCOc1ccc(C(=O)Oc2cc(C)c(OC(=O)c3ccc(OCCOc4ccc(B(O)O)cc4)cc3)c(C)c2C)cc1 ; C=CC(=O)OCCCCOc1ccc(C(=O)Oc2ccc(B(O)O)cc2)cc1]

Specific examples of the onium salt include the onium salts described in paragraphs 0052 to 0058 of JP2012-208397A, the onium salts described in paragraphs 0024 to 0055 of JP2008-026730A, and the onium salts described in JP2002-37777A.

In a case where the liquid crystal composition according to the embodiment of the present invention contains an alignment agent, a content of the alignment agent is preferably 0.01% to 30% r by mass, and more preferably 0.1% to 10% by mass with respect to the total solid content mass of the liquid crystal composition.

### <Polymerization Initiator>

The liquid crystal composition according to the embodiment of the present invention may contain a polymerization initiator. The polymerization initiator is not particularly limited, but a compound having photosensitivity, that is, a photopolymerization initiator is preferable.

As the photopolymerization initiator, various compounds can be used without any particular limitation. Examples of the photopolymerization initiator include ca-carbonyl compounds (U.S. Pat. Nos. 2,367,661A and 2,367,670A), acyloin ether (U.S. Pat. No. 2,448,828A), α-hydrocarbon-substituted aromatic acyloin compounds (U.S. Pat. No. 2,722,512A), polynuclear quinone compounds (U.S. Pat. Nos. 3,046,127A and 2,951,758A), a combination of a triarylimidazole dimer and a p-aminophenyl ketone (U.S. Pat. No. 3,549,367A), acridine and phenazine compounds (JP1985-105667A (JP-S60-105667A) and U.S. Pat. No. 4,239,850A), oxadiazole compounds (U.S. Pat. No. 4,212,970A), o-acyloxime compounds ([0065] of JP2016-27384A), and acylphosphine oxide compounds (JP1988-40799B (JP-S63-40799B), JP1993-29234B (JP-H5-29234B), JP1998-95788A (JP-H10-95788A), and JP1998-29997A (JP-H10-29997A)).

Commercially available products can also be used as such a photopolymerization initiator, and examples thereof include IRGACURE 184, IRGACURE 907, IRGACURE 369, IRGACURE 651, IRGACURE 819, IRGACURE OXE-01, and IRGACURE OXE-02, manufactured by BASF.

The polymerization initiators may be used alone or in combination of two or more kinds thereof.

In a case where the liquid crystal composition according to the embodiment of the present invention contains a polymerization initiator, a content of the polymerization initiator is preferably 0.01% to 30% by mass and more preferably 0.1% to 15% by mass with respect to the total solid content mass of the liquid crystal composition.

### <Solvent>

From the viewpoint of workability and the like, the liquid crystal composition according to the embodiment of the present invention preferably contains a solvent.

Examples of the solvent include organic solvents such as ketones (such as acetone, 2-butanone, methyl isobutyl ketone, cyclopentanone, and cyclohexanone), ethers (such as dioxane, tetrahydrofuran, tetrahydropyran, dioxolane, tetrahydrofurfuryl alcohol, and cyclopentyl methyl ether), aliphatic hydrocarbons (such as hexane), alicyclic hydrocarbons (such as cyclohexane), aromatic hydrocarbons (such as benzene, toluene, xylene, and trimethylbenzene), halogenated carbons (such as dichloromethane, trichloromethane (chloroform), dichloroethane, dichlorobenzene, and chlorotoluene), esters (such as methyl acetate, ethyl acetate, butyl acetate, and diethyl carbonate), alcohols (such as ethanol, isopropanol, butanol, and cyclohexanol), cellosolves (such as methyl cellosolve, ethyl cellosolve, and 1,2-dimethoxyethane), cellosolve acetates, sulfoxides (such as dimethyl sulfoxide), amides (such as dimethylformamide, dimethylacetamide, N-methylpyrrolidone, N-ethylpyrrolidone, and 1,3-dimethyl-2-imidazolidinone), and heterocyclic compounds (such as pyridine), and water. These solvents may be used alone or in combination of two or more kinds thereof.

Among these solvents, from the viewpoint that the effect of the present invention is more excellent, it is preferable to use an organic solvent and it is more preferable to use halogenated carbons or ketones.

In a case where the liquid crystal composition according to the embodiment of the present invention contains a solvent, a content of the solvent is preferably 70% to 99% by mass, more preferably 83% to 97% by mass, and still more preferably 85% to 95% by mass with respect to the total mass of the liquid crystal composition.

### [Light Absorption Anisotropic Film]

The light absorption anisotropic film according to the embodiment of the present invention is a light absorption anisotropic film (light absorption anisotropic layer) that is formed from the above-described liquid crystal composition according to the embodiment of the present invention.

The method of manufacturing the light absorption anisotropic film according to the embodiment of the present invention is not particularly limited, but a method comprising, in the following order, a step of coating an alignment film with the above-described liquid crystal composition to form a coating film (hereinafter, also referred to as “coating film forming step”), and a step of aligning liquid crystal components contained in the coating film (hereinafter, also referred to as “alignment step”) (hereinafter, also referred to as “present manufacturing method”), is preferable from the viewpoint that the alignment degree of the light absorption anisotropic film to be obtained is further increased.

Further, the liquid crystal component is a component containing not only the liquid crystal compound described above but also a dichroic substance having liquid crystallinity. Hereinafter, the respective steps will be described.

### [Coating Film Forming Step]

The coating film forming step is a step of coating the alignment film with the above-described liquid crystal composition to form a coating film.

The alignment film is easily coated with the liquid crystal composition by using the liquid crystal composition containing the above-described solvent or using a liquid-like material such as a melt obtained by heating the liquid crystal composition.

Examples of the method of coating the substrate with the liquid crystal composition include known methods such as a roll coating method, a gravure printing method, a spin coating method, a wire bar coating method, an extrusion coating method, a direct gravure coating method, a reverse gravure coating method, a die coating method, a spraying method, and an ink jet method.

### <Alignment Film>

The alignment film can be provided by methods such as rubbing treatment of an organic compound (preferably a polymer) on a film surface, oblique vapor deposition of an inorganic compound, formation of a layer having microgrooves, or accumulation of an organic compound (for example, o-tricosanoic acid, dioctadecylmethylammonium chloride, or methyl stearate) by the Langmuir-Blodgett method (LB film). Furthermore, an alignment film in which an alignment function is generated by application of an electric field, application of a magnetic field, or irradiation with light has also been known. Among these, in the present invention, an alignment film formed by performing a rubbing treatment is preferable from the viewpoint of easily controlling the pretilt angle of the alignment film, and a photo-alignment film formed by irradiation with light is also preferable from the viewpoint of the uniformity of alignment.

### (Rubbing Treatment Alignment Film)

A polymer material used for the alignment film formed by performing a rubbing treatment is described in a plurality of documents, and a plurality of commercially available products can be used. In the present invention, polyvinyl alcohol or polyimide, or derivatives thereof are preferably used. The alignment film can refer to the description on page 43, line 24 to page 49, line 8 of WO2001/88574A1. A thickness of the alignment film is preferably 0.01 to 10 pun and more preferably 0.01 to 1 m.

### (Photo-Alignment Film)

A photo-alignment material used for the alignment film formed by irradiation with light is described in a plurality of documents. In the present invention, preferred examples thereof include azo compounds described in JP2006-285197A, JP2007-76839A, JP2007-138138A, JP2007-94071A, JP2007-121721A, JP2007-140465A, JP2007-156439A, JP2007-133184A, JP2009-109831A, JP3883848B, and JP4151746B; aromatic ester compounds described in JP2002-229039A; maleimide and/or alkenyl-substituted nadimide compounds having a photo-alignment unit, described in JP2002-265541A and JP2002-317013A; photo-crosslinkable silane derivatives described in JP4205195B and JP4205198B; and photo-crosslinkable polyimides, polyamides, or esters described in JP2003-520878A, JP2004-529220A, and JP4162850B. Among these, azo compounds, photo-crosslinkable polyimides, polyamides, or esters are more preferable.

The photo-alignment film formed of the above-described material is irradiated with linearly polarized light or non-polarized light to manufacture a photo-alignment film.

In the present specification, the “irradiation with linearly polarized light” and the “irradiation with non-polarized light” are operations for causing a photo-reaction in the photo-alignment material. A wavelength of the light to be used varies depending on the photo-alignment material to be used, and is not particularly limited as long as the wavelength is required for the photo-reaction. A peak wavelength of the light to be used for irradiation with light is preferably 200 nm to 700 nm, and ultraviolet light having a peak wavelength of 400 nm or less is more preferable.

Examples of a light source used for the light irradiation include commonly used light sources, for example, lamps such as a tungsten lamp, a halogen lamp, a xenon lamp, a xenon flash lamp, a mercury lamp, a mercury xenon lamp, or a carbon arc lamp, various lasers [for example, a semiconductor laser, a helium neon laser, an argon ion laser, a helium cadmium laser, and a yttrium aluminum garnet (YAG) laser], a light emitting diode, and a cathode ray tube.

As a method of obtaining the linearly polarized light, a method of using a polarizing plate (for example, iodine polarizing plate, dichroic substance polarizing plate, and wire grid polarizing plate), a method of using a prismatic element (for example, Glan-Thomson prism) or a reflective type polarizer using Brewster's angle, or a method of using light emitted from a polarized laser light source can be adopted. In addition, by using a filter, a wavelength conversion element, or the like, only light having a required wavelength may be radiated selectively.

In a case where light to be applied is the linearly polarized light, a method of applying light vertically or obliquely to the upper surface of the alignment film or the surface of the alignment film from the rear surface is employed. An incidence angle of light varies depending on the photo-alignment material, but is preferably 0° to 90° (vertical) and more preferably 40° to 90°.

In a case where the light to be applied is the non-polarized light, the alignment film is irradiated with the non-polarized light obliquely. An incidence angle is preferably 100 to 80°, more preferably 20° to 60°, and still more preferably 300 to 50°.

The irradiation time is preferably 1 minute to 60 minutes and more preferably 1 minute to 10 minutes.

In a case where patterning is required, a method of performing irradiation with light using a photomask as many times as necessary for pattern preparation or a method of writing a pattern by laser light scanning can be employed.

### [Alignment Step]

The alignment step is a step of aligning a dichroic substance contained in the coating film. In this manner, the light absorption anisotropic film according to the embodiment of the present invention is obtained. In the alignment step, the dichroic substance is considered to be aligned along the liquid crystal compound aligned by the alignment film.

The alignment step may include a drying treatment. Components such as a solvent can be removed from the coating film by performing the drying treatment. The drying treatment may be performed by a method of allowing the coating film to stand at room temperature for a predetermined time (for example, natural drying) or a method of heating the coating film and/or blowing air to the coating film.

Here, the dichroic substance contained in the liquid crystal composition may be aligned by performing the above-described coating film forming step or drying treatment. For example, in an embodiment in which the liquid crystal composition is prepared as a coating solution containing a solvent, the light absorption anisotropic film according to the embodiment of the present invention may be obtained by drying the coating film and removing the solvent from the coating film so that the dichroic substance contained in the coating film is aligned.

It is preferable that the alignment step includes a heat treatment. As a result, the dichroic substance contained in the coating film is further aligned, and the alignment degree of the obtained light absorption anisotropic film is further increased.

From the viewpoint of manufacturing suitability, a heat temperature is preferably 10° C. to 250° C. and more preferably 25° C. to 190° C. In addition, the heating time is preferably 1 to 300 seconds and more preferably 1 to 60 seconds.

The alignment step may include a cooling treatment performed after the heat treatment. The cooling treatment is a treatment of cooling the heated coating film to room temperature (20° C. to 25° C.). As a result, the alignment of the dichroic substance contained in the coating film is further fixed, and the alignment degree of the light absorption anisotropic film is further increased. A cooling unit is not particularly limited, and the cooling treatment can be performed according to a known method.

The light absorption anisotropic film according to the embodiment of the present invention can be obtained by performing the above-described steps.

### [Other Steps]

The present manufacturing method may include a step of curing the light absorption anisotropic film after the alignment step (hereinafter, also referred to as “curing step”).

The curing step is performed by, for example, heating the layer and/or irradiating (exposing) the layer with light. Among these, it is preferable that the curing step is performed by irradiating the light absorption anisotropic layer with light.

Various light sources such as infrared rays, visible light, and ultraviolet rays can be used as a light source for curing, but ultraviolet rays are preferable. In addition, ultraviolet rays may be applied while the light absorption anisotropic film is heated during the curing, or ultraviolet rays may be applied through a filter which transmits only a specific wavelength. In addition, the exposure may be performed under a nitrogen atmosphere. In a case where the curing of the light absorption anisotropic film proceeds by radical polymerization, since inhibition of polymerization by oxygen is reduced, it is preferable that the exposure is performed in a nitrogen atmosphere.

A thickness of the light absorption anisotropic film is not particularly limited, but from the viewpoint that the effect of the present invention is more excellent, it is preferably 0.3 to 10 μm and more preferably 0.5 to 9 μm.

The liquid crystal compound and the dichroic substance which are contained in the light absorption anisotropic film according to the embodiment of the present invention have a fixed alignment state.

Examples of one aspect of the light absorption anisotropic film according to the embodiment of the present invention include an aspect in which an angle θ (hereinafter, also referred to as a “transmittance central axis angle θ”) formed by a transmittance central axis of the light absorption anisotropic film and a normal direction of a surface of the light absorption anisotropic film is more than 45° and 900 or less, and the angle θ is more preferably 750 or more and 90° or less and still more preferably 80° or more and 90° or less.

A laminate having a light absorption anisotropic film (polarizer) in which the transmittance central axis angle θ is more than 45° and 90° or less and a λ/4 plate (described later) is suitably used as a circularly polarizing plate.

Examples of the other aspect of the light absorption anisotropic film according to the embodiment of the present invention include an aspect in which the transmittance central axis angle θ is 0° or more and 450 or less, and the transmittance central axis angle θ is more preferably 0° or more and 350 or less and still more preferably 0° or more and less than 35°.

A laminate having a light absorption anisotropic film in which the transmittance central axis angle θ is 0° or more and 45° or less and a polarizer having an absorption axis in a plane is suitably used as a viewing angle control film.

Here, the transmittance central axis is a direction in which the highest transmittance is exhibited in a case where the transmittance is measured by changing an inclination angle (polar angle) and an inclination direction (azimuthal angle) with respect to a normal direction of a surface of the light absorption anisotropic film.

Specifically, the Mueller matrix at a wavelength of 550 nm is measured using AxoScan OPMF-1 (manufactured by Opto Science, Inc.). More specifically, in the measurement, the azimuthal angle at which the transmittance central axis is inclined is first searched for, the Mueller matrix at a wavelength of 550 nm is measured while the polar angle which is the angle with respect to the surface of the light absorption anisotropic film in the normal direction is changed from −70° to 70° at intervals of 1° in the surface (the plane which has the transmittance central axis and is orthogonal to the film surface) having the normal direction of the light absorption anisotropic film along the azimuthal angle thereof, and the transmittance of the light absorption anisotropic film is derived. As a result, the direction in which the highest transmittance is exhibited is defined as the transmittance central axis.

The transmittance central axis denotes a direction of an absorption axis (major axis direction of a molecule) of the dichroic substance contained in the light absorption anisotropic film.

The transmittance central axis angle θ can be set to a desired value, for example, by adjusting the type, content, and the like of the alignment agent.

### [Laminate]

The laminate according to the embodiment of the present invention has a light absorption anisotropic film, and the light absorption anisotropic film may be disposed on a substrate. In addition, in a case where the laminate according to the embodiment of the present invention has a substrate, the laminate may have an alignment film between the substrate and the light absorption anisotropic film.

Hereinafter, each member constituting the laminate according to the embodiment of the present invention will be described.

### [Substrate]

As the substrate, a transparent support is preferable. The transparent support is intended to be a support in which the transmittance of visible light is 60% or more, and the transmittance is preferably 80% or more and more preferably 90% or more.

As the transparent support, a known transparent resin film such as a transparent resin plate, a transparent resin sheet, or the like can be used without particular limitation.

As the transparent resin film, a cellulose acylate film (such as a cellulose triacetate film (refractive index: 1.48), a cellulose diacetate film, a cellulose acetate butyrate film, and a cellulose acetate propionate film), a polyethylene terephthalate film, a polyether sulfone film, a polyacrylic resin film, a polyurethane-based resin film, a polyester film, a polycarbonate film, a polysulfone film, a polyether film, a polymethylpentene film, a polyetherketone film, a (meth)acrylonitrile film, or the like can be used.

Among these, a cellulose acylate film which is highly transparent, has a small optical birefringence, is easily manufactured, and is typically used as a protective film of a polarizing plate is preferable, and a cellulose triacetate film is more preferable.

A thickness of the substrate is usually 20 to 100 μm.

In the present invention, it is particularly preferable that the substrate is a cellulose ester-based film having a film thickness of 20 to 70 μm.

### [Light Absorption Anisotropic Film]

The light absorption anisotropic film according to the embodiment of the present invention is as described above, and thus the description thereof will not be repeated.

### [Alignment Film]

The alignment film (alignment layer) is as described above, and thus the description thereof will not be repeated.

### [λ/4 Plate]

Examples of one suitable aspect of the laminate according to the embodiment of the present invention include an aspect in which the laminate has a light absorption anisotropic film (particularly, a light absorption anisotropic film in which the transmittance central axis angle θ is more than 450 and 90° or less) and a λ/4 plate. Such a laminate (optical film) is suitably used as a circularly polarizing plate.

The λ/4 plate is a plate having a λ/4 function, specifically, a plate having a function of converting linearly polarized light having a specific wavelength into circularly polarized light (or converting circularly polarized light into linearly polarized light).

Specific examples of an aspect in which the λ/4 plate has a monolayer structure include a stretched polymer film and a retardation film in which a light absorption anisotropic film having a λ/4 function is provided on a support. In addition, specific examples of an aspect in which the λ/4 plate has a multilayer structure include a broadband λ/4 plate obtained by laminating a λ/4 plate and λ/2 plate.

The λ/4 plate and the light absorption anisotropic film may be provided to be in contact with each other, or another layer may be provided between the λ/4 plate and the light absorption anisotropic film. Examples of such a layer include a pressure-sensitive adhesive layer or an adhesive layer for ensuring adhesiveness, and a barrier layer.

### [Polarizer]

Examples of the other suitable aspect of the laminate according to the embodiment of the present invention include an aspect in which the laminate has a light absorption anisotropic film (particularly, a light absorption anisotropic film in which the transmittance central axis angle θ is 0° or more and 45° or less) and a polarizer having an absorption axis in a plane. Such a laminate (optical film) is suitably used as a viewing angle control film used for controlling a viewing angle.

It is preferable that the polarizer is disposed on a side of the light absorption anisotropic film opposite to the substrate. The polarizer may be disposed in contact with the surface of the light absorption anisotropic film or may be disposed on the surface of the light absorption anisotropic film via another layer (for example, a known adhesive layer or a known pressure sensitive adhesive layer).

The polarizer is not particularly limited as long as the polarizer is a member having an absorption axis in the plane and having a function of converting light into specific linearly polarized light, and a known polarizer in the related art can be used. As the polarizer, an iodine-based polarizer, a dye-based polarizer obtained by using a dichroic dye, a polyene-based polarizer, or the like is used. Examples of the iodine-based polarizer and the dye-based polarizer include a coating type polarizer and a stretching type polarizer, and both polarizers can be applied.

As the polarizer, a polarizer in which a dichroic organic coloring agent is aligned by using alignment of the liquid crystal compound is preferable, and as the stretching type polarizer, a polarizer produced by adsorbing iodine or a dichroic dye on polyvinyl alcohol and stretching the polyvinyl alcohol is preferable.

Examples thereof include a light absorption anisotropic film containing a dichroic coloring agent compound that is horizontally aligned (direction intersecting the thickness direction of the light absorption anisotropic film) without containing the liquid crystal compound described in JP2010-152351A and a light absorption anisotropic film containing the liquid crystal compound described in WO2017/154907A and a horizontally aligned dichroic coloring agent compound.

### [Barrier Layer]

It is preferable that the laminate according to the embodiment of the present invention includes a barrier layer together with the light absorption anisotropic film.

Here, the barrier layer is also referred to as a gas-shielding layer (oxygen-shielding layer), and has a function of protecting the polarizer according to the embodiment of the present invention from gas such as oxygen in the atmosphere, the moisture, or the compound contained in an adjacent layer.

From the viewpoint of further improving durability, the laminate according to the embodiment of the present invention preferably includes a barrier layer having an oxygen permeability coefficient of 200 cc/m²·day·atm or less on an adjacent layer of the light absorption anisotropic film, and more preferably includes a barrier layer having an oxygen permeability coefficient of 50 cc/m²·day·atm or less.

In addition, in the adjacent layer of the light absorption anisotropic film, in a case where there is a layer other than the above-described barrier layer, which has an oxygen permeability coefficient of 200 cc/m²·day·atm or less, the barrier layer may not be provided. Here, the oxygen permeability coefficient is an index indicating an amount of oxygen passing through the film per unit time and unit area, and in the present invention, a value measured by an oxygen concentration device (for example, MODEL3600 manufactured by Hack Ultra Analytical) in an environment of 25° C. and a relative humidity (RH) of 50% is employed.

From the viewpoint of high oxygen shielding ability, examples of the organic compound contained in the barrier layer include a polymerizable compound having a high hydrogen bonding property and a compound having a large number of polymerizable groups per molecular weight. Examples of the compound having a large number of polymerizable groups per molecular weight include pentaerythritol tetra(meth)acrylate and dipentaerythritol hexa(meth)acrylate.

Examples of the polymerizable compound having a high hydrogen bonding property include an epoxy compound, and specific examples thereof include compounds represented by the following formulae. Among these, 3′,4′-epoxycyclohexylmethyl-3,4-epoxycyclohexanecarboxylate represented by CEL2021P is preferable.

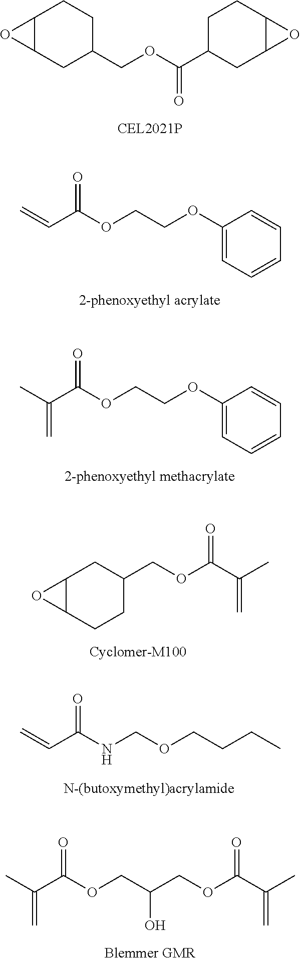

From the viewpoint of preventing the dichroic coloring agent of the light absorption anisotropic layer from diffusing during durability, it is also preferable to use, as the barrier layer, a polymer having a hydrophilic group, described in paragraph [0056] of WO2019-22121A, or a water-soluble polymer described in paragraphs [0117] to [0133] of JP2017-083843A. In addition, reference can be made to, for example, the descriptions in paragraphs [0014] to [0054] of JP2014-159124A, paragraphs [0042] to [0075] of JP2017-121721A, paragraphs [0045] to [0054] of JP2017-115076A, paragraphs [0010] to [0061] of JP2012-213938A, or paragraphs [0021] to [0031] of JP2005-169994A.

### [Pressure-Sensitive Adhesive Layer]

The laminate according to the embodiment of the present invention may or may not include a pressure-sensitive adhesive layer.

Examples of a pressure-sensitive adhesive constituting the pressure-sensitive adhesive layer include a pressure sensitive adhesive and an adhesive.

Examples of the pressure sensitive adhesive include a rubber-based pressure sensitive adhesive, an acrylic pressure sensitive adhesive, a silicone-based pressure sensitive adhesive, a urethane-based pressure sensitive adhesive, a vinyl alkyl ether-based pressure sensitive adhesive, a polyvinyl alcohol-based pressure sensitive adhesive, a polyvinylpyrrolidone-based pressure sensitive adhesive, a polyacrylamide-based pressure sensitive adhesive, and a cellulose-based pressure sensitive adhesive; and among these, an acrylic pressure sensitive adhesive (pressure-sensitive adhesive) is preferable.

Examples of the adhesive include a polyvinyl alcohol adhesive (water-based adhesive), a solvent-based adhesive, an emulsion-based adhesive, a solvent-free adhesive, an active energy ray-curable adhesive, and a thermosetting adhesive. Examples of the active energy ray-curable adhesive include an electron beam-curable adhesive, an ultraviolet curable adhesive, and a visible light-curable adhesive; and among these, an ultraviolet curable adhesive is preferable.

A thickness of the pressure-sensitive adhesive layer is not particularly limited, but from the viewpoint of thinning, it is preferably 25 μm or less, more preferably 15 μm or less, and still more preferably 5 μm or less. The lower limit thereof is not particularly limited, but is 0.1 μm or more in many cases.

It is also preferable from the viewpoint of simplification and thinning to impart a function of improving the durability of the barrier layer to the pressure-sensitive adhesive layer to make a configuration in which the light absorption anisotropic layer and the pressure-sensitive adhesive layer are adjacent to each other without the barrier layer. For example, a configuration in which the alignment layer, the light absorption anisotropic layer, the pressure-sensitive adhesive layer, and the retardation layer are arranged adjacent to each other can be mentioned.

As the adhesive in this case, from the viewpoint of preventing the dichroic substance in the light absorption anisotropic layer from diffusing during durability, for example, an adhesive containing polyvinyl alcohol as a main component, an ultraviolet (UV) adhesive having a low oxygen permeability, or an adhesive containing a hydrophilic group-containing polymer is preferable.

### [Reflective Linear Polarizer]

The image display device according to the embodiment of the present invention can include a reflective linear polarizer. The reflective linear polarizer exhibits an effect of reflecting a part of light emitted from the image display panel and reciprocating the light inside the optical system. From the viewpoint of suppressing stray light and ghosts, a reflective linear polarizer having a high degree of polarization is preferable.

As the reflective linear polarizer, a film obtained by stretching a dielectric multi-layer film, a wire grid polarizer, or the like as described in JP2011-053705A can be used. As a commercially available product thereof, a reflective type polarizer (trade name: APF, IQPE) manufactured by 3M Company, a wire grid polarizer (trade name: WGF) manufactured by Asahi Kasei Corporation, or the like can be suitably used.

### [Image Display Device]

The display device (image display device) according to the embodiment of the present invention has the above-described light absorption anisotropic film (preferably, the above-described laminate) and a display element.

The light absorption anisotropic film and the liquid crystal cell may be laminated through a known adhesive layer or a known pressure-sensitive adhesive layer.

The display element used in the display device according to the embodiment of the present invention is not particularly limited, and examples thereof include a liquid crystal cell, an organic electroluminescence (hereinafter, abbreviated as “EL”) display panel, and a plasma display panel.

Among these, a liquid crystal cell or an organic EL display panel is preferable. That is, as the display device according to the embodiment of the present invention, a liquid crystal display device formed of a liquid crystal cell as a display element or an organic EL display device formed of an organic EL display panel as a display element is preferable.

Some image display devices are thin and can be formed into a curved surface. Since the light absorption anisotropic film used in the present invention is thin and easily bent, the light absorption anisotropic film can be suitably applied to an image display device having a curved display surface.

In addition, some image display devices have a pixel density of more than 250 ppi and are capable of high-definition display. The light absorption anisotropic film used in the present invention can be suitably applied to such a high-definition image display device without causing moire.

### [Liquid Crystal Display Device]

Preferred examples of the liquid crystal display device which is an example of the display device according to the embodiment of the present invention include an aspect in which the liquid crystal display device includes the above-described viewing angle control film and a liquid crystal cell.

Examples of the specific configuration thereof include a configuration in which the viewing angle control film is disposed on a front-side polarizing plate or a rear-side polarizing plate. In these configurations, the viewing angle at which the up-down direction or the left-right direction is light-shielded can be controlled.

In addition, the viewing angle control film may be disposed on both the front-side polarizing plate and the rear-side polarizing plate. With such a configuration, it is possible to control the viewing angle in which all orientations are light-shielded and light is transmitted only in the front direction.

Furthermore, a plurality of the viewing angle control films may be laminated via a retardation layer. Transmission performance and light shielding performance can be controlled by controlling a retardation value and an optical axis direction. For example, in a case where a polarizer, a viewing angle control film, a J2 wavelength plate (the axis angle is deviated by 45° from an alignment direction of the polarizer), and a viewing angle control film are disposed in this order, viewing angle control is possible in which light is shielded in all orientations and only light in the front direction is transmitted. As a retardation layer, a positive A-plate, a negative A-plate, a positive C-plate, a negative C-plate, a B-plate, an O-plate, or the like can be used. From the viewpoint of reducing the thickness of the viewing angle control system, it is preferable that the thickness of the retardation layer is small as long as the optical characteristics, the mechanical properties, and the manufacturing suitability are not impaired, and specifically, the thickness thereof is preferably in a range of 1 to 150 μm, more preferably in a range of 1 to 70 μm, and still more preferably in a range of 1 to 30 μm.

Hereinafter, the liquid crystal cell constituting the liquid crystal display device will be described in detail.

### <Liquid Crystal Cell>

It is preferable that the liquid crystal cell used for the liquid crystal display device is in a vertical alignment (VA) mode, an optically compensated bend (OCB) mode, an in-plane-switching (IPS) mode, or a twisted nematic (TN) mode, but the present invention is not limited thereto.

In the liquid crystal cell in a TN mode, rod-like liquid crystalline molecules are substantially horizontally aligned at the time of no voltage application and further twisted and aligned at 60° to 120°. The liquid crystal cell in a TN mode is most frequently used as a color TFT liquid crystal display device and is described in a plurality of documents.

In the liquid crystal cell in a VA mode, rod-like liquid crystalline molecules are substantially vertically aligned at the time of no voltage application. Examples of the VA mode liquid crystal cells include (1) a VA mode liquid crystal cell in a narrow sense (described in JP1990-176625A (JP-H2-176625A)) in which rod-like liquid crystalline molecules are substantially aligned vertically in a case where no voltage is applied thereto and are substantially aligned horizontally in a case where a voltage is applied thereto, (2) a multi-domain VA mode (MVA mode) liquid crystal cell for enlarging the viewing angle (SID97, described in Digest of Tech. Papers (Proceedings) 28 (1997) 845), (3) a liquid crystal cell in a mode (n-ASM mode) in which rod-like liquid crystalline molecules are substantially aligned vertically in a case where no voltage is applied thereto and are aligned in twisted multi-domain alignment in a case where a voltage is applied thereto (described in Proceedings of Japanese Liquid Crystal Conference, 58 and 59 (1998)), and (4) a SURVIVAL mode liquid crystal cell (presented in LCD International 98). The liquid crystal cell may be any one of a patterned vertical alignment (PVA) type, an optical alignment (OA) type, or a polymer-sustained alignment (PSA) type. The details of these modes are described in JP2006-215326A and JP2008-538819A.

In the liquid crystal cell in an IPS mode, liquid crystal compounds are aligned substantially parallel to the substrate, and the liquid crystalline molecules respond planarly through application of an electric field parallel to the substrate surface. That is, the liquid crystal compounds are aligned in the plane in a state where no electric field is applied. The IPS mode displays black in a state where no electric field is applied and a pair of upper and lower polarizing plates have absorption axes which are orthogonal to each other. A method of reducing light leakage during black display in an oblique direction and improving the viewing angle using an optical compensation sheet is disclosed in JP1998-54982A (JP-H10-54982A), JP1999-202323A (JP-H11-202323A), JP1997-292522A (JP-H9-292522A), JP1999-133408A (JP-H11-133408A), JP1999-305217A (JP-H11-305217A), and JP1998-307291A (JP-H10-307291A).

### [Organic EL Display Device]

Suitable examples of an organic EL display device which is an example of the display device according to the embodiment of the present invention include an aspect including, from the visible side, the above-described circularly polarizing plate and an organic EL display panel. In this case, the substrate, the light absorption anisotropic film, and the λ/4 plate are disposed in order from the visible side.

In addition, the organic EL display panel is a display panel formed of an organic EL element obtained by sandwiching an organic light emitting layer (organic electroluminescence layer) between electrodes (between a cathode and an anode). The configuration of the organic EL display panel is not particularly limited, and a known configuration is employed.

### [Virtual Reality Display Apparatus]

A first aspect of the virtual reality display apparatus which is an example of the display device according to the embodiment of the present invention is a virtual reality display apparatus including, in the following order, an image display panel, a first absorptive linear polarizer (light absorption anisotropic layer), a first retardation layer, a second retardation layer, a reflective linear polarizer, a third retardation layer, a half mirror, and a second absorptive linear polarizer (light absorption anisotropic layer).

A second aspect is a virtual reality display apparatus including, in the following order, an image display panel, a first absorptive linear polarizer, a first retardation layer, a half mirror, a reflective circular polarizer, a second retardation layer, and a second absorptive linear polarizer.

A third aspect is a virtual reality display apparatus including, in the following order, an image display panel, a first absorptive linear polarizer, a first retardation layer, a half mirror, a second retardation layer, a reflective linear polarizer, and a second absorptive linear polarizer.

Furthermore, it is also preferable that the virtual reality display apparatus includes a fourth retardation layer on a visible side of the second absorptive linear polarizer.

In the virtual reality display apparatus according to the embodiment of the present invention, a lens-shaped curved substrate can be used as the substrate (for example, the member between the second retardation layer 12 and the half mirror 40 in the FIGURE).

In this case, the light absorption anisotropic layer or the laminate according to the embodiment of the present invention can be processed into a three-dimensional curved surface and used.

The FIGURE is a side view schematically showing an embodiment of a virtual reality display apparatus according to the embodiment of the present invention. In a virtual reality display apparatus 100 in the FIGURE, from the visible side, a second absorptive linear polarizer 22, a second retardation layer 12, a half mirror 40, an antireflection layer 50, a reflective circular polarizer 30, a positive C-plate 60, a first retardation layer 11, a first absorptive linear polarizer 21, a third retardation layer 13, and an image display panel 70 are disposed in this order.

### [Specific Polymer]

The present invention also relates to the following specific polymers.

A specific polymer according to the embodiment of the present invention is a polymer having the repeating unit A-1 represented by Formula (A-1), and at least one of the repeating unit B represented by Formula (B) or the repeating unit D represented by Formula (D).

Since the repeating unit A-1, the repeating unit B, and the repeating unit D in the specific polymer according to the embodiment of the present invention are all as described in the specific polymer contained in the liquid crystal composition according to the embodiment of the present invention described above, the description thereof will be omitted.

### EXAMPLES

Hereinbelow, the present invention will be described in more detail with reference to Examples. Materials, used amounts, ratios, treatment contents, treatment procedures, and the like described in Examples can be appropriately changed without departing from the spirit of the present invention. Therefore, the scope of the present invention should not be construed as being limited by the following examples.

### Synthesis Example 1

A copolymer B1 was synthesized by the following procedures.

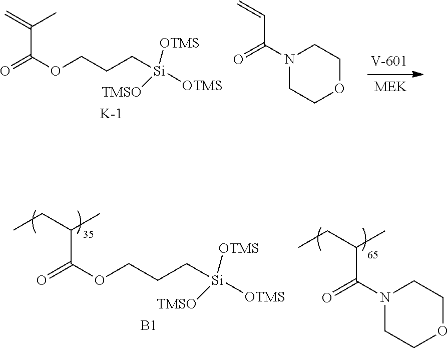

A reaction container was charged with 5.3 g of methyl ethyl ketone (MEK) and heated until the internal temperature reached 80° C. in a nitrogen stream. A mixed solution of 9.75 g of 4-acryloylmorpholine (manufactured by Tokyo Chemical Industry Co., Ltd.), 5.25 g of monomer K-1 (Silaplane TM-0701T manufactured by JNC Corporation), 0.5 g of dimethyl 2,2′-azobis(2-methylpropionate) (trade name, “V-601”, manufactured by FUJIFILM Wako Pure Chemical Corporation), and 15.0 g of methyl ethyl ketone was added dropwise to the reaction container for a polymerization reaction at 80° C. for 3 hours. After the completion of the dropwise addition, a methyl ethyl ketone (1.0 g) solution of 0.10 g of dimethyl 2,2′-azobis(2-methylpropionate) was added thereto, and the solution was stirred at 80° C. for 5 hours, thereby obtaining a methyl ethyl ketone solution of the copolymer B1.

As a result of analysis of the obtained copolymer B1 by gel permeation chromatography (GPC), the weight-average molecular weight (Mw) thereof was 18,000 (in terms of polystyrene).

It is noted that the above-described weight-average molecular weight (Mw) was calculated, in terms of polystyrene, by gel permeation chromatography (EcoSEC HLC-8320GPC (manufactured by Tosoh Corporation)) under measurement conditions of tetrahydrofuran as an eluent, a flow rate of 0.35 mL/min, and a temperature of 40° C., and the columns used were TSKgel SuperHZM-H, TSKgel SuperHZ4000, and TSKgel SuperHZ200 (all manufactured by Tosoh Corporation).

The Mw of each copolymer described later was also measured by the same method as the copolymer B1.

### Synthesis Examples 2 to 6

Copolymers B2 to B5 and B′3 represented by formulae described later were obtained in the same manner as in Synthesis Example 1, except that the monomers and the composition ratios used in Synthesis Example 1 were changed to the monomers and composition ratios forming the repeating unit of the copolymers.

### Synthesis Example 7

A copolymer B6 was synthesized by the following procedures.

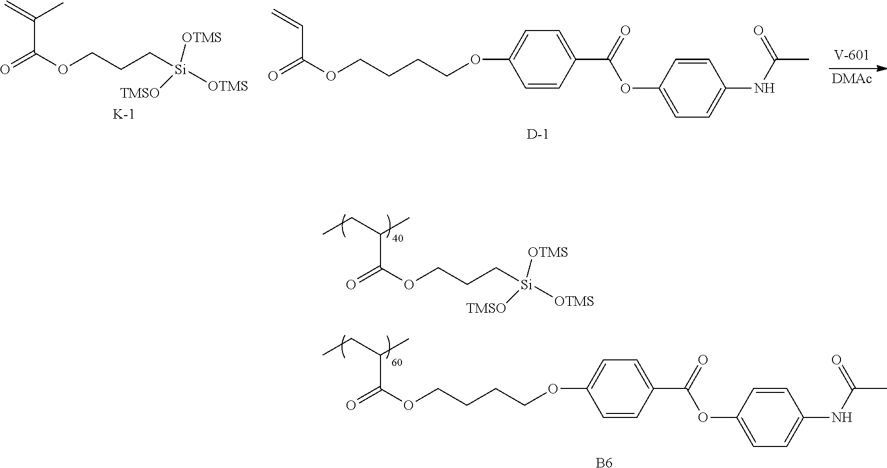

Specifically, 6 g of a compound D-1, 4 g of monomer K-1 (Silaplane TM-0701T manufactured by JNC Corporation), and 30 mg of dimethyl 2,2′-azobis(2-methylpropionate) (trade name, “V-601”, manufactured by FUJIFILM Wako Pure Chemical Corporation) were dissolved in 18 g of dimethylacetamide (DMAc), and the solution was added dropwise to 8 g of dimethylacetamide heated to 80° C. for 3 hours in a nitrogen stream. After the completion of the dropwise addition, the solution was heated at 80° C. for 4 hours.

Next, disappearance of the polymerizable group was confirmed by ¹H-NMR (nuclear magnetic resonance) spectrum measurement, the reaction solution was added to 250 mL of distilled water, the resulting solution was filtered, and the residues were washed with distilled water and hexane, thereby obtaining 7.1 g of the copolymer B6 as a white solid.

The weight-average molecular weight (Mw) of the obtained copolymer B6 was 14,000.

The compound D-1 used for the synthesis was synthesized according to the following scheme.

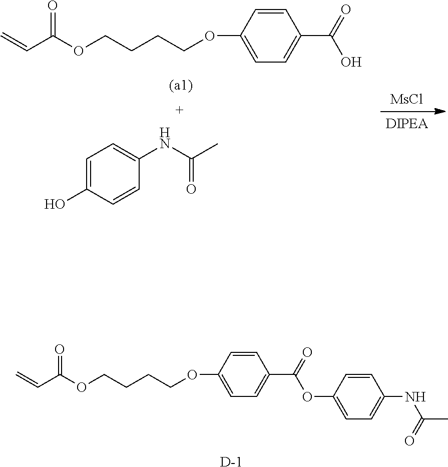

Specifically, 22 g of methanesulfonyl chloride (MsCl) was added to 48.5 mL of tetrahydrofuran (THF), and the mixture was cooled until the internal temperature reached 0° C.

A solution obtained by dissolving 48.5 g of a compound (a1), 0.36 g of 2,2,6,6-tetramethylpiperidine 1-oxyl (TEMPO), and 28 g of diisopropylethylamine (DIPEA) in advance was added dropwise to 26 ml of a mixed solvent of THE and dimethylacetamide at a mass ratio of 33:67 such that the internal temperature did not rise above 10° C. After the solution was stirred at 0° C. for 30 minutes, a 38 ml dimethylacetamide solution of 25 g of acetaminophen was added thereto. 6.85 g of N-methylimidazole and 20 g of triethylamine were added thereto, and the resulting solution was stirred at 0° C. for 60 minutes and heated to room temperature. Thereafter, 30 ml of distilled water and 30 ml of dimethylacetamide were added thereto, and the resulting solution was heated to 40° C. and stirred until the solid was completely dissolved. 300 ml of methanol was gradually added to the contents of the flask and stirred while cooling to an internal temperature of 5° C. to reprecipitate the reactant. The precipitate was filtered, and the residues were washed with distilled water and hexane, thereby obtaining 58 g of the compound D-1 as a white solid.

The ¹H-NMR of the obtained compound D-1 is shown below.

¹H-NMR (solvent: CDCl₃) δ (ppm): 1.92 (br, 4H), 2.16 (t, 3H), 4.09 (t, 2H), 4.26 (t, 2H), 5.84 (dd, 1H), 6.13 (q, 1H), 6.62 (dd, 1H), 6.96 (2H), 7.12 (m, 2H), 7.51 (m, 2H), 7.84 (br, 1H), 8.13 (m, 2H)

### Synthesis Examples 8 to 13

Copolymers B7 to B11 and B′2 represented by formulae described later were obtained in the same manner as in Synthesis Example 7, except that the monomers and the composition ratios used in Synthesis Example 7 were changed to the monomers and composition ratios forming the repeating unit of the copolymers.

### Synthesis Example 14

A copolymer B12 was synthesized by the following procedures.

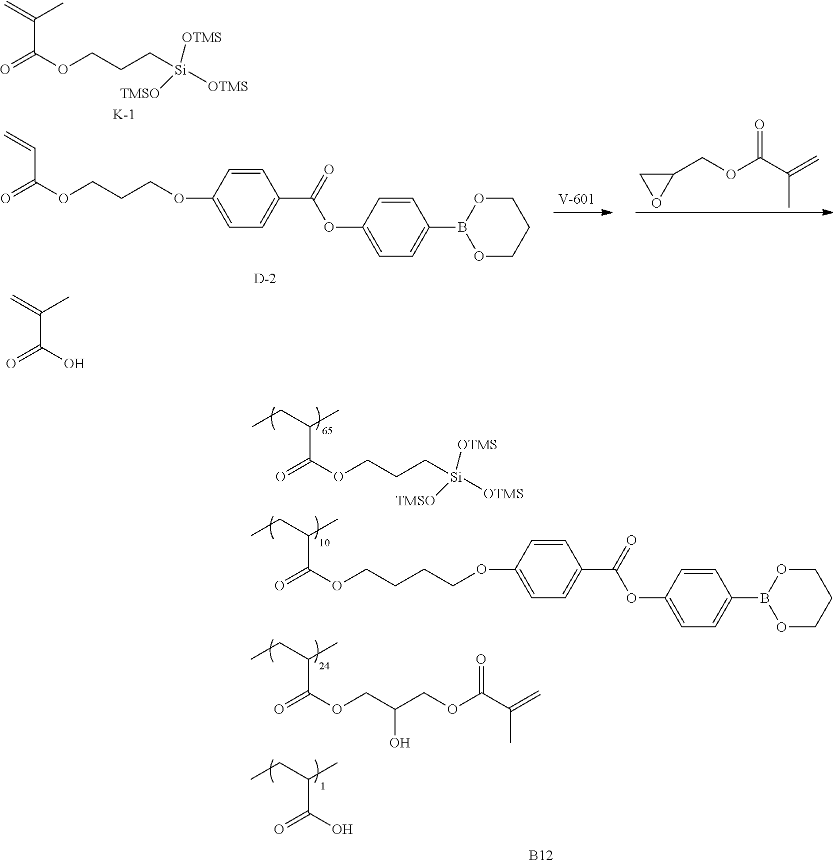

16.0 g of cyclohexanone/isopropanol=8/2 (mass ratio) was put into a 200 mL three-neck flask equipped with a stirrer, a cooling pipe, a nitrogen introduction pipe, and a thermometer, and the inside was substituted with nitrogen gas at an internal temperature of 80° C. A solution obtained by mixing various components including 31.5 g of a monomer K-1 (Silaplane TM-0701T, manufactured by JNC Corporation), 4.4 g of a monomer D-2, 2.1 g of acrylic acid (manufactured by FUJIFILM Wako Pure Chemical Corporation), 1.1 g of 1,3-propanediol (manufactured by FUJIFILM Wako Pure Chemical Corporation), 0.6 g of dimethyl 2,2′-azobis(2-methylpropionate) (trade name, “W-601”, manufactured by FUJIFILM Wako Pure Chemical Corporation), and 72.2 g of cyclohexanone/isopropanol=8/2 (mass ratio) was added dropwise thereto over 3 hours. Furthermore, a mixed solution of 0.5 g of dimethyl 2,2′-azobis(2-methylpropionate) and 7.3 g of cyclohexanone/isopropanol=8/2 (mass ratio) was added thereto, the mixture was stirred at an internal temperature of 80° C. for 5 hours, 4.1 g of glycidyl methacrylate (manufactured by FUJIFILM Wako Pure Chemical Corporation), 1.5 g of tetrabutylammonium bromide (manufactured by FUJIFILM Wako Pure Chemical Corporation), 0.1 g of hydroquinone monomethyl ether (manufactured by FUJIFILM Wako Pure Chemical Corporation), and 16.8 g of cyclohexanone/isopropanol=8/2 (mass ratio) were added thereto, and the mixture was reacted at an internal temperature of 85° C. for 8 hours, thereby obtaining the copolymer B12.

The weight-average molecular weight (Mw) of the copolymer B12 was 15,000.

### Synthesis Examples 15 and 16

Copolymers B13 and B14 were obtained in the same manner as in Synthesis Example 7, except that the monomers and the composition ratios used in Synthesis Example 7 were changed to the monomers and composition ratios forming the repeating unit of the copolymers.

The structures of copolymers B1 to B14, B′2 and B′3 are shown below. The numerical values next to each repeating unit mean the content (% by mass) of each repeating unit with respect to all the repeating units (100% by mass) of the copolymer.

In addition, in the following formulae, TMS represents a trimethylsilyl group and nBu represents a normal butyl group.

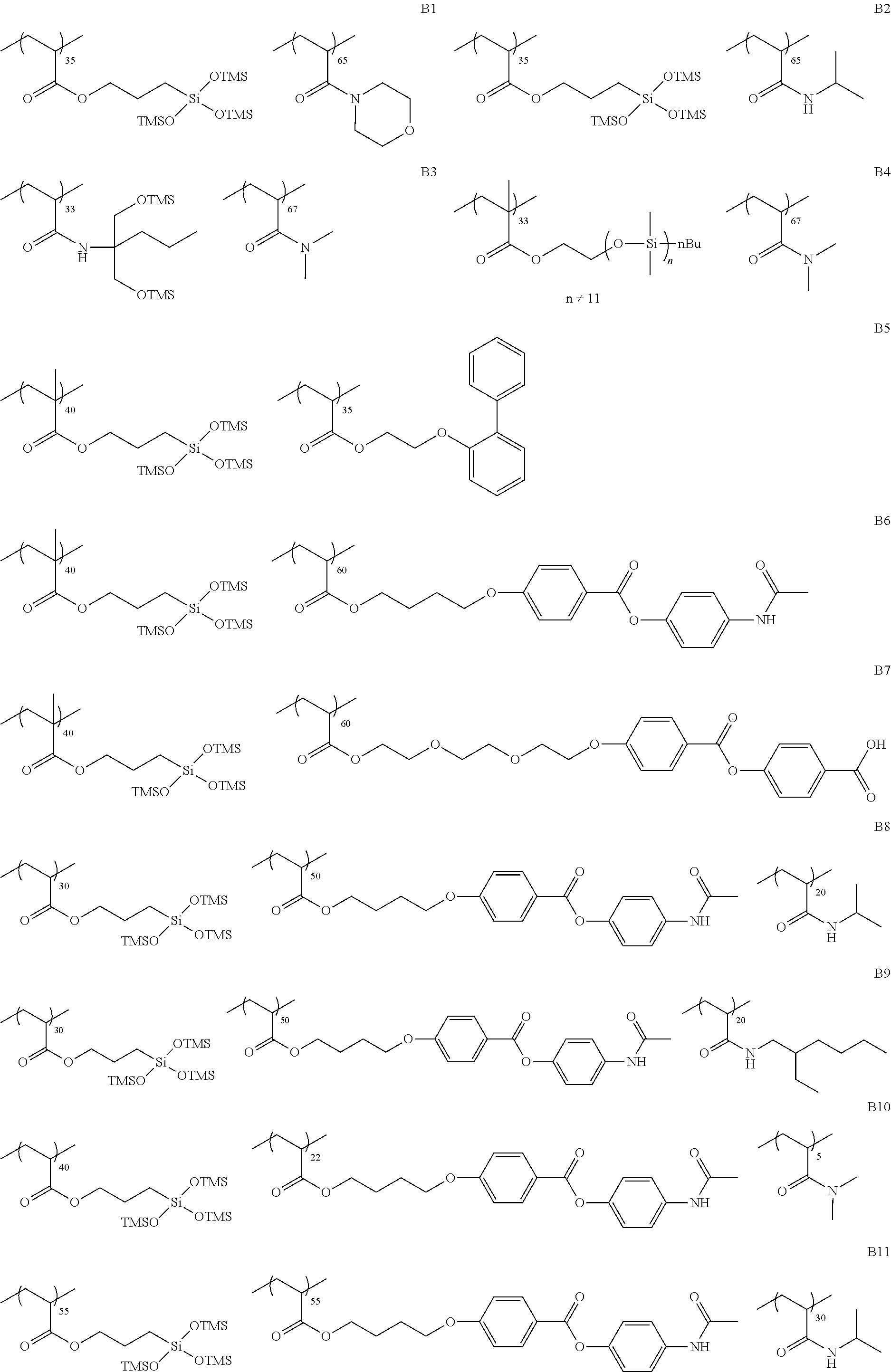

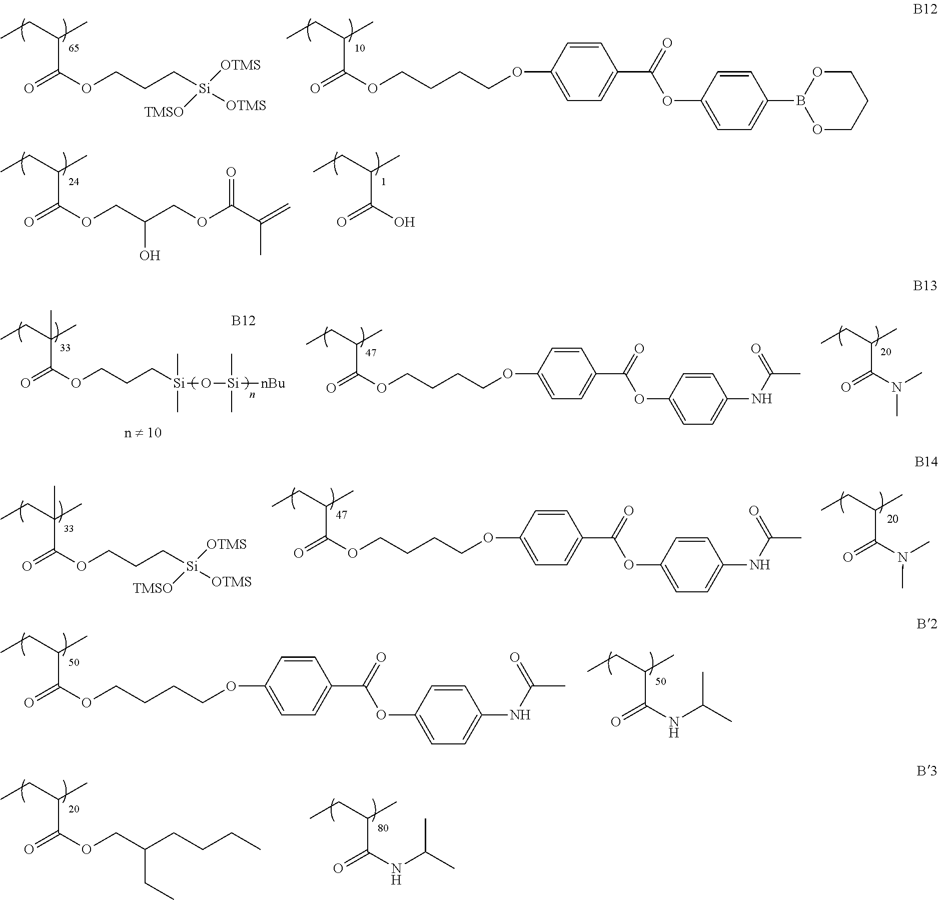

### Example 1-1

### [Production of Cellulose Acylate Film 1]

### <Production of Core Layer Cellulose Acylate Dope>

The following composition was put into a mixing tank and stirred to dissolve each component, thereby preparing a cellulose acetate solution used as a core layer cellulose acylate dope.

Core layer cellulose acylate dope

| | |
|---|---|
| Cellulose acetate having acetyl substitution | 100 parts by mass |
| degree of 2.88 | |
| Polyester compound B described in Examples | 12 parts by mass |
| of JP2015-227955A | |
| Compound F shown below | 2 parts by mass |
| Methylene chloride (first solvent) | 430 parts by mass |
| Methanol (second solvent) | 64 parts by mass |

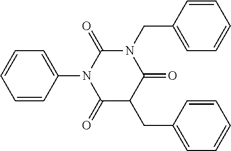 [SMILES: O=C1C(Cc2ccccc2)C(=O)N(c2ccccc2)C(=O)N1Cc1ccccc1]

Compound F

### <Production of Outer Layer Cellulose Acylate Dope>

10 parts by mass of the following matting agent solution were added to 90 parts by mass of the above-described core layer cellulose acylate dope to prepare a cellulose acetate solution used as an outer layer cellulose acylate dope.

Matting agent solution

| | |
|---|---|
| Silica particles with average particle size | 2 parts |
| of 20 nm (AEROSIL R972, manufactured by | |
| Nippon Aerosil Co., Ltd.) by mass | |
| Methylene chloride (first solvent) | 76 parts by mass |
| Methanol (second solvent) | 11 parts by mass |
| Core layer cellulose acylate dope described above | 1 part by mass |

### <Production of Cellulose Acylate Film 1>

The core layer cellulose acylate dope and the outer layer cellulose acylate dope were filtered through filter paper having an average pore size of 34 μm and a sintered metal filter having an average pore size of 10 μm, and three layers which were the core layer cellulose acylate dope and the outer layer cellulose acylate dopes provided on both sides of the core layer cellulose acylate dope were simultaneously cast from a casting port onto a drum at 20° C. (band casting machine).

Next, the film was peeled off in a state where the solvent content was approximately 20% by mass, both ends of the film in the width direction were fixed by tenter clips, and the film was dried while being stretched at a stretching ratio of 1.1 times in the lateral direction.

Thereafter, the film was further dried by being transported between the rolls of the heat treatment device to produce an optical film having a thickness of 40 μm, and the optical film was used as a cellulose acylate film 1 (support 1). The in-plane retardation of the obtained cellulose acylate film 1 was 0 mu.

### [Production of Photoalignment Layer PA1]

The cellulose acylate film 1 was continuously coated with a coating liquid PA1 for forming an alignment layer described below with a wire bar. The support on which a coating film was formed was dried with hot air at 140° C. for 120 seconds, and the coating film was irradiated with polarized ultraviolet rays (10 mJ/cm, using an ultra-high pressure mercury lamp) to form a photoalignment layer PA1, thereby obtaining a TAC film provided with a photoalignment layer. The film thickness of the photoalignment layer PA1 was 0.5 μm.

(Coating liquid PA1 for forming alignment layer)

| | |
|---|---|
| Polymer PA1 shown below | 100.00 parts by mass |
| Acid generator PAG-1 shown below | 8.00 parts by mass |
| Acid generator CPI-110TF shown below | 0.005 parts by mass |
| Xylene | 1220.00 parts by mass |
| Methyl isobutyl ketone | 122.00 parts by mass |

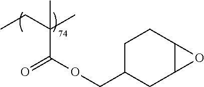

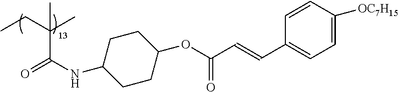

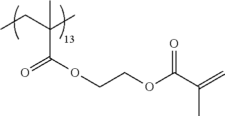

PA1 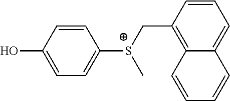 [SMILES: C[S+](Cc1cccc2ccccc12)c1ccc(O)cc1] 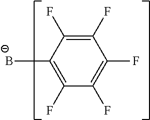
PAG-1 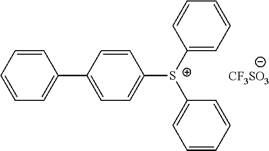
CPI-110TF

### [Production of Light Absorption Anisotropic Film 1-1]

The obtained photoalignment layer PA1 was continuously coated with the following liquid crystal composition 1-1 using a wire bar, thereby forming a coating layer.

Next, the coating layer was heated at 140° C. for 30 seconds and cooled to room temperature (23° C.). Next, the coating layer was heated at 90° C. for 60 seconds and cooled to room temperature again.

Thereafter, a light absorption anisotropic film 1-1 was produced on the photoalignment layer PA1 by irradiation with light (center wavelength of 365 nm) of a light emitting diode (LED) lamp for 2 seconds under an irradiation condition of an illuminance of 200 mW/cm².

In this manner, a laminate 1-1 in which the light absorption anisotropic film 1-1 was formed on the photo-alignment layer PA1 of the TAC film with the photo-alignment layer was obtained. The film thickness of the light absorption anisotropic film 1-1 was 0.5 μm.

Formulation of liquid crystal composition 1-1

| | |
|---|---|
| High-molecular-weight liquid crystal compound P1 shown below | 2.23 parts by mass |
| Low-molecular-weight liquid crystal compound L1 shown below | 0.95 parts by mass |
| Dichroic substance Y1 shown below | 0.09 parts by mass |
| Dichroic substance M1 shown below | 0.20 parts by mass |
| Dichroic substance C1 shown below | 0.41 parts by mass |
| Polymerization initiator I1 | 0.14 parts by mass |
| (IRGACURE OXE-02, manufactured by BASF) | |
| Copolymer B1 shown above | 0.027 parts by mass |
| Cyclopentanone | 53.90 parts by mass |
| Tetrahydrofuran | 23.10 parts by mass |

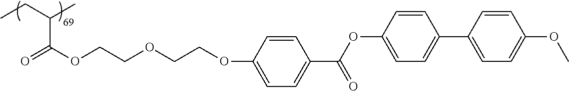

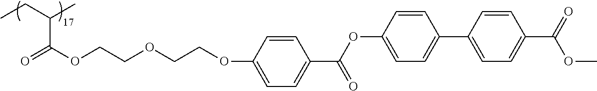

P1 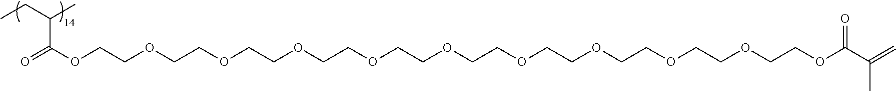 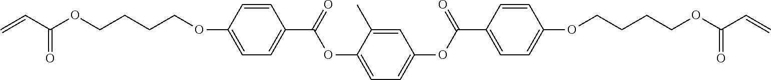 [SMILES: C=CC(=O)OCCCCOc1ccc(C(=O)Oc2ccc(OC(=O)c3ccc(OCCCCOC(=O)C=C)cc3)c(C)c2)cc1]
L1 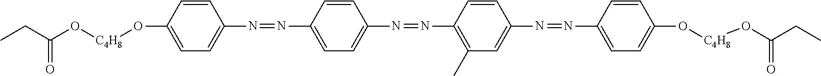
Y1 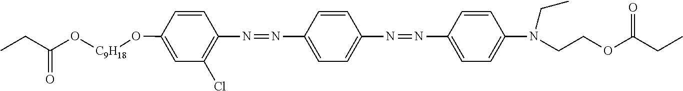
M1 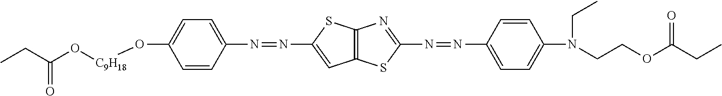
C1

Further, both the high-molecular-weight liquid crystal compound P1 and the low-molecular-weight liquid crystal compound L1 are rod-like liquid crystal compounds.

### Examples 1-2 to 1-13 and Comparative Examples 1-1 to 1-3

Each laminate of Examples 1-2 to 1-13 and Comparative Examples 1-1 to 1-3 was obtained in the same manner as in Example 1-1 except that the formulation of the liquid crystal composition 1-1 was changed to the formulation listed in Table 1.

### Examples 1-14 and 1-15

Each laminate of Examples 1-14 and 1-15 was obtained in the same manner as in Example 1-1 except that the formulation of the liquid crystal composition 1-1 was changed to the formulation listed in Table 1.

Components other than the components described above among the components indicated by symbols in Table 1 are shown below. The numerical values next to the parentheses of each repeating unit denote the content (% by mass) of each repeating unit with respect to all the repeating units of each polymer.

Further, both the high-molecular-weight liquid crystal compounds P2 and P3 and the low-molecular-weight liquid crystal compounds L2 and L3 are rod-like liquid crystal compounds.

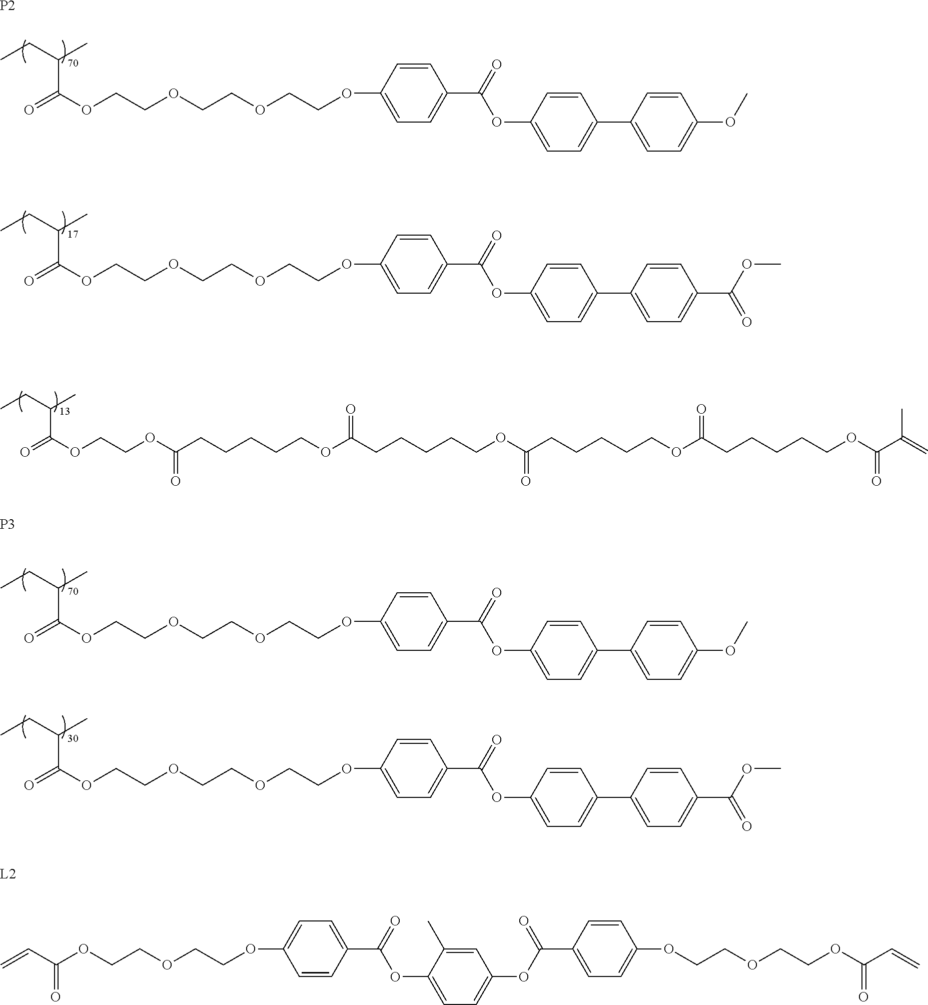

The low-molecular-weight liquid crystal compound L3 is the following mixture of rod-like liquid crystal compound. The numerical value in the following formulae represents % by mass, and R represents a group bonded through an oxygen atom.

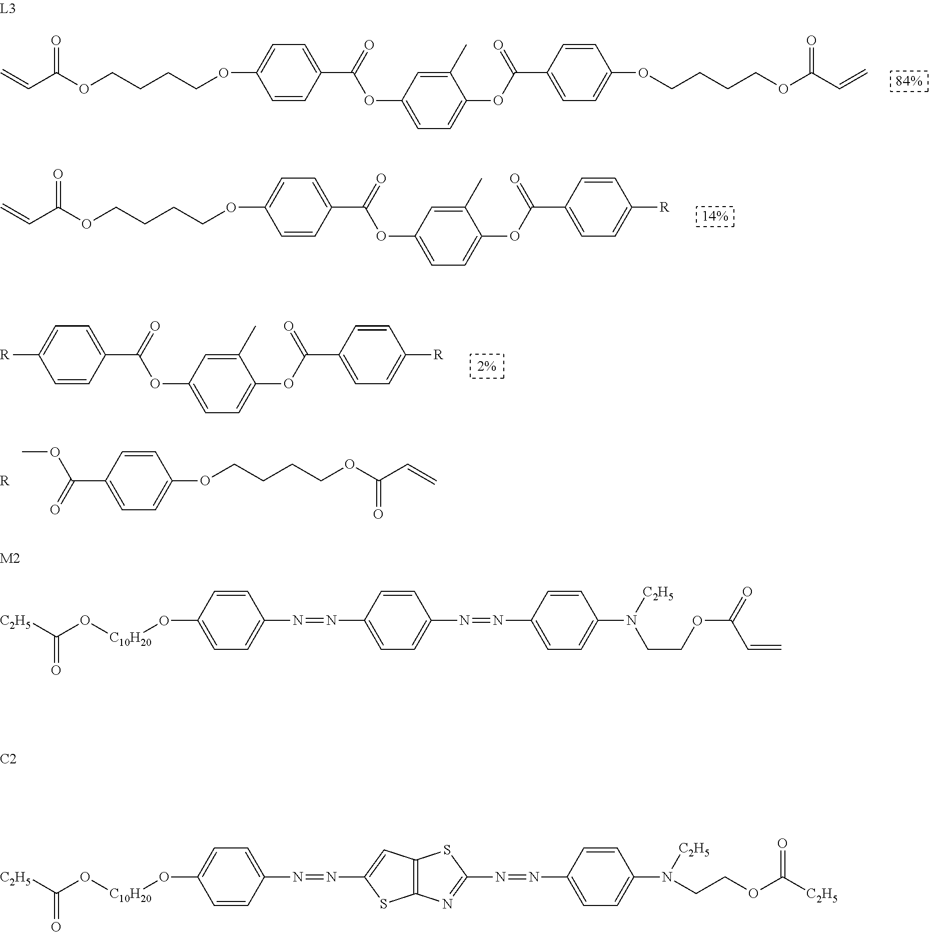

Polymer B′1: polyether-modified silicone (manufactured by Evonik Tego chemie GmbH, trade name “FLOW 425”)

### [Evaluation]

### [Haze]

Each laminate in the examples and the comparative examples was set on a sample table in a state in which a linear polarizer was inserted on a light source side of an optical microscope (product name, “ECLIPSE E600 POL”, manufactured by Nikon Corporation), and the haze was visually evaluated. The more excellent the evaluation of the haze, the more the alignment defects are suppressed. The results are shown in Table 1.
A: haze was not visually recognized on the entire surface.
B: a small amount of haze was visually recognized on a part of the surface.
C: turbidity was visually recognized on the entire surface.

### [Cissing]

A laminate was sandwiched between two polarizing plates disposed on crossed nicols and observed, the laminate was allowed to rotate in a horizontal plane, and a light and dark state was confirmed. For the light absorption anisotropic film in the laminate, the presence or absence of the cissing during the coating was confirmed from the light and dark state. The results are shown in Table 1. The result of C or higher is within an allowable range.
A: cissing was not visually observed as a whole.
B: cissing was partially visually observed.
C: cissing was visually observed in a wide area.
D: cissing was visually observed as a whole.

### [Alignment Degree]

Each laminate of the examples and the comparative examples was set on a sample table in a state where a linear polarizer was inserted on a light source side of an optical microscope (product name, “ECLIPSE E600 POL”, manufactured by Nikon Corporation), the absorbance of the light absorption anisotropic film in a wavelength range of 380 nm to 780 nm was measured at a pitch of 1 nm using a multi-channel spectroscope (product name, “QE65000”, manufactured by Ocean Optics, Inc.), and the alignment degree in a wavelength range of 400 nm to 700 in was calculated according to the following equation. Based on the obtained alignment degree, the alignment degree was evaluated according to the following evaluation standards. The results are shown in Table 1.

$$Alignment degree : S = ( ( Az 0 / Ay 0 ) - 1 ) / ( ( Az 0 / Ay 0 ) + 2 )$$

In the above expression, “Az0” represents the absorbance of the light absorption anisotropic film with respect to polarization in the absorption axis direction, and “Ay0” represents the absorbance of the light absorption anisotropic film with respect to polarization in the transmission axis direction.
A: alignment degree was 0.95 or greater.
B: alignment degree was 0.88 or greater and less than 0.95.
C: alignment degree was less than 0.88.

Since none of the layer configurations of the laminate other than the light absorption anisotropic film had absorption in 400 to 700 nm, the alignment degree calculated as described above can be read as the value of the light absorption anisotropic film in the laminate.

### [Transmittance Central Axis Angle θ]

In a case where the transmittance central axis angle θ was measured for each of the laminates of Examples and Comparative Examples by the above-described method, the transmittance central axis angle θ of each of the laminates of Examples and Comparative Examples was in a range of 80° to 90°.

Since none of the layer configurations of the laminate other than the light absorption anisotropic film had absorption anisotropy, the transmittance central axis angle θ calculated above could be read as the value of the light absorption anisotropic film in the laminate.

TABLE 1

| | Liquid crystal composition | | | | | | | | | |
|---|---|---|---|---|---|---|---|---|---|---|
| | Copolymer | | | | High-molecular-weight | | Low-molecular-weight | | Dichroic | |
| | | | Mass ratio | | liquid crystal compound | | liquid crystal compound | | substance | |
| | | Parts by | to dichroic | | | Parts by | | Parts by | | Parts by |
| | Type | mass | substance | Mw | Type | mass | Type | mass | Type | mass |
| Example 1-1 | B1 | 0.027 | 0.039 | 18000 | P1 | 2.23 | L1 | 0.95 | Y1 | 0.09 |
| Example 1-2 | B2 | 0.027 | 0.039 | 21500 | P1 | 2.23 | L1 | 0.96 | Y1 | 0.09 |
| Example 1-3 | B3 | 0.026 | 0.039 | 16400 | P2 | 2.26 | L1 | 0.97 | Y1 | 0.09 |
| Example 1-4 | B4 | 0.026 | 0.039 | 20100 | P1 | 2.26 | L1 | 0.97 | Y1 | 0.09 |
| Example 1-5 | B5 | 0.026 | 0.039 | 19000 | P1 | 2.26 | L2 | 0.97 | Y1 | 0.09 |
| Example 1-6 | B6 | 0.027 | 0.039 | 14000 | P1 | 2.23 | L1 | 0.96 | Y1 | 0.08 |
| Example 1-7 | B7 | 0.027 | 0.039 | 14300 | P1 | 2.23 | L1 | 0.95 | Y1 | 0.09 |
| Example 1-8 | B8 | 0.027 | 0.039 | 12600 | P1 | 2.23 | L2 | 0.95 | Y1 | 0.09 |
| Example 1-9 | B9 | 0.027 | 0.039 | 13000 | P1 | 2.23 | L1 | 0.96 | Y1 | 0.09 |
| Example 1-10 | B10 | 0.026 | 0.038 | 13400 | P1 | 2.26 | L1 | 0.97 | Y1 | 0.08 |
| Example 1-11 | B11 | 0.026 | 0.039 | 11800 | P3 | 2.26 | L1 | 0.97 | Y1 | 0.09 |
| Example 1-12 | B8 | 0.026 | 0.039 | 12600 | — | — | L3 | 3.23 | Y1 | 0.09 |
| Example 1-13 | B8 | 0.005 | 0.008 | 12600 | P1 | 2.26 | L1 | 0.96 | Y1 | 0.09 |
| Example 1-14 | B13 | 0.026 | 0.038 | 17000 | P1 | 3.23 | L1 | 0.00 | Y1 | 0.09 |
| Example 1-15 | B14 | 0.026 | 0.038 | 23000 | P1 | 3.23 | L1 | 0.00 | Y1 | 0.09 |
| Comparative | B′1 | 0.026 | 0.039 | — | P3 | 2.26 | L1 | 0.97 | Y1 | 0.09 |
| Example 1-1 | | | | | | | | | | |
| Comparative | B′2 | 0.026 | 0.039 | 12500 | P3 | 2.26 | L1 | 0.97 | Y1 | 0.09 |
| Example 1-2 | | | | | | | | | | |
| Comparative | B′3 | 0.026 | 0.039 | 13000 | P3 | 2.26 | L1 | 0.97 | Y1 | 0.09 |
| Example 1-3 | | | | | | | | | | |

| | Liquid crystal composition | | | | | | | | | | |
|---|---|---|---|---|---|---|---|---|---|---|---|
| | Dichroic | | Dichroic | | Polymerization | | Tetrahy- | Cyclo- | | | |
| | substance | | substance | | initiator | | drofuran | pentanone | Evaluation results | | |
| | | Parts by | | Parts by | | Parts by | Parts by | Parts by | | | Alignment |
| | Type | mass | Type | mass | Type | mass | mass | mass | Haze | Cissing | degree |
| Example 1-1 | M1 | 0.20 | C1 | 0.41 | I1 | 0.14 | 53.9 | 23.1 | A | C | A |
| Example 1-2 | M2 | 0.20 | Cl | 0.41 | I1 | 0.14 | 53.9 | 23.1 | A | C | A |
| Example 1-3 | M1 | 0.19 | C2 | 0.39 | I1 | 0.13 | 53.9 | 23.1 | A | C | A |
| Example 1-4 | M1 | 0.19 | C1 | 0.39 | I1 | 0.13 | 53.9 | 23.1 | A | C | B |
| Example 1-5 | M2 | 0.19 | C2 | 0.39 | I1 | 0.13 | 53.9 | 23.1 | B | C | B |
| Example 1-6 | M1 | 0.20 | C1 | 0.41 | I1 | 0.14 | 53.9 | 23.1 | B | A | A |
| Example 1-7 | M1 | 0.20 | C1 | 0.41 | I1 | 0.14 | 53.9 | 23.1 | B | A | A |
| Example 1-8 | M1 | 0.20 | C1 | 0.41 | I1 | 0.14 | 53.9 | 23.1 | A | A | A |
| Example 1-9 | M1 | 0.20 | C2 | 0.41 | I1 | 0.14 | 53.9 | 23.1 | A | A | B |
| Example 1-10 | M2 | 0.19 | C1 | 0.20 | I1 | 0.13 | 53.9 | 23.1 | A | A | A |
| | | | C2 | 0.20 | | | | | | | |
| Example 1-11 | M1 | 0.19 | C1 | 0.39 | I1 | 0.13 | 53.9 | 23.1 | A | B | B |
| Example 1-12 | M1 | 0.19 | C1 | 0.39 | I1 | 0.13 | 53.9 | 23.1 | B | A | B |
| Example 1-13 | M1 | 0.19 | C1 | 0.39 | I1 | 0.13 | 53.9 | 23.1 | B | B | A |
| Example 1-14 | M2 | 0.19 | C1 | 0.20 | I1 | 0.13 | 53.9 | 23.1 | A | A | A |
| | | | C2 | 0.20 | | | | | | | |
| Example 1-15 | M2 | 0.19 | C1 | 0.20 | I1 | 0.13 | 53.9 | 23.1 | A | A | A |
| | | | C2 | 0.20 | | | | | | | |
| Comparative | M1 | 0.19 | C2 | 0.39 | I1 | 0.13 | 53.9 | 23.1 | C | D | C |
| Example 1-1 | | | | | | | | | | | |
| Comparative | M1 | 0.19 | C2 | 0.39 | I1 | 0.13 | 53.9 | 23.1 | C | D | C |
| Example 1-2 | | | | | | | | | | | |
| Comparative | M1 | 0.19 | C2 | 0.39 | I1 | 0.13 | 53.9 | 23.1 | C | D | C |
| Example 1-3 | | | | | | | | | | | |

In Table 1, “Mass ratio to dichroic substance” means a mass ratio of a content of the copolymer to a content of the dichroic substance (content of copolymer/content of dichroic substance) in the liquid crystal composition.

As shown in Table 1, it was shown that, in a case where the liquid crystal composition containing the specific polymer is used, it is possible to form a light absorption anisotropic film in which cissing is suppressed during formation of the light absorption anisotropic film and alignment defects are suppressed (Examples 1-1 to 1-15).

From the comparison between Examples 1-1 and 1-2 and Example 1-5, it was shown that, in a case where the specific polymer having the repeating unit B is used, the alignment defects (haze) can be further suppressed, and a light absorption anisotropic film having an excellent alignment degree can be formed.

From the comparison between Examples 1-6 and 1-7 and Example 1-5, it was shown that, in a case where the specific polymer having the repeating unit D is used, the cissing and the alignment defects (haze) can be further suppressed, and a light absorption anisotropic film having an excellent alignment degree can be formed.

From the comparison between Example 1-8 and Example 1-9, it was shown that, in a case where the total of molecular weights of the groups corresponding to R^{B4} and R^{B5} in the repeating unit B is 100 or less, the alignment defects (haze) can be further suppressed, and a light absorption anisotropic film having an excellent alignment degree can be formed. From the comparison between Example 1-8 and Example 1-11, it was shown that, in a case where the content of the repeating unit D is 20% by mass or more with respect to the total mass of the specific polymer, the cissing can be further suppressed.

From the comparison between Example 1-8 and Example 1-12, it was shown that, in a case where the high-molecular-weight liquid crystal compound is used, the alignment defects (haze) can be further suppressed, and a light absorption anisotropic film having an excellent alignment degree can be formed.

On the other hand, in a case where the liquid crystal composition not containing the specific polymer was used, the cissing could not be sufficiently suppressed in a case of forming the light absorption anisotropic film, and the alignment defects of the obtained light absorption anisotropic film could not be sufficiently suppressed (Comparative Examples 1-1 to 1-3).

### Example 2-1

### [Formation of Alignment Film 2]

A cellulose acylate film (TAC substrate having a thickness of 40 μm: TG40, manufactured by FUJIFILM Corporation) was continuously coated with the following composition 1 for forming an alignment film using a wire bar. The cellulose acylate film on which the coating film had been formed was dried with hot air at 140° C. for 120 seconds to form an alignment film 2, thereby obtaining a TAC film with an alignment film. A film thickness of the alignment film 2 was 0.5 μm.

(Composition 2 for forming alignment film)

| | |
|---|---|
| Polymer PA2 shown below | 100.00 parts by mass |
| Acid generator PAG-1 shown below | 8.25 parts by mass |
| Stabilizer DIPEA shown below | 0.6 parts by mass |
| Methyl ethyl ketone | 250.36 parts by mass |
| Butyl acetate | 1001.42 parts by mass |

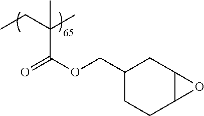

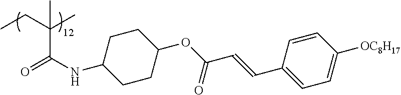

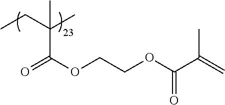

PA2 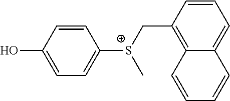 [SMILES: C[S+](Cc1cccc2ccccc12)c1ccc(O)cc1] 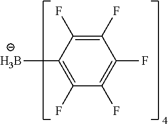
PAG-1 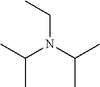
DIPEA

### [Production of Light Absorption Anisotropic Film 2-1]

The obtained alignment film 2 was continuously coated with the following liquid crystal composition 2-1 using a wire bar, heated at 120° C. for 60 seconds, and cooled to room temperature (23° C.).

Next, the coating layer was heated at 85° C. for 60 seconds and cooled to room temperature again.

Thereafter, the film was irradiated with light of a light emitting diode (LED) (central wavelength of 365 nm) under an irradiation condition of an illuminance of 200 mW/cm² for 2 seconds, thereby producing a light absorption anisotropic film 2-1 on the alignment film 2. The film thickness of the light absorption anisotropic film 2-1 was 3.5 μm.

(Liquid crystal composition 2-1)

| | |
|---|---|
| High-molecular-weight liquid crystal compound P4 shown below | 6.373 parts by mass |
| Low-molecular-weight liquid crystal compound L1 shown above | 3.852 parts by mass |
| Dichroic substance Y1 shown above | 0.618 parts by mass |
| Dichroic substance M3 shown below | 0.141 parts by mass |
| Dichroic substance C3 shown below | 1.531 parts by mass |
| Copolymer B12 shown above | 0.004 parts by mass |
| Alignment agent D1 shown below | 0.148 parts by mass |
| Alignment agent D2 shown below | 0.148 parts by mass |
| Polymerization initiator | 0.185 parts by mass |
| (IRGACURE OXE-02, manufactured by BASF) | |
| Cyclopentanone | 87.000 parts by mass |

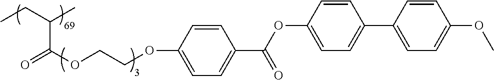

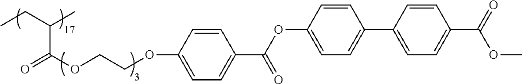

P4 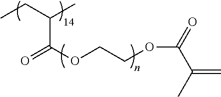
n = 10 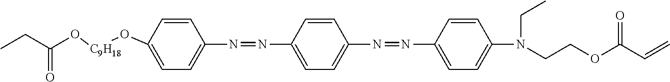
M3 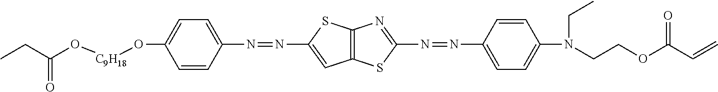
C3 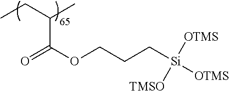 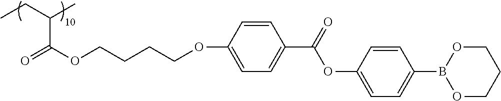 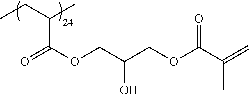 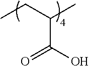
B12 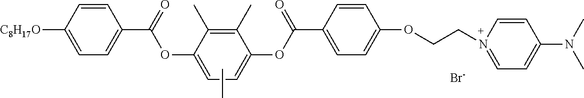
D1 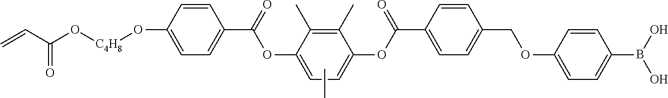
D2

### [Formation of Barrier Layer B1]

The following composition B1 for forming a barrier layer was continuously applied onto the surface of the obtained light absorption anisotropic film 2-1 with a wire bar to form a coating film.

Next, the support on which the coating film was formed was dried with hot air at 60° C. for 60 seconds, and was further dried with hot air at 100° C. for 120 seconds to form a barrier layer B1, thereby preparing a laminate 2-1. The film thickness of the barrier layer was 0.5 μm.

(Composition B1 for forming barrier layer)

| | |
|---|---|
| Modified polyvinyl alcohol PVA-1 shown below | 3.80 parts by mass |
| IRGACURE 2959 | 0.20 parts by mass |
| Water | 70 parts by mass |
| Methanol | 30 parts by mass |

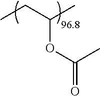

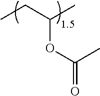

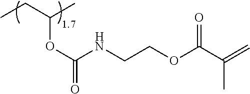

PVA-1

In a case where a transmittance central axis angle θ of the produced laminate 2-1 was measured using the above-described method, the transmittance central axis angle θ was 0°. Since none of the layer configurations of the laminate 2-1 other than the light absorption anisotropic film 2-1 had absorption anisotropy, the transmittance central axis angle θ calculated above could be read as the value of the light absorption anisotropic film 2-1 in the laminate 2-1.

### Comparative Example 2-1

A laminate of Comparative Example 2-1 was obtained in the same manner as in Example 2-1, except that the copolymer B13 used in the liquid crystal composition 2-1 was changed to the above-described copolymer B′1.

### [Evaluation]

The haze and the cissing were evaluated for each of the laminates of Example 2-1 and Comparative Example 2-1. The results are shown in Table 2.

TABLE 2

| | Copolymer | | | Evaluation results | |
|---|---|---|---|---|---|
| | Type | Parts by mass | Mw | Haze | Cissing |
| Example 2-1 | B12 | 0.004 | 15000 | A | A |
| Comparative | B′1 | 0.004 | — | C | D |
| Example 2-1 | | | | | |

As shown in Table 2, it was shown that, in a case where the liquid crystal composition containing the specific polymer is used, it is possible to form a light absorption anisotropic film in which cissing is suppressed during formation of the light absorption anisotropic film and alignment defects are suppressed (Example 2-1).

On the other hand, in a case where the liquid crystal composition not containing the specific polymer was used, the cissing could not be sufficiently suppressed in a case of forming the light absorption anisotropic film, and the alignment defects of the obtained light absorption anisotropic film could not be sufficiently suppressed (Comparative Example 2-1).

### [Production of Display Device]

A laminate 1-14 produced in Example 1-14 was used to produce display devices 1 and 2 by the following method, and it was confirmed that the laminate according to the embodiment of the present invention sufficiently functioned as the light absorption anisotropic film.

### [Production of Retardation Layer Film 1 Including Positive A-Plate]

The above-described cellulose acylate film 1 was continuously coated with a coating liquid E1 for forming a photo-alignment film, having the following formulation, with a wire bar. The cellulose acylate film 1 on which the coating film had been formed was dried with hot air at 140° C. for 120 seconds, and the coating film was irradiated with polarized ultraviolet rays (10 mJ/cm², using an ultra-high pressure mercury lamp) to form a photo-alignment film E1 having a thickness of 0.2 μm, thereby obtaining a TAC film with the photo-alignment film.

Coating liquid E1 for forming photo-alignment film

| | |
|---|---|
| Polymer PA3 shown below | 100.00 parts by mass |
| Thermal cationic polymerization initiator | 5.00 parts by mass |
| PAG-1 shown above | |
| Acid generator CPI-110TF shown below | 0.005 parts by mass |
| Isopropyl alcohol | 16.50 parts by mass |
| Butyl acetate | 1072.00 parts by mass |
| Methyl ethyl ketone | 268.00 parts by mass |

Polymer PA3 [in the formula, the numerical value described in each repeating unit denotes the content (% by mass) of each repeating unit with respect to all repeating units; weight-average molecular weight: 45,000] 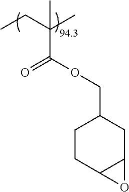 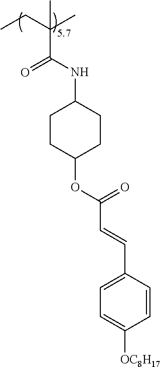
Acid generator CPI-110TF

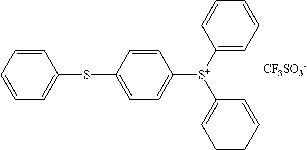

The above-described photo-alignment film E1 was coated with a composition F1 having the following formulation with a bar coater. The coating film formed on the photo-alignment film E1 was heated to 120° C. with hot air, cooled to 60° C., irradiated with ultraviolet rays having a wavelength of 365 nm with an illuminance of 100 mJ/cm² using a high-pressure mercury lamp in a nitrogen atmosphere, and continuously irradiated with ultraviolet rays with an illuminance of 500 mJ/cm² while being heated at 120° C., so that the alignment of the liquid crystal compound was immobilized, thereby producing a retardation layer film 1 including a positive A-plate F1.

A thickness of the positive A-plate F1 was 2.5 μm, and an Re(550) was 144 nm. In addition, the positive A-plate satisfied a relationship of “Re(450)≤Re(550)≤Re(650)”. Re(450)/Re(550) was 0.82. The above-described positive A-plate corresponds to a so-called λ/4 plate.

Composition F1

| | |
|---|---|
| Polymerizable liquid crystal compound LA-1 shown below | 43.50 parts by mass |
| Polymerizable liquid crystal compound LA-2 shown below | 43.50 parts by mass |
| Polymerizable liquid crystal compound LA-3 shown below | 8.00 parts by mass |
| Polymerizable liquid crystal compound LA-4 shown below | 5.00 parts by mass |
| Polymerization initiator PI-1 shown below | 0.55 parts by mass |
| Leveling agent T-1 shown below | 0.20 parts by mass |
| Cyclopentanone | 235.00 parts by mass |

Polymerizable liquid crystal compound LA-1 (tBu represents a tertiary butyl group) 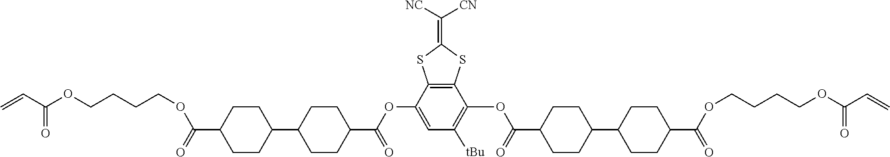 [SMILES: C=CC(=O)OCCCCOC(=O)C1CCC(C2CCC(C(=O)Oc3cc(C(C)(C)C)c(OC(=O)C4CCC(C5CCC(C(=O)OCCCCOC(=O)C=C)CC5)CC4)c4c3SC(=C(C#N)C#N)S4)CC2)CC1]
Polymerizable liquid crystal compound LA-2 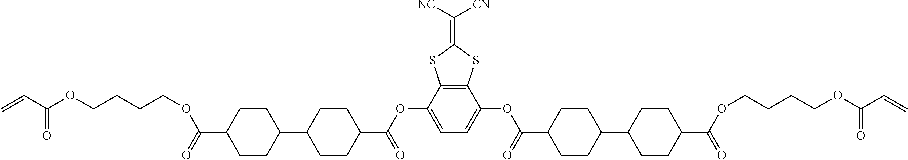 [SMILES: C=CC(=O)OCCCCOC(=O)C1CCC(C2CCC(C(=O)Oc3ccc(OC(=O)C4CCC(C5CCC(C(=O)OCCCCOC(=O)C=C)CC5)CC4)c4c3SC(=C(C#N)C#N)S4)CC2)CC1]
Polymerizable liquid crystal compound LA-3 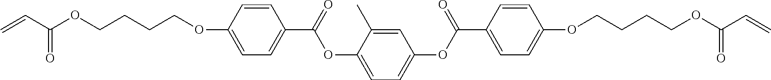 [SMILES: C=CC(=O)OCCCCOc1ccc(C(=O)Oc2ccc(OC(=O)c3ccc(OCCCCOC(=O)C=C)cc3)c(C)c2)cc1]
Polymerizable liquid crystal compound LA-4 (Me represents a methyl group) 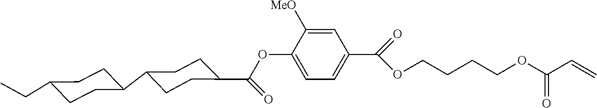 [SMILES: C=CC(=O)OCCCCOC(=O)c1ccc(OC(=O)C2CCC(C3CCC(CC)CC3)CC2)c(OC)c1]
Polymerization initiator PI-1 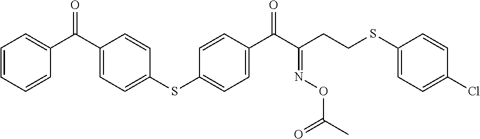 [SMILES: CC(=O)O/N=C(\CCSc1ccc(Cl)cc1)C(=O)c1ccc(Sc2ccc(C(=O)c3ccccc3)cc2)cc1]
Leveling agent T-1 [in the formula, the numerical value described in each repeating unit denotes the content (% by mass) of each repeating unit with respect to all repeating units; weight-average molecular weight: 25,000]

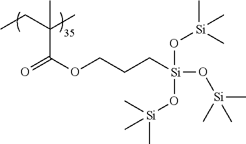

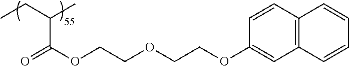

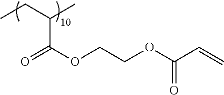

### [Production of Retardation Layer Film 2 Including Positive C-Plate]

The above-described cellulose acylate film 1 was used as a temporary support.

After passing the cellulose acylate film 1 through a dielectric heating roll at a temperature of 60° C. to raise the film surface temperature to 40° C., an alkaline solution having the formulation shown below was applied onto one surface of the film using a bar coater at a coating amount of 14 ml/m², followed by heating to 110° C., and transportation of the film under a steam type far-infrared heater manufactured by Noritake Company Limited for 10 seconds.

Next, the film was coated with pure water such that the coating amount reached 3 ml/m² using the same bar coater. Next, the film was washed with water by a fountain coater and drained by an air knife three times, and then transported to a drying zone at 70° C. for 10 seconds and dried to produce the cellulose acylate film 1 subjected to an alkali saponification treatment.

(Alkaline solution)

| | |
|---|---|
| Potassium hydroxide | 4.7 parts by mass |
| Water | 15.8 parts by mass |
| Isopropanol | 63.7 parts by mass |
| Fluorine-containing surfactant SF-1 | 1.0 part by mass |
| (C₁₄H₂₉O(CH₂CH₂O)₂₀H) | |
| Propylene glycol | 14.8 parts by mass |

The cellulose acylate film 1 which had been subjected to the alkali saponification treatment was continuously coated with a coating liquid G1 for forming an alignment film, having the following formulation, using a #8 wire bar. The obtained film was dried with hot air at 60° C. for 60 seconds, and further dried with hot air at 100° C. for 120 seconds to form an alignment film G1.

Coating liquid G1 for forming alignment film

| | |
|---|---|
| Polyvinyl alcohol (PVA103 manufactured | 2.4 parts by mass |
| by Kuraray Co., Ltd.) | |
| Isopropyl alcohol | 1.6 parts by mass |
| Methanol | 36 parts by mass |
| Water | 60 parts by mass |

The alignment film G1 was coated with a coating liquid H1 for forming a positive C-plate, having the following formulation, the obtained coating film was aged at 60° C. for 60 seconds and irradiated with ultraviolet rays at an illuminance of 1000 mJ/cm² in the air using an air-cooled metal halide lamp at an illuminance of 70 mW/cm² (manufactured by Eye Graphics Co., Ltd.), and the alignment state thereof was fixed to vertically align the liquid crystal compound, thereby producing a retardation layer film 2 including a positive C-plate H1 with a thickness of 0.5 μm.

Rth(550) of the obtained positive C-plate was −60 nm.

Coating liquid H1 for forming positive C-plate

| | |
|---|---|
| Liquid crystal compound LC-1 shown below | 80 parts by mass |
| Liquid crystal compound LC-2 shown below | 20 parts by mass |
| Vertically aligned liquid crystal compound S01 shown below | 1 part by mass |
| Ethylene oxide-modified trimethylolpropane triacrylate | 8 parts by mass |
| (V#360, manufactured by Osaka Organic Chemical Industry Ltd.) | |
| IRGACURE 907 (manufactured by BASF) | 3 parts by mass |
| KAYACURE DETX (manufactured by Nippon Kayaku Co., Ltd.) | 1 part by mass |
| Compound B03 shown below | 0.4 parts by mass |
| Methyl ethyl ketone | 170 parts by mass |
| Cyclohexanone | 30 parts by mass |

Liquid crystal compound LC-1 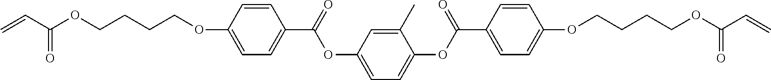 [SMILES: C=CC(=O)OCCCCOc1ccc(C(=O)Oc2ccc(OC(=O)c3ccc(OCCCCOC(=O)C=C)cc3)c(C)c2)cc1]
Liquid crystal compound LC-2 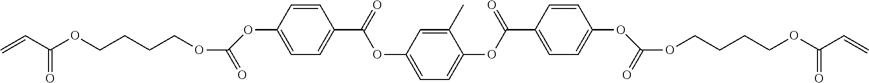 [SMILES: C=CC(=O)OCCCCOC(=O)Oc1ccc(C(=O)Oc2ccc(OC(=O)c3ccc(OC(=O)OCCCCOC(=O)C=C)cc3)c(C)c2)cc1]
Vertically aligned liquid crystal compound S01 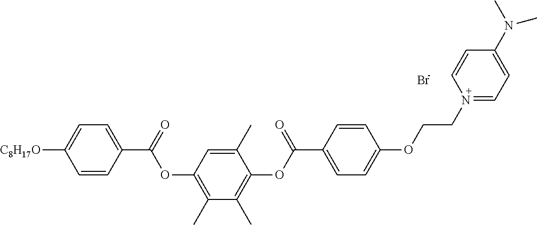
Compound B03 [in the formula, the numerical value described in each repeating unit denotes the content (% by mass) of each repeating unit with respect to all repeating units; weight-average molecular weight: 15,000]

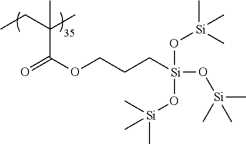

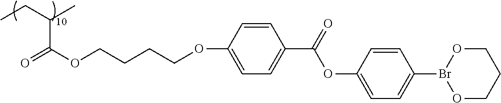

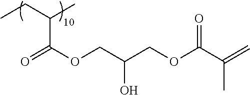

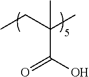

### [Production of Circularly Polarizing Plate 1]

The retardation layer film 1 and the laminate 1-14 which are produced above were bonded to each other using an adhesive such that an angle of an orthographic projection of the transmittance central axis of the laminate 1-14 onto the laminate surface and the slow axis of the retardation film 1 formed an angle of 45° and the light absorption anisotropic film 1-14 side of the laminate 1-14 was the positive A-plate F1 side of the retardation film 1, and then the cellulose acylate film 1 and the photo-alignment film E1 on the retardation film 1 side were peeled off. A corona treatment was performed on the bonding surface of the retardation film 1 and the laminate 1-14, and the following adhesive 1 was used as the adhesive. Furthermore, the alignment film was peeled off, the positive C-plate side of the obtained retardation layer film 2 was bonded to the exposed liquid crystal surface with a pressure sensitive adhesive, and the support and the alignment layer were peeled off. In this manner, a circularly polarizing plate 1 consisting of light absorption anisotropic film/adhesive layer/positive A-plate/adhesive layer/positive C-plate was produced.

### [Preparation of Adhesive 1]

20 parts by mass of methylol melamine with respect to 100 parts by mass of a polyvinyl alcohol-based resin containing an acetoacetyl group (average degree of polymerization: 1200, degree of saponification: 98.5% by mole, degree of acetoacetylation: 5% by mole) was dissolved in pure water under a temperature condition of 30° C. to prepare an aqueous solution in which the concentration of solid contents was adjusted to 3.7% by mass.

### [Production of Organic EL Display Device (Display Device 1)]

GALAXY S5 (manufactured by Samsung Electronics Co., Ltd.) equipped with an organic EL panel (organic EL display element) was disassembled, a touch panel provided with a circularly polarizing plate was peeled off from the organic EL display device, and a circularly polarizing plate was further peeled off from the touch panel, so that the organic EL display element, the touch panel, and the circularly polarizing plate were isolated from each other. Subsequently, the isolated touch panel was bonded to the organic EL display element again, and the circularly polarizing plate 1 on the positive C-plate side, which had been produced above, was bonded onto the touch panel such that air did not enter, thereby producing an organic EL display device (display device 1).

### [Production of Retardation Layer Film 3]

The polymerization was performed using a batch polymerization apparatus consisting of two vertical reactors each equipped with a stirring blade and a reflux condenser controlled at 100° C. 29.60 parts by mass (0.046 mol) of bis[9-(2-phenoxycarbonyl ethyl)fluorene-9-yl]methane, 29.21 parts by mass (0.200 mol) of isosorbide (ISB), 42.28 parts by mass (0.139 mol) of spiroglycol (SPG), 63.77 parts by mass (0.298 mol) of diphenyl carbonate (DPC), and 1.19×10⁻² parts by mass (6.78×10⁻⁵ mol) of calcium acetate monohydrate as a catalyst were charged. After the inside of the reactor was substituted with nitrogen under reduced pressure, the reactor was heated with a heat medium, and stirring was started at a point in time at which the internal temperature reached 100° C. After 40 minutes from the start of the temperature rise, the internal temperature was controlled to reach 220° C. and to be held at this temperature while starting pressure-reducing, and the pressure was reduced to 13.3 kPa 90 minutes after reaching 220° C. Phenol vapor generated as a by-product during the polymerization reaction was introduced to a reflux condenser at 100° C., a monomer component contained in a small amount in the phenol vapor was returned to the reactor, and phenol vapor that was not condensed was introduced to a condenser at 45° C. and recovered. Nitrogen was introduced into the first reactor to be re-pressurized to atmospheric pressure, and then the oligomerized reaction solution in the first reactor was transferred to the second reactor. Next, the temperature rise and the pressure-reducing in the second reactor were started, and the internal temperature was set to 240° C. and the pressure was set to 0.2 kPa in 50 minutes. Thereafter, the polymerization was allowed to proceed until a predetermined stirring power was reached. At a point in time at which the predetermined power was reached, nitrogen was introduced into the reactor to be re-pressurized, and the generated polyester carbonate-based resin was extruded into water to cut strands to obtain pellets.

The obtained polyester carbonate-based resin (pellets) was vacuum-dried at 80° C. for 5 hours, and then a long resin film having a thickness of 130 μm was produced using a film production device comprising a monoaxial extruder (manufactured by Toshiba Machine Co., Ltd., cylinder set temperature: 250° C.), a T-die (width: 200 mm, set temperature: 250° C.), a chill roll (set temperature: 120° C. to 130° C.), and a winder. The obtained long resin film was stretched while adjusting it to obtain a predetermined phase difference, thereby obtaining a retardation film 3 having a thickness of 48 μm. The stretching conditions were a stretching temperature of 143° C. and a stretching ratio of 2.8 times in the width direction. In the obtained retardation film 3, Re(550) was 141 nm, Re(450)/Re(550) was 0.86, and an Nz coefficient was 1.12. The retardation film 3 corresponded to a so-called λ/4 plate.

### [Production of Circularly Polarizing Plate 2]

The retardation layer film 3 and the laminate 1-14 which are produced above were bonded to each other using an adhesive such that an angle of an orthographic projection of the transmittance central axis of the laminate 1-14 onto the laminate surface and the slow axis of the retardation film 3 formed an angle of 45° and the light absorption anisotropic film 1-14 side of the laminate 1-14 was the retardation film 3 side, thereby producing a circularly polarizing plate 2. A corona treatment was performed on the bonding surface of the retardation film 3 and the laminate 1-14, and the above adhesive 1 was used as the adhesive.

### [Production of Organic EL Display Device (Display Device 2)]

GALAXY S5 (manufactured by Samsung Electronics Co., Ltd.) equipped with an organic EL panel (organic EL display element) was disassembled, a touch panel provided with a circularly polarizing plate was peeled off from the organic EL display device, and a circularly polarizing plate was further peeled off from the touch panel, so that the organic EL display element, the touch panel, and the circularly polarizing plate were isolated from each other. Subsequently, the isolated touch panel was bonded to the organic EL display element again, and the retardation film 2 side of the circularly polarizing plate 2, which had been produced above, was bonded onto the touch panel such that air did not enter, thereby producing an organic EL display device (display device 2).

In the display devices 1 and 2 produced in this way, it was confirmed that the laminate (optical film) according to the embodiment of the present invention had sufficient performance as an optical compensation film.

### EXPLANATION OF REFERENCES

100: virtual reality display apparatus
11: first retardation layer
12: second retardation layer
13: third retardation layer
21: first absorptive linear polarizer
22: second absorptive linear polarizer
30: reflective circular polarizer
40: half mirror
50: antireflection layer
60: positive C-plate
70: image display panel

What is claimed is:

1. A liquid crystal composition comprising:
a liquid crystal compound;
a dichroic substance; and
a polymer having a repeating unit A including a structure represented by Formula (A), 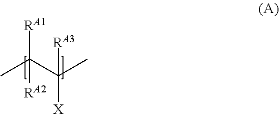
in Formula (A),
R^{A1} and R^{A2} each independently represent a hydrogen atom or an alkyl group,
R^{A3} represents a hydrogen atom, a halogen atom, or a substituent, and
X represents a substituent including one or more structures represented by Formula (a), 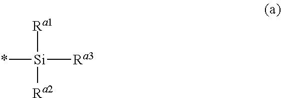
in Formula (a),
* represents a bonding position, and
R^{a1}, R^{a2}, and R^{a3} each independently represent an alkyl group, an alkenyl group, an aryl group, or an alkylene-aryl group, each of which may have a substituent.

2. The liquid crystal composition according to claim 1,
wherein the polymer further has a repeating unit B represented by Formula (B), 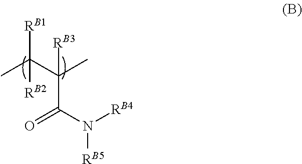
in Formula (B),
R^{B1}, R^{B2}, and R^{B3} each independently represent a hydrogen atom, a halogen atom, a cyano group, an alkyl group, an alkenyl group, or an aryl group,
R^{B4} and R^{B5} each independently represent a hydrogen atom or a substituent, and in a case where R^{B4} and R^{B5} are a substituent, R^{B4} and R^{B5} may be linked to each other to form a ring.

3. The liquid crystal composition according to claim 2,
wherein in Formula (B), a total of molecular weights of R^{B4} and R^{B5} is 100 or less.

4. The liquid crystal composition according to claim 2,
wherein in Formula (B), R^{B4} and R^{B5} each independently represent a hydrogen atom or an organic group having 1 to 15 carbon atoms.

5. The liquid crystal composition according to claim 1,
wherein the polymer further has a repeating unit D represented by Formula (D), 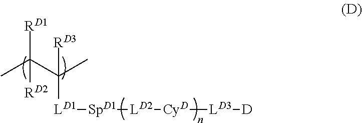
in Formula (D),
R^{D1}, R^{D2}, and R^{D3} each independently represent a hydrogen atom, a halogen atom, a cyano group, an alkyl group, an alkenyl group, or an aryl group,
L^{D1} represents a single bond, —COO—, or —CO—,
Sp^{D1} represents a divalent hydrocarbon group having 1 to 20 carbon atoms, provide that one —CH₂— or two or more —CH₂—'s which are not adjacent to each other among —CH₂—'s constituting a part of the hydrocarbon group may be each independently substituted with —O—, —S—, —NH—, or —N(Q)-, and Q represents a substituent,
L^{D2} and L^{D3} each independently represent a single bond or a divalent linking group,
Cy^{D} represents a divalent linking group including a mesogen group,
D represents a hydrogen bonding group formed of a hydrogen atom and a non-metal atom of Groups 14 to 16, provide that the non-metal atom may have a substituent,
n represents an integer of 1 to 3, and in a case where n is 2 or 3, a plurality of L^{D2}'s may be the same or different from each other and a plurality of Cy^{D}'s may be the same or different from each other.

6. The liquid crystal composition according to claim 5,
wherein in Formula (D), L^{D3} represents a single bond, and D represents —COOH, —NHCOR², or —CONHR³,
here, R^{Z} and R³ each independently represent an alkyl group or an alkenyl group, each of which has 1 to 10 carbon atoms, provide that one —CH₂— or two or more —CH₂—'s which are not adjacent to each other among —CH₂—'s constituting a part of the alkyl group and the alkenyl group may be substituted with —O—.

7. The liquid crystal composition according to claim 5,
wherein in Formula (D), L^{D3} represents a single bond, and D represents —NHCOR⁴,
here, R⁴ represents an alkyl group or an alkenyl group, each of which has 1 to 3 carbon atoms, provide that one —CH₂— or two or more —CH₂—'s which are not adjacent to each other among —CH₂—'s constituting a part of the alkyl group and the alkenyl group may be substituted with —O—.

8. The liquid crystal composition according to claim 5,
wherein in Formula (D), n is 1 or 2.

9. The liquid crystal composition according to claim 1,
wherein the repeating unit A is a repeating unit A-1 represented by Formula (A-1), 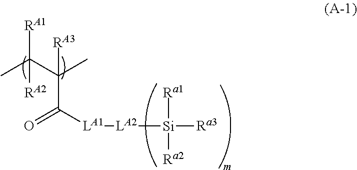
in Formula (A-1),
R^{A1} and R^{A2} each independently represent a hydrogen atom or an alkyl group,
R^{A3} represents a hydrogen atom, a halogen atom, or a substituent,
L^{A1} represents a single bond, —O—, or —NR^{Z}—, provide that R^{Z} represents a hydrogen atom or a substituent,
L^{A2} represents a single bond or an (m+1)-valent linking group,
m represents an integer of 1 or more,
R^{a1}, R^{a2}, and R^{a3} each independently represent an alkyl group, an alkenyl group, an aryl group, or an alkylene-aryl group, each of which may have a substituent, and
in a case where m is an integer of 2 or more, a plurality of R^{a1}'s may be the same or different from each other, a plurality of R^{a2}'s may be the same or different from each other, and a plurality of R^{a3}'s may be the same or different from each other.

10. The liquid crystal composition according to claim 9,
wherein in Formula (A-1), m is an integer of 2 or more.

11. The liquid crystal composition according to claim 1,
wherein the polymer has a repeating unit A-1 represented by Formula (A-1), a repeating unit B represented by Formula (B), and a repeating unit D represented by Formula (D), 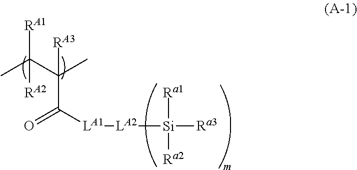
in Formula (A-1),
R^{A1} and R^{A2} each independently represent a hydrogen atom or an alkyl group,
R^{A3} represents a hydrogen atom, a halogen atom, or a substituent,
L^{A1} represents a single bond, —O—, or —NR^{Z}—, provide that R^{Z} represents a hydrogen atom or a substituent,
L^{A2} represents a single bond or an (m+1)-valent linking group,
m represents an integer of 1 or more,
R^{a1}, R^{a2}, and R^{a3} each independently represent an alkyl group, an alkenyl group, an aryl group, or an alkylene-aryl group, each of which may have a substituent, and
in a case where m is an integer of 2 or more, a plurality of R^{a1}'s may be the same or different from each other, a plurality of R^{a2}'s may be the same or different from each other, and a plurality of R^{a3}'s may be the same or different from each other, 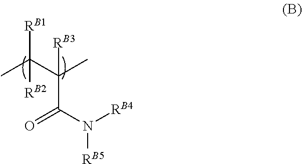
in Formula (B),
R^{B1}, R^{B2}, and R^{B3} each independently represent a hydrogen atom, a halogen atom, a cyano group, an alkyl group, an alkenyl group, or an aryl group,
R^{B4} and R^{B5} each independently represent a hydrogen atom or a substituent, and in a case where R^{B4} and R^{B5} are a substituent, R^{B4} and R^{B5} may be linked to each other to form a ring, 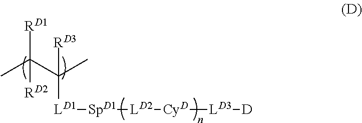
in Formula (D),
R^{D1}, R^{D2}, and R^{D3} each independently represent a hydrogen atom, a halogen atom, a cyano group, an alkyl group, an alkenyl group, or an aryl group,
L^{D1} represents a single bond, —COO—, or —CO—,
Sp^{D1} represents a divalent hydrocarbon group having 1 to 20 carbon atoms, provide that one —CH₂— or two or more —CH₂—'s which are not adjacent to each other among —CH₂—'s constituting a part of the hydrocarbon group may be each independently substituted with —O—, —S—, —NH—, or —N(Q)-, and Q represents a substituent,
L^{D2} and L^{D3} each independently represent a single bond or a divalent linking group,
Cy^{D} represents a divalent linking group including a mesogen group,
D represents a hydrogen bonding group formed of a hydrogen atom and a non-metal atom of Groups 14 to 16, provide that the non-metal atom may have a substituent,
n represents an integer of 1 to 3, and in a case where n is 2 or 3, a plurality of L^{D2}'s may be the same or different from each other and a plurality of Cy^{D}'s may be the same or different from each other.

12. The liquid crystal composition according to claim 1,
wherein a mass ratio of a content of the polymer to a content of the dichroic substance is 0.0007 to 0.6.

13. The liquid crystal composition according to claim 1,
wherein the liquid crystal compound includes a high-molecular-weight liquid crystal compound.

14. The liquid crystal composition according to claim 13,
wherein the liquid crystal compound further includes a low-molecular-weight liquid crystal compound.

15. A light absorption anisotropic film which is obtained by using the liquid crystal composition according to claim 1.

16. The light absorption anisotropic film according to claim 15,
wherein an alignment state of a liquid crystal compound and a dichroic substance which are contained in the light absorption anisotropic film is fixed, and
an angle θ between a transmittance central axis of the light absorption anisotropic film and a normal direction of a surface of the light absorption anisotropic film is more than 450 and 90° or less.

17. A laminate comprising:
the light absorption anisotropic film according to claim 15; and
a λ/4 plate.

18. An image display device comprising:
the light absorption anisotropic film according to claim 15; and
a display element.

19. A polymer comprising:
a repeating unit A-1 represented by Formula (A-1); and
at least one of a repeating unit B represented by Formula (B) or a repeating unit D represented by Formula (D), 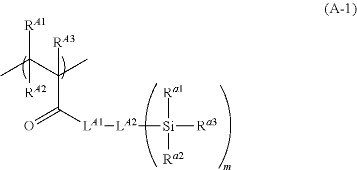
in Formula (A-1),
R^{A1} and R^{A2} each independently represent a hydrogen atom or an alkyl group,
R^{A3} represents a hydrogen atom, a halogen atom, or a substituent,
L^{A1} represents a single bond, —O—, or —NR^{Z}—, provide that R^{Z} represents a hydrogen atom or a substituent,
L^{A2} represents a single bond or an (m+1)-valent linking group,
m represents an integer of 1 or more,
R^{a1}, R^{a2}, and R^{a3} each independently represent an alkyl group, an alkenyl group, an aryl group, or an alkylene-aryl group, each of which may have a substituent, and
in a case where m is an integer of 2 or more, a plurality of R^{a1}'s may be the same or different from each other, a plurality of R^{a2}'s may be the same or different from each other, and a plurality of R^{a3}'s may be the same or different from each other, 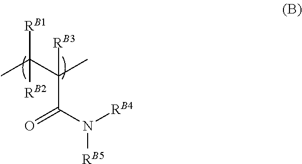
in Formula (B),
R^{B1}, R^{B2}, and R^{B3} each independently represent a hydrogen atom, a halogen atom, a cyano group, an alkyl group, an alkenyl group, or an aryl group,
R^{B4} and R^{B5} each independently represent a hydrogen atom or a substituent, and in a case where R^{B4} and R^{B5} are a substituent, R^{B4} and R^{B5} may be linked to each other to form a ring, 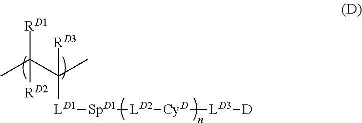
in Formula (D),
R^{D1}, R^{D2}, and R^{D3} each independently represent a hydrogen atom, a halogen atom, a cyano group, an alkyl group, an alkenyl group, or an aryl group,
L^{D1} represents a single bond, —COO—, or —CO—,
Sp^{D1} represents a divalent hydrocarbon group having 1 to 20 carbon atoms, provide that one —CH₂— or two or more —CH₂—'s which are not adjacent to each other among —CH₂—'s constituting a part of the hydrocarbon group may be each independently substituted with —O—, —S—, —NH—, or —N(Q)-, and Q represents a substituent,
L^{D2} and L^{D3} each independently represent a single bond or a divalent linking group,
Cy^{D} represents a divalent linking group including a mesogen group,
D represents a hydrogen bonding group formed of a hydrogen atom and a non-metal atom of Groups 14 to 16, provide that the non-metal atom may have a substituent,
n represents an integer of 1 to 3, and in a case where n is 2 or 3, a plurality of L^{D2}'s may be the same or different from each other and a plurality of Cy^{D}'s may be the same or different from each other.

20. The liquid crystal composition according to claim 3,
wherein in Formula (B), R^{B4} and R^{B5} each independently represent a hydrogen atom or an organic group having 1 to 15 carbon atoms.
